(19) United States
(12) Patent Application Publication
(10) Pub. No.: US 2025/0123561 A1
(43) Pub. Date: Apr. 17, 2025

(54) COMPOSITION, TRANSFER FILM, MANUFACTURING METHOD OF LAMINATE, LAMINATE, AND MANUFACTURING METHOD OF SEMICONDUCTOR PACKAGE

(71) Applicant: FUJIFILM Corporation, Tokyo (JP)

(72) Inventor: Keigo YAMAGUCHI, Minamiashigara-shi (JP)

(73) Assignee: FUJIFILM Corporation, Tokyo (JP)

(21) Appl. No.: 18/987,429

(22) Filed: Dec. 19, 2024

Related U.S. Application Data
(63) Continuation of application No. PCT/JP2023/023833, filed on Jun. 27, 2023.

(30) Foreign Application Priority Data
Jun. 30, 2022 (JP) 2022-105418
Dec. 27, 2022 (JP) 2022-209806

(51) Int. Cl. G03F 7/038; G03F 7/004; G03F 7/32

(52) U.S. Cl. CPC G03F 7/0387; G03F 7/0046; G03F 7/0384; G03F 7/322

(57) ABSTRACT

An object of the present invention is to provide a composition with which a film having excellent cycle thermo characteristics can be formed, a transfer film, a manufacturing method of a laminate, a laminate, and a manufacturing method of a semiconductor package. The composition of the present invention contains a resin X including at least one selected from the group consisting of a polyimide precursor, a polyimide, a polybenzoxazole precursor, and a polybenzoxazole, and a filler, in which a content of the filler is 50.0% by mass or more with respect to a total solid content of the composition, and an average particle diameter of the filler is 300 nm or less.

### CROSS-REFERENCE TO RELATED APPLICATIONS

This application is a Continuation of PCT International Application No. PCT/JP2023/023833 filed on Jun. 27, 2023, which claims priority under 35 U.S.C. § 119(a) to Japanese Patent Application No. 2022-105418 filed on Jun. 30, 2022 and Japanese Patent Application No. 2022-209806 filed on Dec. 27, 2022. The above applications are hereby expressly incorporated by reference, in their entirety, into the present application.

### BACKGROUND OF THE INVENTION

### 1. Field of the Invention

The present invention relates to a composition, a transfer film, a manufacturing method of a laminate, a laminate, and a manufacturing method of a semiconductor package.

### 2. Description of the Related Art

In a display device provided with a touch panel such as a capacitive input device (for example, a display device such as an organic electroluminescence (EL) display device and a liquid crystal display device), a conductive pattern such as an electrode pattern corresponding to a sensor in a visual recognition portion and a wiring line for a peripheral wiring portion and a lead-out wiring portion is provided inside the touch panel.

For example, JP2021-103307A discloses a photosensitive resin composition having a predetermined configuration.

### SUMMARY OF THE INVENTION

The present inventors have found that, in a case where a film is formed of a composition having the configuration as disclosed in JP2021-103307A and a cycle thermos test in which the obtained film is repeatedly heated and cooled is performed, cracks are likely to occur in the film.

Hereinafter, the fact that the cracks are unlikely to occur during the above-described cycle thermo test is referred to that cycle thermo characteristics are excellent.

An object of the present invention is to provide a composition with which a film having excellent cycle thermo characteristics can be formed.

Another object of the present invention is to provide a transfer film, a manufacturing method of a laminate, a laminate, and a manufacturing method of a semiconductor package, which are related to the above-described composition.

As a result of intensive studies to achieve the above-described objects, the present inventors have found that the above-described objects can be achieved by the following configurations, and have completed the present invention.

(1) A composition comprising:
a resin X including at least one selected from the group consisting of a polyimide precursor, a polyimide, a polybenzoxazole precursor, and a polybenzoxazole; and
a filler,
in which a content of the filler is 50.0% by mass or more with respect to a total solid content of the composition, and
an average particle diameter of the filler, which is calculated by a particle diameter measuring method described later, is 300 nm or less.

(2) The composition according to (1),
in which the filler includes at least one selected from the group consisting of silicon dioxide, boron nitride, barium sulfate, and silicate.

(3) The composition according to (1) or (2),
in which the average particle diameter of the filler is 5 to 100 nm.

(4) The composition according to any one of (1) to (3),
in which the content of the filler is 60.0% by mass or more with respect to the total solid content of the composition.

(5) The composition according to any one of (1) to (4),
in which the filler is subjected to a surface treatment with a surface modifier.

(6) The composition according to (5),
in which a content of the surface modifier is 3% by mass or less with respect to a total mass of the filler.

(7) The composition according to (6),
in which the content of the surface modifier is 1% by mass or less with respect to the total mass of the filler.

(8) The composition according to any one of (1) to (7), further comprising:
a thermal-base generator,
in which the resin X includes the precursor.

(9) The composition according to (8),
in which a mass ratio of a content of the thermal-base generator to a content of the resin X is 0.10 or less.

(10) The composition according to (8) or (9),
in which a content of the thermal-base generator is 5.0% by mass or less with respect to the total solid content of the composition.

(11) The composition according to any one of (1) to (10),
in which, in a case where the resin X has a polymerizable group, the composition further contains a photopolymerization initiator, or
   in a case where the resin X has no polymerizable group, the composition further contains a polymerizable compound and a photopolymerization initiator.

(12) The composition according to any one of (1) to (10), further comprising:
a polymerizable compound.

(13) The composition according to (12),
in which a content of the polymerizable compound is 25.0% by mass or less with respect to the total solid content of the composition.

(14) The composition according to any one of (1) to (13), further comprising:
a compound Y having no ethylenically polymerizable group and having a boiling point of 300° C. or higher.

(15) The composition according to (14),
in which the composition further contains a polymerizable compound and the compound Y, and
a total content of the polymerizable compound and the compound Y is 30.0% by mass or less with respect to the total solid content of the composition.

(16) The composition according to any one of (11) to (15), further comprising:
a photopolymerization initiator,
in which a content of the photopolymerization initiator is 5.0% by mass or less with respect to the total solid content of the composition.

(17) The composition according to any one of (1) to (16),
in which the composition contains no sodium ion, or
   in a case of containing a sodium ion, a content of the sodium ion is less than 50 ppm by mass with respect to the total solid content of the composition.

(18) The composition according to any one of (1) to (17),
in which the composition contains no chloride ion, or
   in a case of containing a chloride ion, a content of the chloride ion is less than 50 ppm by mass with respect to the total solid content of the composition.

(19) The composition according to (11),
in which an average value X of coefficients of thermal expansion of a film obtained by a method A described later in a range of 50° C. to 100° C. is 20 ppm/K or less.

(20) The composition according to (11) or (19),
in which a ratio of an average value Y of coefficients of thermal expansion of a film obtained by a method A described later in a range of 190° C. to 210° C. to an average value X of coefficients of thermal expansion of the film in a range of 50° C. to 100° C. is 2.0 or less.

(21) The composition according to any one of (11), (19), or (20),
in which an average relative permittivity of a film obtained by a method A described later at 28 GHz is 3.5 or less.

(22) The composition according to any one of (11) or (19) to (21),
in which an average dielectric loss tangent of a film obtained by a method A described later at 28 GHz is 0.0030 or less.

(23) The composition according to any one of (1) to (10), further comprising:
a photoacid generator,
in which the resin X includes the precursor which has a group decomposed by action of acid to generate a polar group.

(24) The composition according to (23),
in which a content of the photoacid generator is 5.0% by mass or less with respect to the total solid content of the composition.

(25) The composition according to (23) or (24),
in which an average value X of coefficients of thermal expansion of a film obtained by a method B described later in a range of 50° C. to 100° C. is 20 ppm/K or less.

(26) The composition according to any one of (23) to (25),
in which a ratio of an average value Y of coefficients of thermal expansion of a film obtained by a method B described later in a range of 190° C. to 210° C. to an average value X of coefficients of thermal expansion of the film in a range of 50° C. to 100° C. is 2.0 or less.

(27) The composition according to any one of (23) to (26),
in which an average relative permittivity of a film obtained by a method B described later at 28 GHz is 3.5 or less.

(28) The composition according to any one of (23) to (27),
in which an average dielectric loss tangent of a film obtained by a method B described later at 28 GHz is 0.0030 or less.

(29) A transfer film comprising:
a temporary support; and
a composition layer formed of the composition according to any one of (1) to (28).

(30) A manufacturing method of a laminate, comprising:
a step of forming a composition layer on a base material using the composition according to any one of (1) to (28) or the transfer film according to (29);
a step of exposing the composition layer in a patterned manner; and
a step of developing the exposed composition layer with a developer to form a pattern,
in which the developer includes at least one selected from the group consisting of cyclopentanone, a tetramethylammonium hydroxide aqueous solution, a sodium hydroxide aqueous solution, a sodium carbonate aqueous solution, and a potassium carbonate aqueous solution.

(31) A laminate manufactured by the manufacturing method of a laminate according to (30).

(32) A manufacturing method of a semiconductor package, comprising:
the manufacturing method of a laminate according to (30).

According to the present invention, it is possible to provide a composition with which a film having excellent cycle thermo characteristics can be formed.

In addition, it is also possible to provide a transfer film, a manufacturing method of a laminate, a laminate, and a manufacturing method of a semiconductor package, which are related to the above-described composition.

### BRIEF DESCRIPTION OF THE DRAWINGS

FIG. 1 is a diagram (nomograph) describing a boiling point measuring method of a compound Y.

FIG. 2 is a schematic view showing an example of a layer configuration of a transfer film.

### DESCRIPTION OF THE PREFERRED EMBODIMENTS

Hereinafter, the present invention will be described in detail.

In the present specification, a numerical range expressed using “to” means a range that includes the proceeding and succeeding numerical values of “to” as a lower limit value and an upper limit value, respectively.

In addition, regarding numerical ranges that are described stepwise in the present specification, an upper limit value or a lower limit value described in a numerical range may be replaced with an upper limit value or a lower limit value of another stepwise numerical range. In addition, regarding the numerical range described in the present specification, an upper limit value or a lower limit value described in a numerical value may be replaced with a value described in Examples.

In addition, a term “step” in the present specification includes not only an independent step but also a step that cannot be clearly distinguished from other steps, as long as the intended purpose of the step is achieved.

In the present specification, a temperature condition may be set to 25° C. unless otherwise specified. For example, unless otherwise specified, a temperature at which each of the above-described steps is performed may be 25° C.

In the present specification, “transparent” means that an average transmittance of visible light having a wavelength of 400 nm to 700 nm is 80% or more, preferably 90% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means, for example, a bright line spectrum of a mercury lamp such as g-rays, h-rays and i-rays, or far ultraviolet rays typified by an excimer laser, extreme ultraviolet rays (EUV light), X-rays, electron beams (EB). In addition, in the present invention, light means the actinic ray or the radiation.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by corpuscular beams such as electron beams and ion beams.

In the present specification, unless otherwise specified, a content ratio of each repeating unit of a polymer is a molar ratio.

In addition, in the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight. In the present specification, a weight-average molecular weight (Mw) and a number-average molecular weight (Mn) are values in terms of polystyrene by gel permeation chromatography (GPC).

In the present specification, “(meth)acrylic acid” is a concept including both acrylic acid and a methacrylic acid, “(meth)acryloyl group” is a concept including both acryloyl group and methacryloyl group, and “(meth)acrylate” has a concept including both acrylate and methacrylate.

In the present specification, “water-soluble” means that the solubility in 100 g of water with a pH of 7.0 at a liquid temperature of 22° C. is 0.1 g or more.

“Solid content” of a composition means a component forming a composition layer formed of the composition, and in a case where the composition contains a solvent (for example, organic solvent, water, and the like), the solid content means all components excluding the solvent. In addition, in a case where the components are components which form a composition layer, the components are considered to be solid contents even in a case where the components are liquid components.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The above-described average thickness is an average thickness obtained by producing a section to be measured using an ultramicrotome, measuring thicknesses of any five points, and arithmetically averaging the values.

### [Composition]

The composition according to the embodiment of the present invention contains a resin X including at least one selected from the group consisting of polyimide, polybenzoxazole, and a precursor thereof (at least one selected from the group consisting of a polyimide precursor, a polyimide, a polybenzoxazole precursor, and a polybenzoxazole), and a filler, in which a content of the filler is 50.0% by mass or more with respect to a total solid content of the composition, and an average particle diameter of the filler is 300 nm or less.

Although the detailed action mechanism of the composition according to the embodiment of the present invention is not clear, the present inventors have presumed as follows. It is presumed that, since a film formed of the composition according to the embodiment of the present invention contains the resin X and contains a predetermined amount or more of the filler, a film having excellent cycle thermo characteristics can be obtained.

The above-described film to be formed may have a patterned shape.

Hereinafter, the fact that the cycle thermo characteristics of the film to be formed are more excellent is also referred to as “the effect of the present invention is more excellent”.

Hereinafter, example of embodiments of the composition will be described.

### Embodiment X1

a composition containing a resin X, a filler, and a thermal-base generator, in which the resin X includes at least one selected from the group consisting of a polyimide precursor and a polybenzoxazole precursor

### Embodiment Y1

a composition containing a resin X and a filler, in which, in a case where the resin X has a polymerizable group, the composition further contains a photopolymerization initiator, or in a case where the resin X has no polymerizable group, the composition further contains a polymerizable compound and a photopolymerization initiator

### Embodiment Y2

a composition containing a resin X, a filler, a polymerizable compound, a photopolymerization initiator, and a thermal-base generator, in which the resin X includes at least one selected from the group consisting of a polyimide precursor and a polybenzoxazole precursor

### Embodiment Y3

a composition containing a resin X, a filler, a polymerizable compound, a photopolymerization initiator, and a thermal-base generator, in which the resin X includes at least one selected from the group consisting of a polyimide precursor and a polybenzoxazole precursor, and the composition does not substantially contain a photoacid generator

### Embodiment Z1

a composition containing a resin X, a filler, and a photoacid generator, in which the resin X includes at least one selected from the group consisting of a polyimide precursor and a polybenzoxazole precursor, and the precursor has a group decomposed by action of acid to generate a polar group

### Embodiment Z2

a composition containing a resin X, a filler, a photoacid generator, and a thermal-base generator, in which the resin X includes at least one selected from the group consisting of a polyimide precursor and a polybenzoxazole precursor, and the precursor has a group decomposed by action of acid to generate a polar group, and the composition does not substantially contain a photopolymerization initiator

In the above-described embodiment Y1, in a case where the resin X has a polymerizable group, the composition may further contain a polymerizable compound.

In addition, in the above-described embodiment Y2, the resin X may or may not have a polymerizable group.

In a case where the composition in a manufacturing method of a laminate described later is the embodiments Y1 to Y3, it is preferable that an exposed portion forms a pattern (film). The composition is preferably a so-called negative tone resist.

In a case where the composition in a manufacturing method of a laminate described later is the embodiments Z1 and Z2, it is preferable that a non-exposed portion forms a pattern (film). The composition is preferably a so-called positive tone resist.

In the above-described embodiments, the “does not substantially contain a photoacid generator” means that a content of the photoacid generator may be less than 0.1% by mass, preferably 0% to 0.05% by mass and more preferably 0% to 0.01% by mass with respect to the total solid content of the composition.

In addition, the “does not substantially contain a photopolymerization initiator” means that a content of the photopolymerization initiator may be less than 0.1% by mass, preferably 0% to 0.05% by mass and more preferably 0% to 0.01% by mass with respect to the total solid content of the composition.

Hereinafter, various components which can be contained in the composition according to the embodiment of the present invention will be described in detail.

### [Resin X]

The composition contains a resin X.

The resin X is a resin including at least one selected from the group consisting of polyimide, polybenzoxazole, and a precursor thereof. In other words, the resin X includes at least one selected from the group consisting of a polyimide precursor, a polyimide, a polybenzoxazole precursor, and a polybenzoxazole.

In addition, the resin X is a compound different from various components (for example, a polymerizable compound) described later.

The polyimide precursor is a resin which is converted into a polyimide by a heating treatment or a chemical treatment. In addition, the polybenzoxazole precursor is a resin which is converted into a polybenzoxazole by a heating treatment or a chemical treatment.

The resin X may have a polymerizable group.

Examples of the polymerizable group include known polymerizable groups such as a radically polymerizable group, an epoxy group, an oxetanyl group, a methylol group, and an alkoxymethyl group.

As the above-described radically polymerizable group, a group having an ethylenically unsaturated bond is preferable.

Examples of the group having an ethylenically unsaturated bond include a (meth)acrylamide group and a (meth)acryloyl group, and a (meth)acryloyl group is preferable.

The resin X preferably has a polymerizable group which is polymerizable with a polymerizable group in the polymerizable compound described later.

As described in the embodiment Y1 above, in a case where the resin X has a polymerizable group, the composition preferably contains a photopolymerization initiator.

The resin X may have a group decomposed by action of acid to generate a polar group.

In a case where the composition is the embodiment Z1 and the embodiment Z2, the resin X preferably has a group which generates a polar group by action of acid (hereinafter, also referred to as “acid-decomposable group”), and more preferably includes a polyimide precursor having the acid-decomposable group or a polybenzoxazole precursor having the acid-decomposable group.

The acid-decomposable group preferably has a structure in which a polar group is protected by a leaving group which is eliminated by action of acid. The resin X including a repeating unit having the acid-decomposable group has an increased polarity by action of acid, an increased solubility in an alkali developer, and a decreased solubility in an organic solvent developer.

Examples of the polar group include a carboxy group, a phenolic hydroxyl group, a fluorinated alcohol group, a sulfonic acid group, a phosphoric acid group, a sulfonamide group, and an alcoholic hydroxyl group.

As the polar group, a carboxy group, a phenolic hydroxyl group, a fluorinated alcohol group (preferably, a hexafluoroisopropanol group), or a sulfonic acid group is preferable; and a carboxy group or a phenolic hydroxyl group is more preferable.

Examples of the leaving group which is eliminated by action of acid include groups represented by any of Formulae (Y1) to (Y4).

—C(R^{x1})(R^{x2})(R^{x3}) Formula (Y1):

—C(═O)OC(R^{x1})(R^{x2})(R^{x3}) Formula (Y2):

—C(R³⁶)(R³⁷)(OR³⁸) Formula (Y3):

—C(Rn)(H)(Ar) Formula (Y4):

In Formulae (Y1) and (Y2), R^{x1} to R^{x3} each independently represent an alkyl group (which may be linear, branched, or cyclic), an alkenyl group (which may be linear or branched), or an aryl group (which may be monocyclic or polycyclic). In a case where all of R^{x1} to R^{x3} are linear or branched alkyl groups, it is preferable that at least two of R^{x1} to R^{x3} are methyl groups.

Among these, R^{x1} to R^{x3} are preferably linear or branched alkyl groups, and more preferably linear alkyl groups.

Two of R^{x1} to R^{x3} may be bonded to each other to form a monocycle or a polycycle.

As the linear or branched alkyl group of R^{x1} to R^{x3}, an alkyl group having 1 to 5 carbon atoms, such as a methyl group, an ethyl group, an n-propyl group, an isopropyl group, an n-butyl group, an isobutyl group, and a t-butyl group, is preferable.

As the cyclic alkyl group (cycloalkyl group) of R^{x1} to R^{x3}, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group of R^{x1} to R^{x3}, an aryl group having 6 to 10 carbon atoms is preferable, and examples thereof include a phenyl group, a naphthyl group, and an anthryl group.

As the alkenyl group of R^{x1} to R^{x3}, a vinyl group is preferable.

A cycloalkyl group is preferable as the ring formed by the bonding of two of R^{x1} to R^{x3}. As the above-described cycloalkyl group, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable; and a monocyclic cycloalkyl group having 5 or 6 carbon atoms is more preferable.

In the cycloalkyl group formed by the bonding of two of R^{x1} to R^{x3}, one of methylene groups constituting the ring may be replaced with a heteroatom such as an oxygen atom, with a group including a heteroatom, such as a carbonyl group, or with a vinylidene group. In addition, in the cycloalkyl group, one or more of the ethylene groups constituting the cycloalkane ring may be replaced with a vinylene group.

With regard to the group represented by Formula (Y1) or Formula (Y2), for example, an aspect in which R^{x1} is a methyl group or an ethyl group and R^{x2} and R^{x3} are bonded to each other to form the above-described cycloalkyl group is preferable.

In Formula (Y3), R³⁶ to R³⁸ each independently represent a hydrogen atom or a monovalent organic group. R³⁷ and R³⁸ may be bonded to each other to form a ring. Examples of the monovalent organic group include an alkyl group (which may be linear, branched, or cyclic), an aryl group, an aralkyl group, and an alkenyl group. It is also preferable that R³⁶ is a hydrogen atom.

The alkyl group, the aryl group, and the aralkyl group described above may include a heteroatom such as an oxygen atom, and/or a group including a heteroatom, such as a carbonyl group. For example, in the above-described alkyl group, aryl group, and aralkyl group, one or more of methylene groups may be replaced with a heteroatom such as an oxygen atom and/or with a group including a heteroatom, such as a carbonyl group.

In addition, R³⁸ and another substituent included in the main chain of the repeating unit may be bonded to each other to form a ring. A group formed by the mutual bonding of R³⁸ and another substituent on the main chain of the repeating unit is preferably an alkylene group such as a methylene group.

As the group represented by Formula (Y3), a group represented by Formula (Y3-1) is preferable.

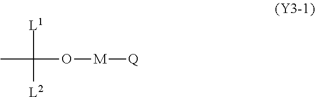

In Formula (Y3-1), L¹ and L² each independently represent a hydrogen atom, an alkyl group (which may be linear, branched, or cyclic), an aryl group, or a group formed by a combination of these groups (for example, a group formed by a combination of an alkyl group and an aryl group).

M represents a single bond or a divalent linking group.

Q represents an alkyl group which may include a heteroatom (which may be linear, branched, or cyclic), an aryl group which may include a heteroatom, an amino group, an ammonium group, a mercapto group, a cyano group, an aldehyde group, or a group formed by a combination thereof (for example, a group formed by a combination of a linear or branched alkyl group and a cycloalkyl group).

In the alkyl group, for example, one of methylene groups may be replaced with a heteroatom such as an oxygen atom or with a group including a heteroatom, such as a carbonyl group.

It is preferable that one of L¹ or L² is a hydrogen atom, and the other is an alkyl group, an aryl group, or a group formed by a combination of an alkylene group and an aryl group.

At least two of Q, M, or L¹ may be bonded to each other to form a ring (preferably, a 5-membered ring or a 6-membered ring).

As L², a secondary or tertiary alkyl group is preferable, and a tertiary alkyl group is more preferable. Examples of the secondary alkyl group include an isopropyl group, a cyclohexyl group, and a norbornyl group. Examples of the tertiary alkyl group include a tert-butyl group and an adamantane group.

It is also preferable that the alkyl group, the aryl group, and the group formed by a combination thereof, represented by L¹ and L², further have a fluorine atom or an iodine atom as a substituent. In addition, it is also preferable that the above-described alkyl group, aryl group, and aralkyl group include a heteroatom such as an oxygen atom in addition to the fluorine atom and the iodine atom (that is, in the above-described alkyl group, aryl group, and aralkyl group, for example, one of methylene groups may be replaced with a heteroatom such as an oxygen atom or with a group including a heteroatom, such as a carbonyl group).

In addition, in the alkyl group which may include a heteroatom, the aryl group which may include a heteroatom, the amino group, the ammonium group, the mercapto group, the cyano group, the aldehyde group, and the group formed by a combination thereof, which are represented by Q, the heteroatom is also preferably at least one heteroatom selected from the group consisting of a fluorine atom, an iodine atom, and an oxygen atom.

In Formula (Y4), Ar represents an aromatic ring group. Rn represents an alkyl group or an aryl group. Rn and Ar may be bonded to each other to form a non-aromatic ring. Ar is preferably an aryl group.

It is also preferable that the aromatic ring group represented by Ar and the alkyl group and the aryl group represented by Rn further have a fluorine atom or an iodine atom as a substituent.

From the viewpoint that acid decomposability is excellent, in a case where a non-aromatic ring is directly bonded to a polar group (or a residue thereof) in the leaving group which protects the polar group, it is also preferable that a ring member atom adjacent to a ring member atom directly bonded to the polar group (or a residue thereof) in the non-aromatic ring does not have a halogen atom such as a fluorine atom as a substituent.

Examples of the leaving group which is eliminated by action of acid include a 2-cyclopentenyl group having a substituent (for example, an alkyl group), such as a 3-methyl-2-cyclopentenyl group, and a cyclohexyl group having a substituent (for example, an alkyl group), such as a 1,1,4,4-tetramethylcyclohexyl group.

### <Polyimide and Polyimide Precursor>

The polyimide is a resin having an imide structure.

The polyimide is preferably a resin having a cyclic imide structure, and may have a substituent. As the polyimide, a resin synthesized from a polyimide precursor having a repeating unit represented by Formula (1) (for example, a resin obtained by a ring closure reaction) is preferable.

The polyimide precursor preferably has a repeating unit represented by Formula (1).

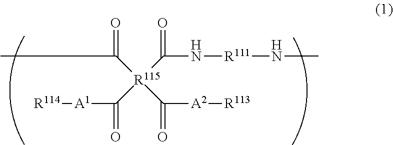

In Formula (1), A¹ and A² each independently represent an oxygen atom or —NH—, R¹¹¹ represents a divalent organic group, R¹¹³ and R¹¹⁴ each independently represent a hydrogen atom or a monovalent organic group, and R¹¹⁵ represents a tetravalent organic group.

In Formula (1), A¹ and A² each independently represent an oxygen atom or —NH—.

As A¹ and A², an oxygen atom is preferable.

In Formula (1), R¹¹¹ represents a divalent organic group.

Examples of the above-described divalent organic group include a divalent aliphatic group, a divalent aromatic ring group, and a divalent group formed by a combination of these groups. As the above-described divalent organic group, a divalent aliphatic group having 2 to 20 carbon atoms, a divalent aromatic ring group having 6 to 20 carbon atoms, or a divalent group formed by a combination of these groups is preferable; and a divalent aromatic ring group having 6 to 20 carbon atoms is more preferable. The above-described divalent aliphatic group may be linear, branched, or cyclic. The above-described divalent aromatic ring group may be monocyclic or polycyclic. The above-described divalent aliphatic group and divalent aromatic ring group may have a heteroatom. The heteroatom may be included in a divalent organic group as a group such as —O—, —CO—, —S—, —SO₂—, and —NHCO—.

As R¹¹¹, a divalent organic group derived from a diamine is also preferable. The above-described diamine is preferably a diamine used for producing the polyimide precursor, and more preferably an aliphatic diamine or an aromatic diamine.

The above-described diamine is preferably a diamine having a linear aliphatic group having 2 to 20 carbon atoms, a branched aliphatic group having 3 to 20 carbon atoms, a cyclic aliphatic group having 3 to 20 carbon atoms, an aromatic ring group having 6 to 20 carbon atoms, or a group formed by a combination of these groups; and more preferably a diamine having an aromatic ring group having 6 to 20 carbon atoms (aromatic diamine). Examples of the above-described aromatic ring group include groups having the following structures.

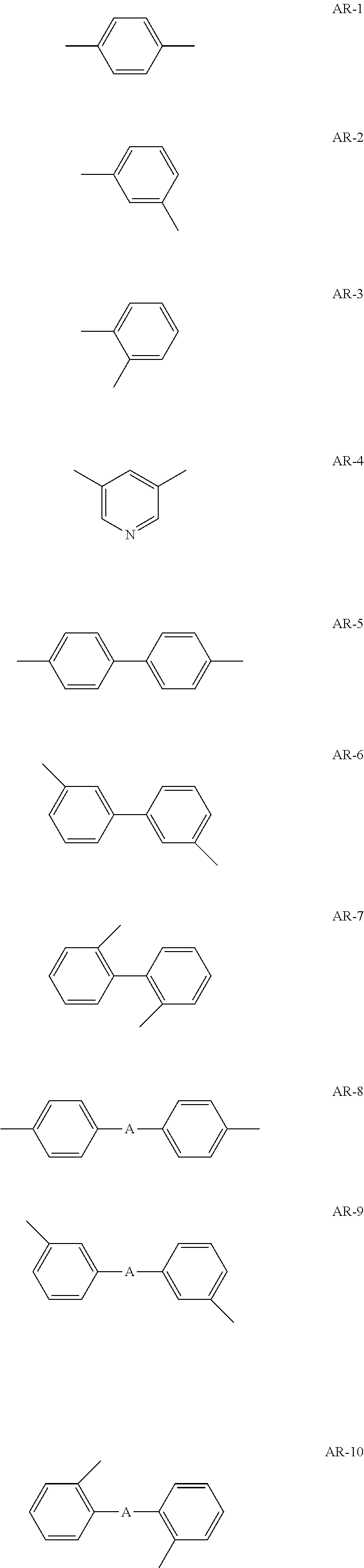

In the formulae, A represents a divalent aliphatic hydrocarbon group having 1 to 10 carbon atoms, which may have a fluorine atom, —O—, —CO—, —S—, —SO₂—, —NHCO—, a group formed by a combination of these groups, or a single bond. As A, at least one selected from the group consisting of an alkylene group having 1 to 3 carbon atoms, which may have a fluorine atom, —O—, —CO—, —S—, and —SO₂— is preferable; at least one selected from the group consisting of —CH₂—, —O—, —S—, —SO₂—, —C(CF₃)₂—, and —C(CH₃)₂— is more preferable; and —O— is still more preferable.

R¹¹¹ is also preferably *—Ar⁰-L⁰-Ar⁰—*.

Ar⁰ represents an aromatic hydrocarbon group. L⁰ represents an aliphatic hydrocarbon group having 1 to 10 carbon atoms, which may have a fluorine atom, —O—, —CO—, —S—, —SO₂—, —NHCO—, a group formed by a combination of these groups, or a single bond. * represents a bonding position.

Ar⁰'s may be the same or different from each other.

The number of carbon atoms in the aromatic hydrocarbon group represented by Ar⁰ is preferably 6 to 22, more preferably 6 to 18, and still more preferably 6 to 10. As the above-described aromatic hydrocarbon group, a phenyl group is preferable.

L⁰ has the same meaning as A in AR-8 described above, and a suitable aspect thereof is also the same.

Examples of the diamine include 1,2-diaminoethane, 1,2-diaminopropane, 1,3-diaminopropane, 1,4-diaminobutane,1,6-diaminohexane, 1,2- or 1,3-diaminocyclopentane, 1,2-, 1,3-, or 1,4-diaminocyclohexane, 1,2-, 1,3-, or 1,4-bis(aminomethyl)cyclohexane, bis-(4-aminocyclohexyl)methane, bis-(3-aminocyclohexyl)methane, 4,4′-diamino-3,3′-dimethylcyclohexylmethane, isophorone diamine, meta or paraphenylene diamine, diaminotoluene, 4,4′- or 3,3′-diaminobiphenyl, 4,4′-diaminodiphenyl ether, 3,3-diaminodiphenyl ether, 4,4′- or 3,3′-diaminodiphenylmethane, 4,4′- or 3,3′-diaminodiphenyl sulfone, 4,4′- or 3,3′-diaminodiphenyl sulfide, 4,4′- or 3,3′-diaminobenzophenone, 3,3′-dimethyl-4,4′-diaminobiphenyl, 2,2′-dimethyl-4,4′-diaminobiphenyl (4,4′-diamino-2,2′-dimethylbiphenyl), 3,3′-dimethoxy-4,4′-diaminobiphenyl, 2,2-bis(4-aminophenyl)propane, 2,2-bis(4-aminophenyl)hexafluoropropane, 2,2-bis(3-hydroxy-4-aminophenyl)propane, 2,2-bis(3-hydroxy-4-aminophenyl)hexafluoropropane, 2,2-bis(3-amino-4-hydroxyphenyl)propane, 2,2-bis(3-amino-4-hydroxyphenyl)hexafluoropropane, bis(3-amino-4-hydroxyphenyl)sulfone, bis(4-amino-3-hydroxyphenyl)sulfone, 4,4′-diaminoparaterphenyl, 4,4-bis(4-aminophenoxy)biphenyl, bis[4-(4-aminophenoxy)phenyl]sulfone, bis[4-(3-aminophenoxy)phenyl]sulfone, bis[4-(2-aminophenoxy)phenyl]sulfone, 1,4-bis(4-aminophenoxy)benzene, 9,10-bis(4-aminophenyl)anthracene, 3,3′-dimethyl-4,4′-diaminodiphenyl sulfone, 1,3-bis(4-aminophenoxy)benzene, 1,3-bis(3-aminophenoxy)benzene, 1,3-bis(4-aminophenyl)benzene, 3,3′-diethyl-4,4′-diaminodiphenylmethane, 3,3′-dimethyl-4,4′-diaminodiphenylmethane, 4,4′-diaminooctafluorobiphenyl, 2,2-bis[4-(4-aminophenoxy)phenyl]propane, 2,2-bis[4-(4-aminophenoxy)phenyl]hexafluoropropane, 9,9-bis(4-aminophenyl)-10-hydroanthracene, 3,3′,4,4′-tetraaminobiphenyl, 3,3′,4,4′-tetraaminodiphenyl ether, 1,4-diaminoanthraquinone, 1,5-diaminoanthraquinone, 3,3-dihydroxy-4,4′-diaminobiphenyl, 9,9′-bis(4-aminophenyl)fluorene, 4,4′-dimethyl-3,3′-diaminodiphenyl sulfone, 3,3′,5,5′-tetramethyl-4,4′-diaminodiphenylmethane, 2-(3′,5′-diaminobenzoyloxy)ethylmethacrylate, 2,4- or, 2,5-diaminocumene, 2,5-dimethyl-paraphenylene diamine, acetoguanamine, 2,3,5,6-tetramethyl-paraphenylene diamine, 2,4,6-trimethyl-metaphenylene diamine, bis(3-aminopropyl)tetramethyl disiloxane, 2,7-diaminofluorene, 2,5-diaminopyridine, 1,2-bis(4-aminophenyl)ethane, diaminobenzanilide, esters of diaminobenzoic acid, 1,5-diaminonaphthalene, diaminobenzotrifluoride, 1,3-bis(4-aminophenyl)hexafluoropropane, 1,4-bis(4-aminophenyl)octafluorobutane, 1,5-bis(4-aminophenyl)decafluoropentane, 1,7-bis(4-aminophenyl)tetradecafluoroheptane, 2,2-bis[4-(3-aminophenoxy)phenyl]hexafluoropropane, 2,2-bis[4-(2-aminophenoxy)phenyl]hexafluoropropane, 2,2-bis[4-(4-aminophenoxy)-3,5-dimethylphenyl]hexafluoropropane, 2,2-bis[4-(4-aminophenoxy)-3,5-bis(trifluoromethyl)phenyl]hexafluoropropane, parabis(4-amino-2-trifluoromethylphenoxy)benzene, 4,4′-bis(4-amino-2-trifluoromethylphenoxy)biphenyl, 4,4′-bis(4-amino-3-trifluoromethylphenoxy)biphenyl, 4,4′-bis(4-amino-2-trifluoromethylphenoxy)diphenyl sulfone, 4,4′-bis(3-amino-5-trifluoromethylphenoxy)diphenyl sulfone, 2,2-bis[4-(4-amino-3-trifluoromethylphenoxy)phenyl]hexafluoropropane, 3,3′,5,5′-tetramethyl-4,4′-diaminobiphenyl, 4,4′-diamino-2,2′-bis(trifluoromethyl)biphenyl, 2,2′,5,5′,6,6′-hexafluorotolidine, and 4,4′-diaminoquaterphenyl.

In addition, examples of the diamine also include a compound represented by any of Formulae (DA-1) to (DA-18).

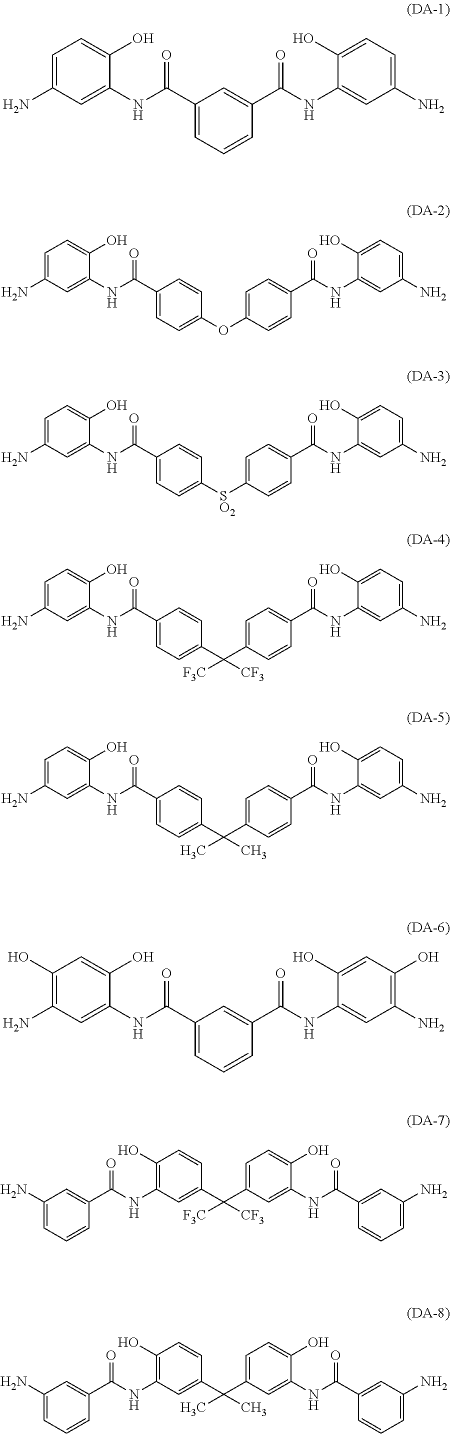

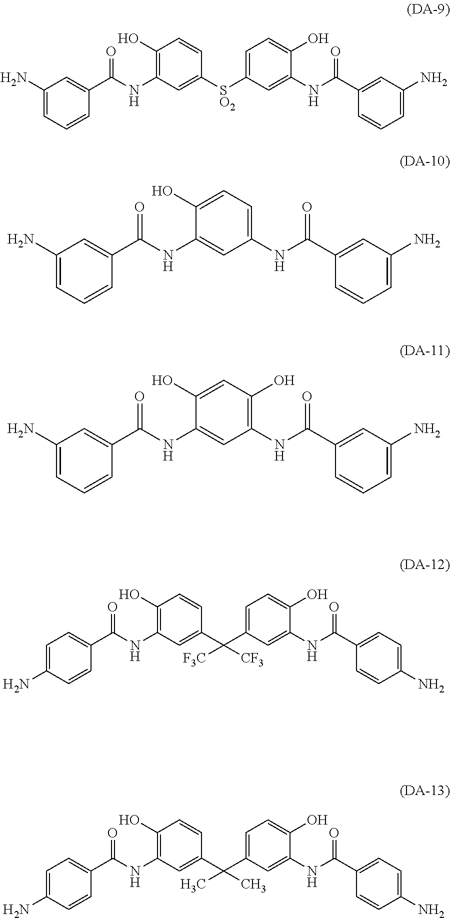 [SMILES: Nc1cccc(C(=O)Nc2cc(S(=O)(=O)c3ccc(O)c(NC(=O)c4cccc(N)c4)c3)ccc2O)c1 ; Nc1cccc(C(=O)Nc2ccc(O)c(NC(=O)c3cccc(N)c3)c2)c1 ; Nc1cccc(C(=O)Nc2cc(NC(=O)c3cccc(N)c3)c(O)cc2O)c1 ; Nc1ccc(C(=O)Nc2cc(C(c3ccc(O)c(NC(=O)c4ccc(N)cc4)c3)(C(F)(F)F)C(F)(F)F)ccc2O)cc1 ; CC(C)(c1ccc(O)c(NC(=O)c2ccc(N)cc2)c1)c1ccc(O)c(NC(=O)c2ccc(N)cc2)c1]

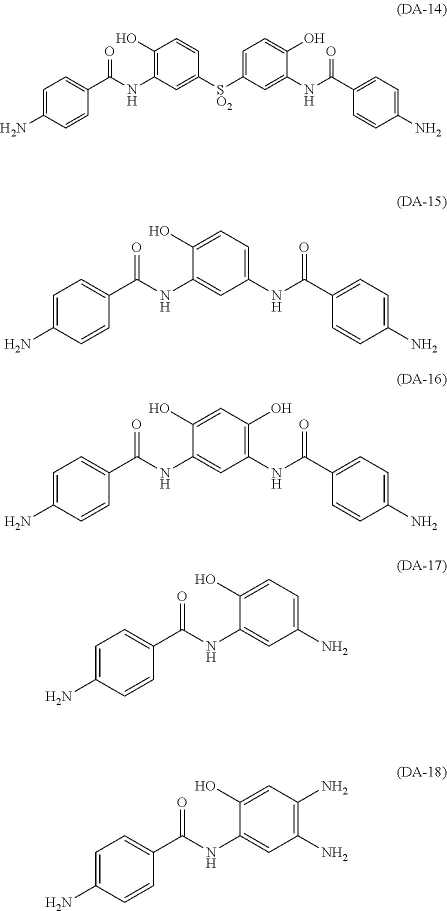 [SMILES: Nc1ccc(C(=O)Nc2cc(S(=O)(=O)c3ccc(O)c(NC(=O)c4ccc(N)cc4)c3)ccc2O)cc1 ; Nc1ccc(C(=O)Nc2ccc(O)c(NC(=O)c3ccc(N)cc3)c2)cc1 ; Nc1ccc(C(=O)Nc2cc(NC(=O)c3ccc(N)cc3)c(O)cc2O)cc1 ; Nc1ccc(C(=O)Nc2cc(N)ccc2O)cc1 ; Nc1ccc(C(=O)Nc2cc(N)c(N)cc2O)cc1]

In addition, examples of the diamine also include a diamine having two or more alkylene glycol units in the main chain; and as the diamine having two or more alkylene glycol units in the main chain, a diamine including two or more of one or both of an ethylene glycol chain and a propylene glycol chain in one molecule is preferable. In addition, a diamine not including an aromatic ring is also preferable.

Examples of the above-described diamine include JEFFAMINE (registered trademark) series (KH-511, ED-600, ED-900, ED-2003, EDR-148, EDR-176, D-200, D-400, D-2000, and D-4000, manufactured by HUNTSMAN Corporation); 1-(2-(2-(2-aminopropoxy)ethoxy)propoxy)propane-2-amine, and 1-(1-(1-(2-aminopropoxy)propane-2-yl)oxy)propane-2-amine.

R¹¹³ and R¹¹⁴ each independently represent a hydrogen atom or a monovalent organic group.

It is preferable that at least one of R¹¹³ or R¹¹⁴ represents a group having a polymerizable group, and it is more preferable that both R¹¹³ and R¹¹⁴ represent a group having a polymerizable group. Examples of the polymerizable group include the groups exemplified as the polymerizable group which may be included in the above-described resin X.

The above-described monovalent organic group may be a monovalent organic group X described later.

R¹¹³ and R¹¹⁴ are each preferably a group having an ethylenically unsaturated group, and more preferably a vinyl group, an allyl group, a (meth)acryloyl group, or a group represented by Formula (III).

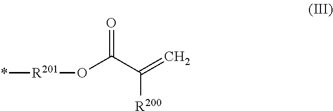

In Formula (III), R²⁰⁰ represents a hydrogen atom or a methyl group, R²⁰¹ represents an alkylene group having 2 to 12 carbon atoms, —CH₂CH(OH)CH₂—, or a (poly)oxyalkylene group having 4 to 30 carbon atoms, and * represents a bonding position.

In Formula (III), R²⁰⁰ represents a hydrogen atom or a methyl group.

R²⁰⁰ is preferably a methyl group.

In Formula (III), R²⁰¹ represents an alkylene group having 2 to 12 carbon atoms, —CH₂CH(OH)CH₂—, or a (poly)oxyalkylene group having 4 to 30 carbon atoms.

The number of carbon atoms in the alkylene group constituting the above-described (poly)oxyalkylene group is preferably 1 to 12, more preferably 1 to 6, and still more preferably 1 to 3. The repetition number of the oxyalkylene constituting the above-described (poly)oxyalkylene group is preferably 1 to 12, more preferably 1 to 6, and still more preferably 1 to 3.

The (poly)oxyalkylene group is a concept including both an oxyalkylene group and a polyoxyalkylene group.

Examples of R²⁰¹ include an ethylene group, a propylene group, a trimethylene group, a tetramethylene group, a 1,2-butanediyl group, a 1,3-butanediyl group, a pentamethylene group, a hexamethylene group, an octamethylene group, a dodecamethylene group, and —CH₂CH(OH)CH₂—; and an ethylene group, a propylene group, a trimethylene group, or —CH₂CH(OH)CH₂— is preferable, and an ethylene group is more preferable.

Examples of the monovalent organic group represented by R¹¹³ or R¹¹⁴ include an aliphatic group, an aromatic ring group, and an arylalkyl group, each of which has 1 to 3 acid groups. Examples thereof include an aromatic ring group having 6 to 20 carbon atoms, which has an acid group, and an arylalkyl group having 7 to 25 carbon atoms, which has an acid group. More specific examples thereof include a phenyl group having an acid group and a benzyl group having an acid group. The acid group is preferably a hydroxyl group or a carboxy group.

As R¹¹³ and R¹¹⁴, a hydrogen atom, 2-hydroxybenzyl, 3-hydroxybenzyl, or 4-hydroxybenzyl is also preferable.

Examples of the monovalent organic group represented by R¹¹³ or R¹¹⁴ include the leaving group which is eliminated by action of acid described above, and may be a group represented by any of Formulae (Y1) to (Y4) described above.

In Formula (1), R¹¹⁵ represents a tetravalent organic group.

As the tetravalent organic group, a tetravalent organic group having an aromatic ring is preferable; and a group represented by Formula (5) or a group represented by Formula (6) is more preferable.

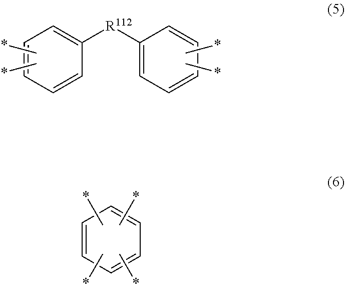

In Formula (5), R¹¹² represents a divalent aliphatic hydrocarbon group having 1 to 10 carbon atoms, which may have a fluorine atom, —O—, —CO—, —S—, —SO₂—, —NHCO—, a group formed by a combination of these groups, or a single bond, and * represents a bonding position.

In Formula (6), * represents a bonding position.

In Formula (5), R¹¹² has the same meaning as A in AR-8 described above, and a suitable aspect thereof is also the same.

Examples of the tetravalent organic group also include a tetracarboxylic acid residue remaining after removing an acid dianhydride group from a tetracarboxylic acid dianhydride. The tetracarboxylic acid dianhydride is preferably a compound represented by Formula (7).

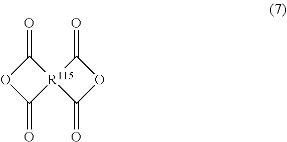

In Formula (7), R¹¹⁵ represents a tetravalent organic group.

R¹⁵ in Formula (7) has the same meaning as R¹¹⁵ in Formula (1), and a suitable aspect thereof is also the same.

Examples of the tetracarboxylic acid dianhydride include pyromellitic acid, pyromellitic acid dianhydride (PMDA), 3,3′,4,4′-biphenyltetracarboxylic acid dianhydride, 3,3′,4,4′-diphenylsulfide tetracarboxylic acid dianhydride, 3,3′,4,4′-diphenylsulfone tetracarboxylic acid dianhydride, 3,3′,4,4′-benzophenone tetracarboxylic acid dianhydride, 3,3′,4,4′-diphenylmethane tetracarboxylic acid dianhydride, 2,2′,3,3′-diphenylmethane tetracarboxylic acid dianhydride, 2,3,3′,4′-biphenyltetracarboxylic acid dianhydride, 2,3,3′,4′-benzophenone tetracarboxylic acid dianhydride, 4,4′-oxydiphthalic acid dianhydride, 2,3,6,7-naphthalene tetracarboxylic acid dianhydride, 1,4,5,7-naphthalene tetracarboxylic acid dianhydride, 2,2-bis(3,4-dicarboxyphenyl)propane dianhydride, 2,2-bis(2,3-dicarboxyphenyl)propane dianhydride, 2,2-bis(3,4-dicarboxyphenyl) hexafluoropropane dianhydride, 1,3-diphenylhexafluoropropane-3,3,4,4-tetracarboxylic acid dianhydride, 1,4,5,6-naphthalene tetracarboxylic acid dianhydride, 2,2′,3,3′-diphenyl tetracarboxylic acid dianhydride, 3,4,9,10-perylene tetracarboxylic acid dianhydride, 1,2,4,5-naphthalene tetracarboxylic acid dianhydride, 1,4,5,8-naphthalene tetracarboxylic acid dianhydride, 1,8,9,10-phenanthrene tetracarboxylic acid dianhydride, 1,1-bis(2,3-dicarboxyphenyl)ethane dianhydride, 1,1-bis(3,4-dicarboxyphenyl)ethane dianhydride, 1,2,3,4-benzene tetracarboxylic acid dianhydride, alkyl derivatives thereof, having 1 to 6 carbon atoms, and alkoxy derivatives thereof, having 1 to 6 carbon atoms.

Examples of the tetracarboxylic acid dianhydride also include a compound represented by any of Formulae (DAA-1) to (DAA-5).

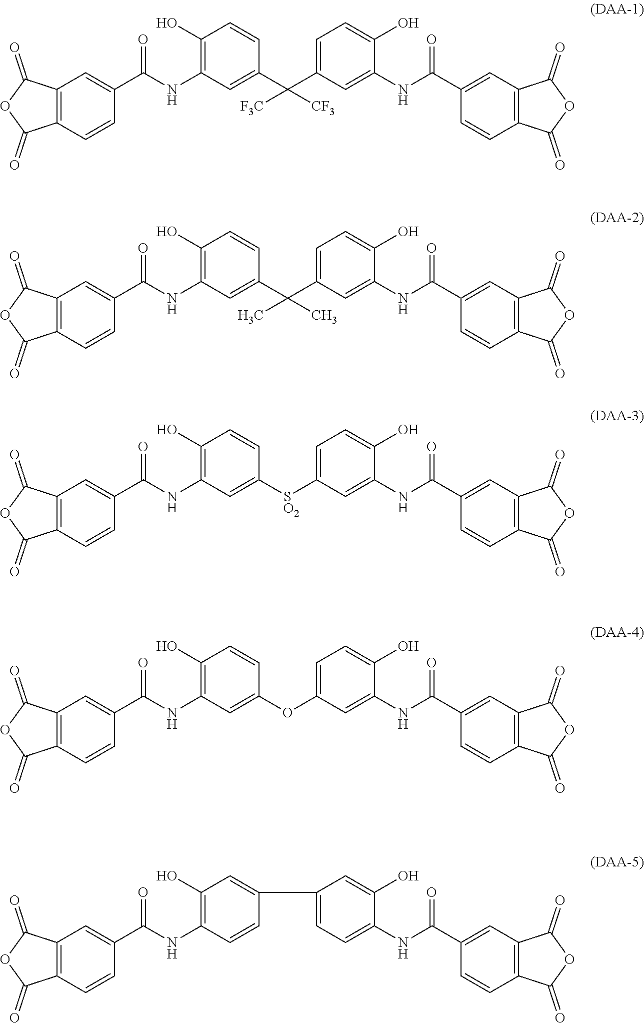 [SMILES: O=C(Nc1cc(C(c2ccc(O)c(NC(=O)c3ccc4c(c3)C(=O)OC4=O)c2)(C(F)(F)F)C(F)(F)F)ccc1O)c1ccc2c(c1)C(=O)OC2=O ; CC(C)(c1ccc(O)c(NC(=O)c2ccc3c(c2)C(=O)OC3=O)c1)c1ccc(O)c(NC(=O)c2ccc3c(c2)C(=O)OC3=O)c1 ; O=C(Nc1cc(S(=O)(=O)c2ccc(O)c(NC(=O)c3ccc4c(c3)C(=O)OC4=O)c2)ccc1O)c1ccc2c(c1)C(=O)OC2=O ; O=C(Nc1cc(Oc2ccc(O)c(NC(=O)c3ccc4c(c3)C(=O)OC4=O)c2)ccc1O)c1ccc2c(c1)C(=O)OC2=O ; O=C(Nc1ccc(-c2ccc(NC(=O)c3ccc4c(c3)C(=O)OC4=O)c(O)c2)cc1O)c1ccc2c(c1)C(=O)OC2=O]

### (Monovalent Organic Group X)

The monovalent organic group X is preferably an alkyl group which may have a substituent or an aromatic ring group which may have a substituent; and more preferably an alkyl group which may have an aromatic ring group.

The above-described alkyl group may be linear, branched, or cyclic. The alicyclic ring may be a monocycle or a polycycle.

The number of carbon atoms in the linear or branched alkyl group is preferably 1 to 30. The number of carbon atoms in the cyclic alkyl group (cycloalkyl group) is preferably 3 to 30.

Examples of the above-described alkyl group include linear or branched alkyl groups such as a methyl group, an ethyl group, a propyl group, a butyl group, a pentyl group, a hexyl group, a heptyl group, an octyl group, a nonyl group, a decyl group, a dodecyl group, a tetradecyl group, an octadecyl group, an isopropyl group, an isobutyl group, a sec-butyl group, a t-butyl group, a 1-ethylpentyl group, and a 2-ethylhexyl group; monocyclic cycloalkyl groups such as a cyclopropyl group, a cyclobutyl group, a cyclopentyl group, a cyclohexyl group, a cycloheptyl group, and a cyclooctyl group; and polycyclic cycloalkyl groups such as an adamantyl group, a norbornyl group, a bornyl group, a camphanyl group, a decahydronaphthyl group, a tricyclodecanyl group, a tetracyclodecanyl group, a camphoroyl group, a dicyclohexyl group, and a pyrenyl group.

As the substituent which can be included in the above-described alkyl group, an aromatic ring group described below is preferable.

The aromatic ring group may be any one of an aromatic hydrocarbon ring group or an aromatic heterocyclic group. In addition, the aromatic ring group may be monocyclic or polycyclic.

Examples of a ring constituting the aromatic ring group include aromatic hydrocarbon rings such as a benzene ring, a naphthalene ring, a biphenyl ring, a fluorene ring, a pentalene ring, an indene ring, an azulene ring, a heptalene ring, an indacene ring, a perylene ring, a pentacene ring, an acenaphthene ring, a phenanthrene ring, an anthracene ring, a naphthacene ring, a chrysene ring, and a triphenylene ring; and aromatic heterocyclic groups such as a pyrrole ring, a furan ring, a thiophene ring, an imidazole ring, an oxazole ring, a thiazole ring, a pyridine ring, a pyrazine ring, a pyrimidine ring, a pyridazine ring, an indridine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, and a phenazine ring.

As the substituent which can be included in the above-described aromatic ring group, the above-described alkyl group is preferable.

It is also preferable that the polyimide precursor has a fluorine atom.

A content of the fluorine atom in the polyimide precursor is preferably 10% by mass or more and more preferably 20% by mass or more with respect to the total mass of the polyimide precursor. The upper limit thereof is preferably 50% by mass or less.

From the viewpoint of improving adhesiveness with the base material, the polyimide precursor may be obtained by copolymerization with an aliphatic group having a siloxane structure and the repeating unit represented by Formula (1). Examples of the aliphatic group having a siloxane structure include bis(3-aminopropyl)tetramethyldisiloxane and bis(paraminophenyl)octamethylpentasiloxane.

As the repeating unit represented by Formula (1), a repeating unit represented by Formula (1-A) or a repeating unit represented by Formula (1-B) is preferable.

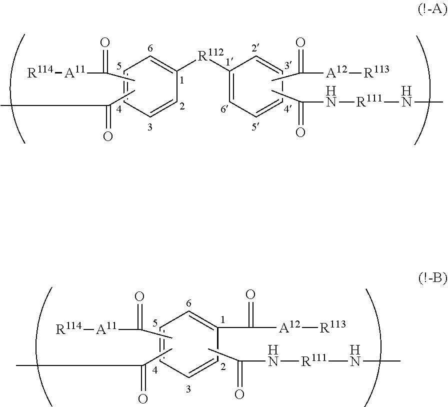

A¹¹ and A¹² represent an oxygen atom or —NH—. R¹¹¹ and R¹¹² each independently represent a divalent organic group. R¹¹³ and R¹¹⁴ each independently represent a hydrogen atom or a monovalent organic group.

A¹¹, A¹², R¹¹¹, R¹¹³, and R¹¹⁴ in Formula (1-A) each have the same meaning as A¹, A², R¹¹¹, R¹¹³, and R¹¹⁴ in Formula (1), and suitable aspects thereof are also the same.

R¹¹² in Formula (1-A) has the same meaning as R¹¹² in Formula (5), and a suitable aspect thereof is also the same.

In Formula (1-A), a bonding position of the carbonyl group to the benzene ring is preferably 4, 5, 3′, or 4′ in Formula (1-A).

In Formula (1-B), a bonding position of the carbonyl group to the benzene ring is preferably 1, 2, 4, or 5 in Formula (1-B).

The polyimide precursor may include other repeating units in addition to the repeating unit represented by Formula (1).

A content of the repeating unit represented by Formula (1) is preferably 50 mol % or more, more preferably 70 mol % or more, and still more preferably 90 mol % or more with respect to all repeating units of the polyimide precursor. The upper limit thereof is preferably 100 mol % or less.

A weight-average molecular weight (Mw) of the polyimide precursor is preferably 2,000 to 500,000, more preferably 5,000 to 100,000, and still more preferably 10,000 to 50,000. A number-average molecular weight (Mn) of the polyimide precursor is preferably 800 to 250,000, more preferably 2,000 to 50,000, and still more preferably 4,000 to 25,000. A dispersity (Mw/Mn) of the polyimide precursor is preferably 1.5 to 3.5, and more preferably 2.0 to 3.0.

### <Polybenzoxazole and Polybenzoxazole Precursor>

The polybenzoxazole is a resin having a benzoxazole ring.

The polybenzoxazole is not particularly limited as long as it is a resin having a benzoxazole ring, and may have a substituent. As the polybenzoxazole, a resin synthesized from a polybenzoxazole precursor having a repeating unit represented by Formula (2) (for example, a resin obtained by a ring closure reaction) is preferable.

The polybenzoxazole precursor preferably has a repeating unit represented by Formula (2).

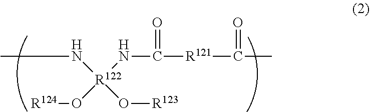

In Formula (2), R¹²¹ represents a divalent organic group, R¹²² represents a tetravalent organic group, and R¹²³ and R¹²⁴ each independently represent a hydrogen atom or a monovalent organic group.

In Formula (2), R¹²¹ represents a divalent organic group.

Examples of the divalent organic group include the divalent organic group represented by R¹¹¹.

In Formula (2), R¹²² represents a tetravalent organic group.

Examples of the tetravalent organic group include the tetravalent organic group represented by R¹¹⁵.

In Formula (2), R¹²³ and R¹²⁴ each independently represent a hydrogen atom or a monovalent organic group.

R¹²³ and R¹²⁴ have the same meanings as R¹¹³ and R¹¹⁴, and suitable aspects thereof are also the same.

The polybenzoxazole precursor may include other repeating units in addition to the repeating unit represented by Formula (2).

Examples of the other repeating units include a repeating unit having a siloxane structure. Examples of the other repeating units described above include repeating units described in paragraphs 0150 to 0154 of JP2020-154205A.

A weight-average molecular weight (Mw) of the polybenzoxazole precursor is preferably 2,000 to 500,000, more preferably 5,000 to 100,000, and still more preferably 10,000 to 50,000.

A number-average molecular weight (Mn) of the polybenzoxazole precursor is preferably 800 to 250,000, more preferably 2,000 to 50,000, and still more preferably 4,000 to 25,000.

A dispersity (Mw/Mn) of the polybenzoxazole precursor is preferably 1.5 to 3.5, and more preferably 2.0 to 3.0.

The resin X may be used alone or in combination of two or more kinds thereof.

A content of the resin X is preferably 5.0% by mass or more, and more preferably 10.0% by mass or more with respect to the total solid content of the composition. The upper limit thereof is preferably 50.0% by mass or less, and more preferably 30.0% by mass or less with respect to the total solid content of the composition.

### [Filler]

The composition contains a filler.

The content of the filler is 50.0% by mass or more with respect to the total solid content of the composition, preferably 60.0% by mass or more, and more preferably 70.0% by mass or more. The upper limit thereof is preferably 90.0% by mass or less, and more preferably 80.0% by mass or less.

The average particle diameter of the filler is 300 nm or less, preferably 200 nm or less, and more preferably 100 nm or less. The lower limit thereof is preferably more than 0 nm, and more preferably 5 nm or more. In addition, the average particle diameter of the filler is also preferably 5 to 100 nm.

The average particle diameter of the filler is calculated by the following particle diameter measuring method.

Particle diameter measuring method: the composition is applied onto a base material to form a coating film, a rectangular region of 3 μm×10 μm in a cross section of the coating film along a normal direction of a surface of the coating film is observed with a scanning electron microscope, an operation of measuring a major diameter of all the fillers observed in the region is performed at five different locations on the coating film, and an average value of all major diameters of the fillers measured in each operation is obtained as the average particle diameter of the filler.

The procedure of the particle diameter measuring method described above will be described in detail.

First, the composition is applied onto a base material to form a coating film. A thickness of the coating film is preferably 3 μm or more. As the base material to be used, a glass substrate is used. In a case of forming the coating film, a drying treatment may be performed as necessary.

A cross section of the obtained coating film along the normal direction of a surface (surface opposite to the substrate side) of the coating film is cut out, a rectangular region of 3 m×10 μm in the cross section is observed with a scanning electron microscope, and a major diameter of all fillers observed in the region is measured. As the scanning electron microscope, S-4800 manufactured by Hitachi High-Tech Corporation is used. In addition, a magnification in the observation is 50,000 times.

The above-described operation is performed at five different positions on the coating film, and an average value (arithmetic mean value) of the major diameters of all the fillers measured in each operation is defined as the average particle diameter of the filler.

The above-described major diameter refers to a length of the longest line segment among line segments connecting any two points on a contour line of the filler in the observation image.

In addition, in a case where the fillers are aggregated in the observation image to constitute an aggregate, the major diameter of each filler constituting the aggregate is measured.

Examples of the filler include an organic filler and an inorganic filler, and an inorganic filler is preferable.

Examples of the filler include silicon dioxide (silica); silicate such as kaolinite, kaolin clay, calcined clay, talc, and undoped glass; and alumina, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride.

The filler preferably includes at least one selected from the group consisting of silicon dioxide (silica), boron nitride, barium sulfate, and silicate, and more preferably includes silicon dioxide (silica).

A shape of the filler may be a spherical shape or a non-spherical shape (for example, a crushed shape and a fibrous shape), and a spherical shape is preferable.

The filler may be subjected to a surface treatment. In other words, it is preferable that the filler is subjected to a surface treatment with a surface modifier. Examples of the surface treatment include a treatment of introducing a functional group and a treatment using a known surface modifier (for example, a liquid phase treatment and a gas phase treatment). Examples of the above-described functional group include a polymerizable group (for example, a polymerizable group included in the polymerizable compound described later) and a hydrophobic group.

The expression “the filler is subjected to a surface treatment with a surface modifier” means that at least a part of the surface of the filler is covered with a surface modifier, a component derived from a surface modifier, or the like. That is, at least a part of the surface of the filler which has been subjected to a surface treatment with a surface modifier is covered with the surface modifier or a component derived from the surface modifier. In a case where the surface modifier is a hydrolyzable compound, examples of the above-described component derived from the surface modifier include a hydrolyzate of the surface modifier and a hydrolysis condensate thereof.

It is preferable that at least a part of the surface of the filler is covered with the surface modifier or the component derived from the surface modifier through a chemical bond; and it is more preferable that at least a part of the surface of the filler is covered with the surface modifier through a bond of “—Si—O—”.

Examples of the surface modifier include a known surface modifier such as a silane coupling agent, a titanate-based coupling agent, and a silazane compound.

The above-described silane coupling agent is, for example, a compound having a hydrolyzable group directly bonded to an Si atom.

Examples of the above-described hydrolyzable group include an alkoxy group (preferably having 1 to 10 carbon atoms) and a halogen atom such as a chlorine atom.

The number of hydrolyzable groups directly bonded to an Si atom in the silane coupling agent is preferably 1 or more, more preferably 2 or more, and still more preferably 3 or more. The upper limit thereof is preferably 10,000 or less.

The silane coupling agent also preferably has a functional group other than the hydrolyzable group.

Examples of the functional group include a (meth)acryloyl group, a phenyl group, a silazane group, an epoxy group, an oxetanyl group, a vinyl group, a styryl group, an amino group, an isocyanate group, a mercapto group, and an acid anhydride group. The number of functional groups included in the silane coupling agent may be 1, or 2 or more.

The surface modifier may be used alone or in combination of two or more kinds thereof.

A content of the surface modifier is usually 8% by mass or less, preferably less than 5% by mass, more preferably 3% by mass or less, still more preferably less than 2% by mass, and particularly preferably 1% by mass or less with respect to the total mass of the filler. The lower limit thereof is preferably 0% by mass or more.

The above-described content of the surface modifier means the total content of the surface modifier and the component derived from the surface modifier, covering at least a part of the surface of the filler. In other words, the above-described content of the surface modifier is a value that does not include a surface modifier which does not cover the surface of the filler, that is, a surface modifier which is liberated in the composition.

The content of the surface modifier is not particularly limited, and can be measured, for example, by a method Z.

The composition is applied onto the base material and dried such that the thickness after drying is 10 μm, thereby forming a composition layer. A temperature in the above-described drying is preferably 50° C. to 150° C. and more preferably 70° C. to 100° C. A heating time in the above-described drying is preferably 1 to 10 minutes and more preferably 2 to 7 minutes.

Next, the obtained composition layer is dissolved in a mixed solvent of methyl ethyl ketone (MEK):N-methylpyrrolidone (NMP)=1:1 to obtain a solution. Thereafter, the above-described solution is centrifuged and filtered using a filter to collect a filler before solidification, and the filler before solidification is further dried to obtain a filler for measurement. A temperature in the above-described solidification is preferably 50° C. to 150° C. and more preferably 70° C. to 100° C. A heating time in the above-described solidification is preferably 1 to 120 minutes and more preferably 5 to 30 minutes. The above-described filter can be appropriately selected according to the average particle diameter of the filler.

With the above-described filler for measurement, a weight loss rate is measured three times under conditions of temperature rising (10° C./min) from room temperature to 1,000° C. in an air atmosphere using a TG-DTA device (TG/DTA7300) manufactured by Hitachi High-Tech Science Corporation, and the content of the surface modifier is calculated from the average value thereof.

Examples of the filler include Sea Foster KE-S30 (manufactured by Nippon Shokubai Co., Ltd., silicon dioxide, concentration of solid contents of 100% by mass), NHM-3N (manufactured by TOKUYAMA CORPORATION, silicon dioxide, concentration of solid contents of 100% by mass), YA050C-MJE (manufactured by Admatechs Co., Ltd., silicon dioxide, MEK slurry having a concentration of solid contents of 50% by mass), SFP-20M (manufactured by Denka Company Limited, silicon dioxide), PMA-ST (manufactured by Nissan Chemical Corporation, silicon dioxide), MEK-ST-L (manufactured by Nissan Chemical Corporation, silicon dioxide), MEK-AC-5140Z (manufactured by Nissan Chemical Corporation, silicon dioxide), MEK-EC-2430Z (manufactured by NISSAN CHEMICAL CORPORATION, concentration of solid contents of 30% by mass), barium sulfate (manufactured by SOLVAY SPECIALTY CHEMICALS JAPAN, concentration of solid contents of 100% by mass), NHM-5N (manufactured by Tokuyama Corporation, silicon dioxide, concentration of solid contents: 100% by mass), Y50SP-AM1 (manufactured by Admatechs Co., Ltd., silicon dioxide, MEK slurry having a concentration of solid contents of 50% by mass), and Y50SZ-AM1 (manufactured by Admatechs Co., Ltd., silicon dioxide, MEK slurry having a concentration of solid contents of 50% by mass).

A refractive index of the filler is preferably 0.5 to 3.0 and more preferably 1.2 to 1.8.

The refractive index can be measured by the above-described method.

The filler may be used alone or in combination of two or more kinds thereof.

### [Polymerizable Compound]

It is preferable that the composition further contains a polymerizable compound.

The polymerizable compound is a compound different from the above-described various components.

The polymerizable compound is a compound having one or more polymerizable groups in one molecule.

Examples of the polymerizable group included in the polymerizable compound include a (meth)acryloyl group, a vinyl group, and a styryl group. Among these, a (meth)acryloyl group is preferable, and a methacryloyl group is more preferable.

Examples of the polymerizable compound include a polymerizable compound having one polymerizable group in one molecule (hereinafter, also referred to as “monofunctional polymerizable compound”); a polymerizable compound having two polymerizable groups in one molecule (hereinafter, also referred to as “bifunctional polymerizable compound”); and a polymerizable compound having three or more polymerizable groups in one molecule (hereinafter, also referred to as “tri- or higher functional polymerizable compound”).

The polymerizable compound is preferably a bifunctional polymerizable compound.

Examples the bifunctional polymerizable compound include polyethylene glycol methacrylate, tricyclodecane dimethanol di(meth)acrylate, 1,9-nonanediol di(meth)acrylate, and 1,6-hexanediol di(meth)acrylate. Examples of a commercially available product of the bifunctional polymerizable compound include diethylene glycol dimethacrylate (2G, manufactured by Shin-Nakamura Chemical Co., Ltd.), triethylene glycol dimethacrylate (3G, manufactured by Shin-Nakamura Chemical Co., Ltd.), polyethylene glycol #200 dimethacrylate (4G, manufactured by Shin-Nakamura Chemical Co., Ltd.), tricyclodecane dimethanol diacrylate (A-DCP, manufactured by Shin-Nakamura Chemical Co., Ltd.), 1,9-nonandiol diacrylate (A-NOD-N, manufactured by Shin-Nakamura Chemical Co., Ltd.), and 1,6-hexanediol diacrylate (A-HD-N, manufactured by Shin-Nakamura Chemical Co., Ltd.).

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

The “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of a commercially available product of the polymerizable compound include a caprolactone-modified compound of a (meth)acrylate compound (KAYARAD (registered trademark) DPCA-20 and the like manufactured by Nippon Kayaku Co., Ltd.; and A-9300-1CL and the like manufactured by Shin-Nakamura Chemical Co., Ltd.), an alkylene oxide-modified compound of a (meth)acrylate compound (KAYARAD RP-1040 and the like manufactured by Nippon Kayaku Co., Ltd.; ATM-35E, A-9300, and the like manufactured by Shin-Nakamura Chemical Co., Ltd.; and EBECRYL (registered trademark) 135 manufactured by Daicel-Allnex Ltd.), and ethoxylated glycerin triacrylate (A-GLY-9E and the like manufactured by Shin-Nakamura Chemical Co., Ltd.).

Examples of the polymerizable compound also include urethane (meth)acrylate (preferably, tri- or higher functional urethane (meth)acrylate). The number of polymerizable groups included in the urethane (meth)acrylate is preferably 6 or more, and more preferably 8 or more. The upper limit thereof is 20 or less.

Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (all manufactured by Nippon Kayaku Co., Ltd.).

The polymerizable compound may be used alone or in combination of two or more kinds thereof.

A content of the polymerizable compound is preferably 30.0% by mass or less, more preferably 25.0% by mass or less, and still more preferably 20.0% by mass or less with respect to the total solid content of the composition. The lower limit thereof is preferably 1.0% by mass or more.

### [Photopolymerization Initiator]

The composition may contain a photopolymerization initiator.

The photopolymerization initiator is a compound different from the above-described various components.

Examples of the photopolymerization initiator include a photoradical polymerization initiator, a photocationic polymerization initiator, and a photoanionic polymerization initiator, and a photoradical polymerization initiator is preferable.

Examples of the photopolymerization initiator include an oxime ester compound (photopolymerization initiator having an oxime ester structure), an aminoacetophenone compound (photopolymerization initiator having an aminoacetophenone structure), a hydroxyacetophenone compound (photopolymerization initiator having a hydroxyacetophenone structure), an acylphosphine oxide compound (photopolymerization initiator having an acylphosphine oxide structure), and a bistriphenylimidazole compound (photopolymerization initiator having a bistriphenylimidazole structure).

As the photopolymerization initiator, an oxime ester compound or an aminoacetophenone compound is preferable, and an oxime ester compound is more preferable.

Examples of the oxime ester compound include 1,2-octanedione, 1-[4-(phenylthio)phenyl-,2-(O-benzoyloxime)](product name: IRGACURE OXE-01; manufactured by BASF SE), etanone,1-[9-ethyl-6-(2-methylbenzoyl)-9H-carbazol-3-yl]-,1-(O-acetyloxime) (product name: IRGACURE OXE-02, manufactured by BASF SE), [8-[5-(2,4,6-trimethylphenyl)-11-(2-ethylhexyl)-11H-benzo[a]carbazoyl][2-(2,2,3,3-tetrafluoropropoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(O-acetyloxime) (product name: IRGACURE OXE-04, manufactured by BASF SE, and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(0-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad series are manufactured by IGM Resins B.V), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the photopolymerization initiator also include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl) phenylphosphine oxide (product name: Omnirad 819).

Examples the photopolymerization initiator also include photopolymerization initiators described in paragraphs 0031 to 0042 of JP2011-095716A and paragraphs 0064 to 0081 of JP2015-014783A.

The photopolymerization initiator may be used alone or in combination of two or more kinds thereof.

A content of the photopolymerization initiator is preferably 10.0% by mass or less, more preferably 5.0% by mass or less, and still more preferably 1.0% by mass or less with respect to the total solid content of the composition. The lower limit thereof is preferably 0.1% by mass or more.

### [Thermal-Base Generator]

The composition may contain a thermal-base generator.

In a case where the composition contains a thermal-base generator, the ring closure reaction of the polyimide precursor and the polybenzoxazole precursor is promoted, and the polyimide and the polybenzoxazole are likely to be generated, which may result in excellent cycle thermo characteristics.

As the thermal-base generator, an acidic compound or an onium salt compound (a compound consisting of a cation and an anion), which generates a base by heating, is preferable.

As the onium salt compound, an ammonium salt compound (a compound consisting of an ammonium cation and an anion), an iminium salt compound (a compound consisting of an iminium cation and an anion), a sulfonium salt compound (a compound consisting of a sulfonium cation and an anion), an iodonium salt compound (a compound consisting of an iodonium cation and an anion), or a phosphonium salt compound (a compound consisting of a phosphonium cation and an anion) is preferable; and an iminium salt compound is more preferable.

As the anion constituting the onium salt compound, a carboxylate anion, a phenolate anion, a phosphate anion, or a sulfate anion is preferable; and a carboxylate anion is more preferable.

It is preferable that the anion constituting the ammonium salt compound further has an aromatic ring.

Examples of the above-described aromatic ring include an aromatic ring constituting an aromatic ring group represented by A^{a1} in Formula (A1) described later.

A temperature at which the above-described acidic compound and the above-described onium salt compound generate a base is preferably a heating temperature of a step X4 in a manufacturing method of a laminate described later.

A temperature at which the thermal-base generator generates a base can be obtained, for example, by heating a compound to be measured in a pressure-resistant capsule to 250° C. at 5° C./min using differential scanning calorimetry, reading a peak temperature of an exothermic peak at the lowest temperature, and setting the peak temperature as a base generation temperature.

The base generated by the thermal-base generator is preferably a secondary amine or a tertiary amine, and more preferably a tertiary amine. The above-described base may be linear, branched, or cyclic, and is preferably cyclic.

As the acidic compound, a compound represented by Formula (A1) is preferable.

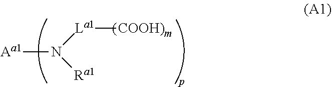

In Formula (A1), A^{a1} represents a p-valent organic group, R^{a1} represents a monovalent organic group, L^{a1} represents an (m+1)-valent linking group, m represents an integer of 1 or more, and p represents an integer of 1 or more.

In Formula (A1), A^{a1} represents a p-valent organic group.

Examples of the above-described organic group include an aliphatic hydrocarbon group and an aromatic ring group; and an aromatic ring group is preferable.

Examples of a monovalent aliphatic hydrocarbon group include an alkyl group and an alkenyl group.

The above-described alkyl group may be linear, branched, or cyclic.

The number of carbon atoms in the above-described alkyl group is preferably 1 to 30, more preferably 1 to 20, and still more preferably 1 to 10.

Examples of the above-described alkyl group include a methyl group, an ethyl group, a tert-butyl group, a dodecyl group, a cyclopentyl group, a cyclohexyl group, a cycloheptyl group, and an adamantyl group.

The alkenyl group may be linear, branched, or cyclic.

The number of carbon atoms in the alkenyl group is preferably 2 to 30, more preferably 2 to 20, and still more preferably 2 to 10.

Examples of the alkenyl group include a vinyl group, an allyl group, and a methallyl group.

Examples of the p-valent (p is an integer of 2 or more) aliphatic hydrocarbon group include a group formed by removing (p-1) hydrogen atoms from the above-described monovalent aliphatic hydrocarbon group.

The aliphatic hydrocarbon group may further have a substituent.

The aromatic ring group may be monocyclic or polycyclic.

The aromatic ring group may be any one of an aromatic hydrocarbon ring group or an aromatic heterocyclic group.

Examples of the aromatic ring group include a benzene ring group, a naphthalene ring group, a biphenyl ring group, a fluorene ring group, a pentalene ring group, an indene ring group, an azulene ring group, a heptalene ring group, an indacene ring group, a perylene ring group, a pentacene ring group, an acenaphthene ring group, a phenanthrene ring group, an anthracene ring group, a naphthacene ring group, a chrysene ring group, and a triphenylene ring group, a fluorene ring group, a biphenyl ring group, a pyrrole ring group, a furan ring group, a thiophene ring group, an imidazole ring group, an oxazole ring group, a thiazole ring group, a pyridine ring group, a pyrazine ring group, a pyrimidine ring group, a pyridazine ring group, an indridine ring group, an indole ring group, a benzofuran ring group, a benzothiophene ring group, an isobenzofuran ring group, a quinolizine ring group, a quinoline ring group, a phthalazine ring group, a naphthyridine ring group, a quinoxaline ring group, a quinoxazoline ring group, an isoquinoline ring group, a carbazole ring group, a phenanthridine ring group, an acridine ring group, a phenanthroline ring group, a thianthrene ring group, a chromene ring group, a xanthene ring group, a phenoxathiin ring group, a phenothiazine ring group, and a phenazine ring group; and a benzene ring group is preferable.

The aromatic ring group may further have a substituent.

In Formula (A1), R^{a1} represents a monovalent organic group.

Examples of the monovalent organic group include the monovalent aliphatic hydrocarbon group and the monovalent aromatic ring group represented by A^{a1}.

The monovalent organic group may further have a substituent. The above-described substituent is preferably a carboxy group.

In Formula (A1), Lai represents an (m+1)-valent linking group.

Examples of the (m+1)-valent linking group include a divalent linking group such as an ether group (—O—), a carbonyl group (—CO—), an ester group (—COO—), a thioether group (—S—), —SO₂—, —NR^{N}— (R^{N} represents a hydrogen atom or a substituent), an alkylene group (preferably having 1 to 10 carbon atoms), and an alkenylene group (preferably having 2 to 10 carbon atoms); a trivalent linking group having a group represented by “—N<” and a trivalent linking group having a group represented by “—CR<” (R represents a hydrogen atom or a substituent); a tetravalent linking group having a group represented by “>C<”; a k-valent linking group having a ring group such as an aromatic ring group and an alicyclic ring group; and a group formed by a combination of these groups.

In Formula (A1), m represents an integer of 1 or more.

m is preferably 1 or 2, and more preferably 1.

In Formula (A1), p represents an integer of 1 or more.

p is preferably 1 or 2, and more preferably 1.

As the ammonium cation constituting the ammonium salt compound, a cation represented by Formula (101) is preferable.

As the iminium cation constituting the iminium salt compound, a cation represented by Formula (102) is preferable.

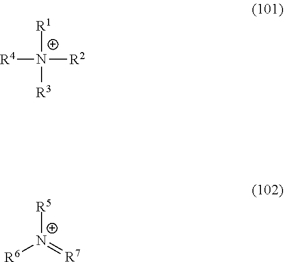

In Formula (101), R¹ to R⁴ each independently represent a hydrogen atom or an aliphatic group, and at least two of R¹ to R⁴ may be bonded to each other to form a ring.

In Formula (102), R⁵ and R⁶ each independently represent a hydrogen atom or an aliphatic group, R⁷ represents an aliphatic group, and at least two of R⁵ to R⁷ may be bonded to each other to form a ring.

The aliphatic group represented by R¹ to R⁴ and R⁵ to R⁷ may be linear, branched, or cyclic.

The number of carbon atoms in the above-described aliphatic group is preferably 1 to 10.

The above-described aliphatic group is preferably an alkyl group or an alkenyl group, and more preferably an alkyl group.

The above-described aliphatic group may have a substituent. Examples of the substituent include an arylcarbonyl group.

In addition, in the above-described aliphatic group, a methylene group (—CH₂—) in the group may be replaced with a heteroatom (for example, an oxygen atom, a sulfur atom, —NR—, and the like; R represents a hydrogen atom or a substituent).

At least one of R⁵ to R⁷ is preferably an aliphatic group having —NR—, and more preferably an alkyl group having —NR—.

At least two of R⁵ to R⁷ may be bonded to each other to form a ring, and it is preferable that R⁵ and R⁷, and R⁶ and R⁷ are bonded to each other to form a ring. In other words, the above-described ring is preferably a polycyclic heterocycle and more preferably a bicyclic heterocycle.

Examples of the thermal-base generator include thermal-base generators described in WO2018/038002A.

The thermal-base generator may be used alone or in combination of two or more kinds thereof.

A content of the thermal-base generator is preferably 10.0% by mass or less, more preferably 5.0% by mass or less, and still more preferably 1.0% by mass or less with respect to the total solid content of the composition. The lower limit thereof is preferably more than 0% by mass, and more preferably 0.1% by mass or more.

A mass ratio of the content of the thermal-base generator to the content of the resin X (Content of thermal-base generator/Content of resin X) is preferably 1.00 or less, more preferably 0.10 or less, and still more preferably 0.05 or less. The lower limit thereof is preferably more than 0.

### [Compound Y]

The composition may contain a compound Y.

The compound Y is a compound which does not have an ethylenically polymerizable group and has a boiling point of 300° C. or higher.

The compound Y is a compound different from both the above-described photopolymerization initiator and the above-described thermal-base generator.

By containing the compound Y in the composition, in a case where a transfer film having a composition layer formed of the composition is bonded (laminated) to an adherend, and a pattern is formed by an exposure treatment, a development treatment, and a heating treatment after the development, the compound Y functions as a component for ensuring plasticity of the resin such as the resin X in the photosensitive layer, and is removed by volatilization by being subjected to the heating treatment after the development, and thus is likely to be hardly remain in the system of the pattern.

The boiling point of the compound Y is 300° C. or higher, preferably 350° C. or higher. The upper limit thereof is preferably 500° C. or lower, more preferably 480° C. or lower, and still more preferably 450° C. or lower.

In the present specification, the above-described boiling point of the compound Y is a value obtained by the following measuring method.

In a case where the compound Y is distilled under normal pressure (760 mmHg), a temperature of a gas at a point in time when condensation of the evaporated gas starts is defined as the boiling point (measured at 23° C. to 300° C.; temperature rising rate: 1° C./min).

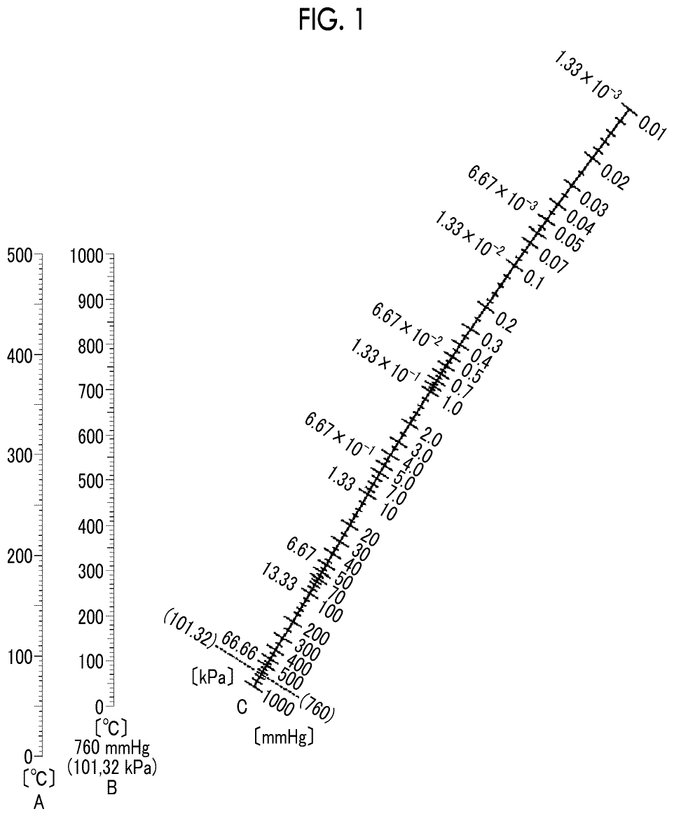

The compound Y is distilled using a Liebig condenser, and in a case where the distillation does not start at 300° C. under normal pressure, the compound Y is distilled under reduced pressure. The same distillation is carried out in the order of an atmospheric pressure of 100 mmHg, 50 mmHg, and 5 mmHg (measured at 23° C. to 300° C.; temperature rising rate: 1° C./min; in a case where the distillation does not start at 300° C., the distillation is carried out at the next pressure), and the boiling point under normal pressure is defined as the boiling point (calculated value) obtained using a nomograph shown in FIG. 1 (source: Science of Petroleum, Vol. II, p. 1281 (1938)), from the temperature and pressure at which the condensation of the evaporated gas starts. In a case where the distillation does not start at 300° C. under 5 mmHg, the boiling point under normal pressure is considered to be higher than 500° C. The nomograph is used by a known method. Specifically, a boiling point of the Aline under reduced pressure and a degree of reduction of the C line are connected by a straight line (procedure 1), a numerical value of an intersection of the straight line drawn in the procedure 1 and the B line is read (procedure 2), and this is regarded as the boiling point under normal pressure.

A molecular weight of the compound Y is preferably 200 or more, more preferably 250 or more, and still more preferably 300 or more. The upper limit is preferably 1,000 or less, more preferably 800 or less, and still more preferably 600 or less.

In a case where the compound Y has a molecular weight distribution, the above-described molecular weight of the compound Y is intended to be a weight-average molecular weight.

A viscosity of the compound Y at 25° C. is preferably 500 mPa·s or less, more preferably 300 mPa·s or less, and still more preferably 100 mPa·s or less. The lower limit thereof is preferably 0.01 mPa·s or more, more preferably 0.05 mPa·s or more, and still more preferably 0.1 mPa·s or more.

The viscosity can be measured with a B-type viscometer.

Examples of the compound Y include ethylphthalyl ethyl glycolate, dihexyl phthalate, tributyl o-acetyl citrate, benzyl 2-ethylhexyl phthalate, benzyl benzoate, hexaethylene glycol monomethyl ether, pentaethylene glycol monomethyl ether, tetraethylene glycol monomethyl ether, heptaethylene glycol monomethyl ether, octaethylene glycol monomethyl ether, nonaethylene glycol monomethyl ether, pentaethylene glycol dimethyl ether, hexaethylene glycol dimethyl ether, heptaethylene glycol dimethyl ether, octaethylene glycol dimethyl ether, nonaethylene glycol dimethyl ether, bis(2-ethylhexyl) isophthalate, triamyl phosphate, tris(2-butoxyethyl) phosphate, triethylene glycol bis(2-ethylhexanoate), tris(2-ethylhexyl) trimellitate, and bis(2-butoxyethyl) adipate.

The compound Y may be used alone or in combination of two or more kinds thereof.

The content of the compound Y is preferably 1.0% by mass or more, more preferably 3.0% by mass or more, and still more preferably 5.0% by mass or more with respect to the total solid content of the composition. The upper limit thereof is preferably 60.0% by mass or less, more preferably 50.0% by mass or less, still more preferably 35.0% by mass or less, and particularly preferably 25.0% by mass or less.

The total content of the polymerizable compound and the compound Y is preferably 50.0% by mass or less, more preferably 30.0% by mass or less, and still more preferably 25.0% by mass or less with respect to the total solid content of the composition.

### [Photoacid Generator]

The composition may contain a photoacid generator.

The photoacid generator is a compound which generates an acid by light (for example, exposure light).

Examples of the photoacid generator include an ionic photoacid generator and a nonionic photoacid generator.

Examples of the ionic photoacid generator include a compound having a sulfonium structure, an onium salt compound having a diaryliodonium structure or a triarylsulfonium structure, and an ammonium salt compound having a quaternary ammonium structure. Examples of the ionic photoacid generator also include ionic photoacid generators described in paragraphs 0114 to 0133 of JP2014-085643A.

Examples of the nonionic photoacid generator include trichloromethyl-s-triazine and derivatives thereof (trichloromethyl-s-triazine which may have a substituent), a compound having a diazomethane structure, a compound having an imidosulfonate structure, and a compound having an oxime sulfonate structure. Examples of the trichloromethyl-s-triazine and derivatives thereof, the diazomethane compound, and the imidosulfonate compound include compounds described in paragraphs 0083 to 0088 of JP2011-221494A. In addition, examples of the oxime sulfonate compound include compounds described in paragraphs 0084 to 0088 of WO2018/179640A.

The photoacid generator may be used alone or in combination of two or more kinds thereof.

A content of the photoacid generator is preferably 0.1% to 10.0% by mass and more preferably 0.5% to 5.0% by mass with respect to the total solid content of the composition.

### [Surfactant]

The composition may contain a surfactant.

Examples of the surfactant include surfactants described in paragraph 0017 of JP4502784B and paragraphs 0060 to 0071 of JP2009-237362A.

Examples of the surfactant include a hydrocarbon-based surfactant, a fluorine-based surfactant, and a silicone-based surfactant. From the viewpoint of improving environmental suitability, it is preferable that the surfactant does not contain a fluorine atom. As the surfactant, a hydrocarbon-based surfactant or a silicone-based surfactant is preferable.

Examples of a commercially available product of the fluorine-based surfactant include MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, and F-780 (all of which are manufactured by DIC Corporation); EXP.MFS-324, EXP.MFS-330, EXP.MFS-578, EXP.MFS-578-2, EXP.MFS-579, EXP.MFS-586, EXP.MFS-587, EXP.MFS-628, EXP.MFS-631, EXP.MFS-603, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED); and U-120E (Uni-chem Co., Ltd.).

Examples of the fluorine-based surfactant include an acrylic compound which has a molecular structure including a functional group having a fluorine atom and in which the functional group having a fluorine atom is broken to volatilize a fluorine atom by applying heat to the molecular structure. Examples of such a fluorine-based surfactant include MEGAFACE DS series (manufactured by DIC Corporation; The Chemical Daily, Feb. 22, 2016; Nikkei Business Daily, Feb. 23, 2016), MEGAFACE DS-21, and the like).

In addition, the fluorine-based surfactant may be a polymer of a fluorine atom-containing vinyl ether compound having a fluorinated alkyl group or a fluorinated alkylene ether group, and a hydrophilic vinyl ether compound. The fluorine-based surfactant may be a block polymer.

As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) may be used.

In addition, examples of the fluorine-based surfactant also include a fluorine-containing polymer having a group having an ethylenically unsaturated group in a side chain. Specific examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the hydrocarbon-based surfactant include glycerol, trimethylolpropane, trimethylolethane, and ethoxylate and propoxylate thereof (for example, glycerol propoxylate, glycerol ethoxylate, and the like), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester.

Examples of the hydrocarbon-based surfactant include PLURONIC (registered trademark) L10, L31, L61, L62, 10R5, 17R2, and 25R2, TETRONIC 304, 701, 704, 901, 904, and 150R1, and HYDROPALAT WE 3323 (all of which are manufactured by BASF); Solsperse 20000 (manufactured by Nippon Lubrizol Corporation); NCW-101, NCW-1001, and NCW-1002 (all of which are manufactured by FUJIFILM Wako Pure Chemical Corporation); Pionin D-1105, D-6112, D-6112-W, and D-6315 (all of which are manufactured by TAKEMOTO OIL & FAT Co., Ltd.); and OLFINE E1010, and SURFYNOL 104, 400, and 440 (all of which are manufactured by Nissin Chemical Co., Ltd.).

Examples of the silicone-based surfactant include a linear polymer including a siloxane bond, a modified siloxane polymer in which an organic group is introduced into a side chain and/or a terminal, and a polymer having a repeating unit having a hydrophilic group in a side chain and a repeating unit having a siloxane bond-containing group in a side chain. As the silicone-based surfactant, a polymer having a repeating unit having a hydrophilic group in a side chain and a repeating unit having a siloxane bond-containing group in a side chain is preferable. The above-described polymer may be either a random copolymer or a block copolymer.

As the repeating unit having a siloxane bond-containing group in a side chain, a repeating unit represented by Formula (SX1) or a repeating unit represented by Formula (SX2) is preferable.

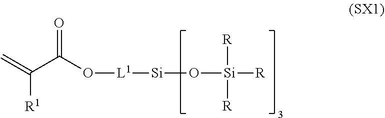

In Formula (SX1), R's each independently represent an alkyl group having 1 to 3 carbon atoms, R¹ represents a hydrogen atom or a methyl group, L¹ represents a single bond or a divalent organic group, and
in a case of a plurality of R's, R's may be the same or different from each other.

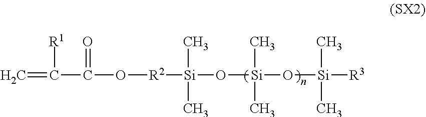

In Formula (SX2), R¹ represents a hydrogen atom or a methyl group, R² represents an alkylene group having 1 to 10 carbon atoms, R³ represents an alkyl group having 1 to 4 carbon atoms, and n represents an integer of 5 to 50.

As the repeating unit having a hydrophilic group in a side chain, a repeating unit represented by Formula (SX3) is preferable.

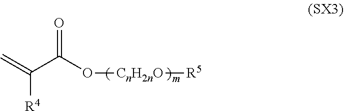

In Formula (SX3), R⁴ and R⁵ each independently represent a hydrogen atom or a methyl group, n represents an integer of 1 to 4, and q represents an integer of 1 to 100.

Examples of the silicone-based surfactant include EXP.S-309-2, EXP.S-315, EXP.S-503-2, and EXP.S-505-2 (all of which are manufactured by DIC Corporation); DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KF-6001, KF-6002, KP-101, KP-103, KP-104, KP-105, KP-106, KP-109, KP-112, KP-120, KP-121, KP-124, KP-125, KP-301, KP-306, KP-310, KP-322, KP-323, KP-327, KP-341, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK325, BYK330, BYK313, BYK315N, BYK331, BYK333, BYK345, BYK347, BYK348, BYK349, BYK370, BYK377, BYK378, and BYK323 (all of which are manufactured by BYK Chemie).

In addition, examples of the surfactant also include a nonionic surfactant.

The surfactant may be used alone or in combination of two or more kinds thereof.

A content of the surfactant is preferably 0.01% to 3.0% by mass, more preferably 0.01% to 1.0% by mass, and still more preferably 0.05% to 0.8% by mass with respect to total solid content of the composition.

### [Other Additives]

The composition may contain an additive other than the above-described various components.

Examples of other additives include a heterocyclic compound (for example, triazole, benzotriazole, and tetrazole, derivatives thereof, and the like), an aliphatic thiol compound, a thermal crosslinking compound, a polymerization inhibitor, a hydrogen donating compound, a solvent, impurities, a plasticizer, a sensitizer, and an alkoxysilane compound.

Examples of the heterocyclic compound, the aliphatic thiol compound, the thermal crosslinking compound, the polymerization inhibitor, and the hydrogen donating compound include various components described in WO2022/039027A.

Examples of the plasticizer, the sensitizer, and the alkoxysilane compound include those described in paragraphs 0097 to 0119 of WO2018/179640A.

The solvent is not particularly limited as long as it can dissolve or disperse the various components which can be contained in the composition, other than the solvent.

Examples of the solvent include water, an alkylene glycol ether solvent, an alkylene glycol ether acetate solvent, an alcohol solvent (for example, methanol, ethanol, and the like), a ketone solvent (for example, acetone, methyl ethyl ketone, and the like), an aromatic hydrocarbon solvent (for example, toluene and the like), an aprotic polar solvent (for example, N,N-dimethylformamide and the like), a cyclic ether solvent (for example, tetrahydrofuran and the like), an ester solvent (for example, n-propyl acetate and the like), an amide solvent, a lactone solvent, and a solvent including two or more kinds thereof.

The solvent may be used alone or in combination of two or more kinds thereof.

A content of the solvent is preferably 50 to 1,900 parts by mass, more preferably 100 to 1,200 parts by mass, and still more preferably 100 to 900 parts by mass with respect to 100 parts by mass of the total solid content of the composition.

The composition may contain impurities.

Examples of the impurities include sodium, potassium, magnesium, calcium, iron, manganese, copper, aluminum, titanium, chromium, cobalt, nickel, zinc, tin, halogen, and ions of these. Since the halide ion, the sodium ion, and the potassium ion (preferably, the sodium ion and the chloride ion) are likely to be mixed in as the impurities, the content thereof is preferably set to the following content.

In a case where the composition does not contain impurities (particularly, sodium ions or chloride ions), or in a case where the composition contains impurities, a content of the impurities is usually 100 ppm by mass or less, preferably 80 ppm by mass or less, more preferably less than 50 ppm by mass, still more preferably 10 ppm by mass or less, particularly preferably less than 10 ppm by mass, and most preferably 2 ppm by mass or less with respect to the total solid content of the composition. The lower limit thereof is usually 0 ppb by mass or more with respect to the total solid content of the composition, preferably 1 ppb by mass or more, and more preferably 0.1 ppb by mass or more.

Specific examples of the amount of impurities in the composition include a chloride ion concentration of 15 ppm, a bromide ion concentration of 1 ppm, a sodium ion concentration of 5 ppm, and an iron ion concentration of 1 ppm with respect to the total solid content of the composition.

Examples of a method for adjusting the content of the impurities include a method of using raw materials having a low content of impurities as raw materials of the various components contained in the composition; a method of purifying the various components contained in the composition; and a method of preventing the impurities from being mixed in the composition during the preparation of the composition.

In particular, examples of a method for adjusting the contents of the sodium ion and the chloride ion include a method of subjecting the filler to a surface treatment with a surface modifier having a low content of the surface modifier and a low content of impurities.

The content of the impurities can be quantified by a known method such as inductively coupled plasma (ICP) emission spectroscopy, atomic absorption spectroscopy, and ion chromatography. In a case where ion chromatography is used, for example, using ICS-2100 manufactured by Thermo Fisher Scientific Inc. as an analysis apparatus, a measurement can be performed at a column temperature of 35° C. using IonPac AS11HC manufactured by Thermo Fisher Scientific Inc. as a column in a case where the measurement target is an anion, and using IonPac CS12 manufactured by Thermo Fisher Scientific Inc. as a column in a case where the measurement target is a cation.

In the composition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low. Specifically, the content of these compounds is preferably 100 ppm by mass or less, more preferably 20 ppm by mass or less, and still more preferably 4 ppm by mass or less with respect to the total solid content of the composition. The lower limit thereof may be 10 ppb by mass or more or 100 ppb by mass or more with respect to the total solid content of the composition.

The content of these compounds can be adjusted by the same method as that for the above-described impurities. In addition, these compounds can be quantified by a known measuring method.

The film formed of the composition preferably exhibits each physical property value described below.

In particular, it is preferable that a film formed of the compositions of the embodiments Y1 to Y3 described above exhibits [Physical property value A] described later, and a film formed of the compositions of the embodiments Z1 and Z2 described above exhibits [Physical property value B] described later.

### [Physical Property Value A]

An average value X of coefficients of thermal expansion of a film obtained by a method A in a range of 50° C. to 100° C. is preferably 20 ppm/K or less, more preferably 17 ppm/K or less. The lower limit thereof is preferably 0 ppm/K or more.

The average value X of the coefficients of thermal expansion can be measured using a thermomechanical analyzer (TMA, TMA450EM manufactured by TA Instruments). For example, a coefficient of thermal expansion at each temperature is measured under measurement conditions of a temperature rising rate of 10° C./min, a chuck-to-chuck distance of 16 mm, a weighting of 49 mN, and a temperature range of −60° C. to 350° C.; and an average value of the coefficients of thermal expansion in a range of 50° C. to 100° C. is calculated from the obtained results. The number of trials of measurement is set to 3, and an arithmetic mean value thereof is defined as the average value X.

In the method A, a composition layer is formed on a base material using the composition, the composition layer is exposed at an integrated illuminance of 100 mJ/cm² using a high pressure mercury lamp, and the exposed composition layer is heat-treated at 230° C. for 8 hours, immersed in a 2 M hydrochloric acid for 8 hours, rinsed with water, and peeled off from the base material to obtain a film (hereinafter, also referred to as “film A for measurement”).

In a case where the film A for measurement cannot be peeled off from the base material in the above-described method A, the film A for measurement may be obtained by further immersing the film A for measurement in a 2 M hydrochloric acid for about one week, and then performing the above-described rinsing treatment.

Examples of the base material in the method A include a base material in a manufacturing method of a laminate described later, and a copper base material is preferable.

Examples of the method of forming the composition layer using the composition include a method of forming a composition layer in a manufacturing method of a transfer film.

Examples of the method of the rinsing treatment include known methods such as immersion treatment and spray cleaning.

As the water used in the rinsing treatment, pure water is preferable. A liquid temperature of the above-described water is preferably normal temperature (for example, 20° C.). A time for the rinsing treatment is preferably 10 minutes to 2 hours.

The exposure may be a full-surface exposure or a pattern exposure, and a full-surface exposure is preferable.

A ratio of an average value Y of coefficients of thermal expansion of the film obtained by the method A in a range of 190° C. to 210° C. to an average value X of coefficients of thermal expansion of the film in a range of 50° C. to 100° C. (Average value Y/Average value X) is preferably 2.0 or less, and more preferably 0.9 to 2.0.

The average value X and the measuring method thereof are as described above.

The average value Y is preferably 40 ppm/K or less, and more preferably 15 ppm/K or less. The lower limit thereof is preferably 0 ppm/K or more.

The measuring method of the average value Y is the same as the measuring method of the average value X described above, except that the temperature range to be calculated is changed to a range of 190° C. to 210° C.

An average relative permittivity of the film obtained by the method A at 28 GHz is preferably 3.5 or less, and more preferably 3.0 or less. The lower limit thereof is not particularly limited, but is often 1.0 or more, and more often 2.0 or more.

The above-described average relative permittivity can be measured using, for example, a split cylinder-type resonator (manufactured by Kanto Electronics Application & Development Inc.). The number of trials of measurement is set to 3, and an arithmetic mean value thereof is defined as the average relative permittivity.

An average dielectric loss tangent of the film obtained by the method A at 28 GHz is preferably 0.0030 or less, and more preferably 0.0020 or less. The lower limit thereof is not particularly limited, but is often 0.0001 or more, and more often 0.0005 or more.

The above-described average dielectric loss tangent can be measured using, for example, a split cylinder-type resonator (manufactured by Kanto Electronics Application & Development Inc.). The number of trials of measurement is set to 3, and an arithmetic mean value thereof is defined as the average dielectric loss tangent.

The above-described method A is a method of forming a composition layer on a base material using a composition, but the composition layer may be formed on the base material using a transfer film instead of the composition.

Examples of the method of forming the composition layer on the base material using the above-described transfer film include a transfer method in a step X1.

### [Physical Property Value B]

An average value X of coefficients of thermal expansion of a film obtained by a method B in a range of 50° C. to 100° C. is preferably 20 ppm/K or less, more preferably 17 ppm/K or less. The lower limit thereof is preferably 0 ppm/K or more.

The measuring method of the average value X of the coefficients of thermal expansion is the same as the measuring method of the average value X of the coefficients of thermal expansion described in the physical property value A.

In the method B, a composition layer is formed on a base material using the composition, and the composition layer is heat-treated at 230° C. for 8 hours, immersed in a 2 M hydrochloric acid for 8 hours, rinsed with water, and peeled off from the base material to obtain a film (hereinafter, also referred to as “film B for measurement”).

In a case where the film B for measurement cannot be peeled off from the base material in the above-described method B, the film B for measurement may be obtained by further immersing the film B for measurement in a 2 M hydrochloric acid for about one week, and then performing the above-described rinsing treatment.

Examples of the base material in the method B include a base material in a manufacturing method of a laminate described later, and a copper base material is preferable.

Examples of the method of forming the composition layer using the composition include a method of forming a composition layer in a manufacturing method of a transfer film.

Examples of the method of the rinsing treatment include known methods such as immersion treatment and spray cleaning.

As the water used in the rinsing treatment, pure water is preferable. A liquid temperature of the above-described water is preferably normal temperature (for example, 20° C.). A time for the rinsing treatment is preferably 10 minutes to 2 hours.

The exposure may be a full-surface exposure or a pattern exposure, and a full-surface exposure is preferable.

A ratio of an average value Y of coefficients of thermal expansion of the film obtained by the method B in a range of 190° C. to 210° C. to an average value X of coefficients of thermal expansion of the film in a range of 50° C. to 100° C. (Average value Y/Average value X) is preferably 2.0 or less, and more preferably 0.9 to 2.0.

The average value X and the measuring method thereof are as described above.

The average value Y is preferably 40 ppm/K or less, and more preferably 15 ppm/K or less. The lower limit thereof is preferably 0 ppm/K or more.

The measuring method of the average value Y is the same as the measuring method of the average value X described above, except that the temperature range to be calculated is changed to a range of 190° C. to 210° C.

An average relative permittivity of the film obtained by the method B at 28 GHz is preferably 3.5 or less, and more preferably 3.0 or less. The lower limit thereof is not particularly limited, but is often 1.0 or more, and more often 2.0 or more.

The above-described average relative permittivity can be measured using, for example, a split cylinder-type resonator (manufactured by Kanto Electronics Application & Development Inc.). The number of trials of measurement is set to 3, and an arithmetic mean value thereof is defined as the average relative permittivity.

An average dielectric loss tangent of the film obtained by the method B at 28 GHz is preferably 0.0030 or less, and more preferably 0.0020 or less. The lower limit thereof is not particularly limited, but is often 0.0001 or more, and more often 0.0005 or more.

The above-described average dielectric loss tangent can be measured using, for example, a split cylinder-type resonator (manufactured by Kanto Electronics Application & Development Inc.). The number of trials of measurement is set to 3, and an arithmetic mean value thereof is defined as the average dielectric loss tangent.

The above-described method B is a method of forming a composition layer on a base material using a composition, but the composition layer may be formed on the base material using a transfer film instead of the composition.

Examples of the method of forming the composition layer on the base material using the above-described transfer film include a transfer method in a step X1.

### [Transfer Film]

The transfer film includes a temporary support, and a composition layer formed of the above-described composition.

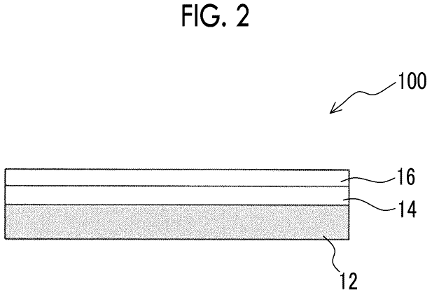

FIG. 2 is a schematic cross-sectional view showing an example of the embodiment of the transfer film.

A transfer film 100 shown in FIG. 2 has a configuration in which a temporary support 12, a composition layer 14, and a cover film 16 are laminated in this order.

The transfer film 100 shown in FIG. 2 has a form in which the cover film 16 is provided, but the transfer film may have a form in which the cover film 16 is not provided. In addition, as will be described later, the transfer film may further include an interlayer and/or a thermoplastic resin layer.

Hereinafter, each member included in the transfer film will be described in detail.

### [Temporary Support]

The transfer film includes a temporary support.

The temporary support is a member which supports the composition layer, and is finally removed by a peeling treatment.

The temporary support may have a monolayer structure or a multilayer structure.

The temporary support is preferably a film and more preferably a resin film.

As the temporary support, a film which has flexibility and does not generate significant deformation, contraction, or stretching under pressure or under pressure and heating is also preferable. Examples of the above-described film include a polyethylene terephthalate film (for example, a biaxially stretched polyethylene terephthalate film and the like), a polymethyl methacrylate film, a cellulose triacetate film, a polystyrene film, a polyimide film, and a polycarbonate film; and a polyethylene terephthalate film is preferable. In addition, it is preferable that the temporary support does not have deformation such as wrinkles and scratches.

From the viewpoint that pattern exposure through the temporary support can be performed, the temporary support preferably has high transparency. Specifically, any of transmittances at a wavelength of 313 nm, at a wavelength of 365 nm, at a wavelength of 405 nm, and at a wavelength of 436 nm is preferably 60% or more, more preferably 70% or more, still more preferably 80% or more, and most preferably 90% or more. The upper limit thereof is preferably less than 100%. Examples of a preferred value of any of the transmittances at each of the wavelengths described above include 87%, 92%, and 98%.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less. The lower limit thereof is preferably 0% or more.

From the viewpoint of pattern formability during the pattern exposure through the temporary support and transparency of the temporary support, it is preferable that the number of fine particles, foreign substances, and defects contained in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is preferably 5 to 200 μm, and from the viewpoint of ease of handling and general-purpose properties, it is more preferably 5 to 150 μm, still more preferably 5 to 50 μm, and particularly preferably 5 to 35 μm.

The thickness of the temporary support can be obtained as an average value of 5 random points measured by cross-sectional observation with a scanning electron microscope (SEM).

In order to improve adhesiveness between the temporary support and the composition layer, a surface of the temporary support in contact with the composition layer may be surface-modified by UV irradiation, corona discharge, plasma, or the like.

In a case where the surface is modified by UV irradiation, an exposure amount of the UV irradiation is preferably 10 to 2,000 mJ/cm² and more preferably 50 to 1,000 mJ/cm².

Examples of a light source for the UV irradiation include a low pressure mercury lamp, a high pressure mercury lamp, an ultra-high pressure mercury lamp, a carbon arc lamp, a metal halide lamp, a xenon lamp, a chemical lamp, an electrodeless discharge lamp, and a light emitting diode, all of which emit light in a wavelength range of 150 to 450 nm.

The lamp output and the illuminance can be appropriately adjusted.

Examples of the temporary support include a biaxial stretching polyethylene terephthalate film having a film thickness of 16 μm, a biaxial stretching polyethylene terephthalate film having a film thickness of 12 μm, and a biaxial stretching polyethylene terephthalate film having a film thickness of 9 μm.

The temporary support may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

Examples of the temporary support include temporary supports described in paragraphs 0017 and 0018 of JP2014-085643A, paragraphs 0019 to 0026 of JP2016-027363A, paragraphs 0041 to 0057 of WO2012/081680A, and paragraphs 0029 to 0040 of WO2018/179370A, the contents of which are incorporated in the present specification.

The temporary support may have a layer (lubricant layer) containing fine particles on one or both surfaces of the temporary support, from the viewpoint of imparting handleability. A diameter of the fine particles contained in the lubricant layer is preferably 0.05 to 0.8 μm. A film thickness of the lubricant layer is preferably 0.05 to 1.0 μm.

Examples of a commercially available product of the temporary support include LUMIRROR 16FB40, LUMIRROR 16KS40, LUMIRROR #38-U48, LUMIRROR #75-U34, and LUMIRROR #25T60 (all of which are manufactured by Toray Industries, Inc.); and COSMOSHINE A4100, COSMOSHINE A4160, COSMOSHINE A4300, COSMOSHINE A4360, and COSMOSHINE A8300 (all of which are manufactured by TOYOBO Co., Ltd.).

### [Composition Layer]

The composition layer is a layer formed of the above-described composition.

Various components which can be contained in the composition layer are synonymous with the various components which can be contained in the composition described above, and suitable aspects thereof are also the same.

However, suitable numerical ranges of contents of the various components in the composition layer are the same as suitable ranges in which “content (% by mass) of various components with respect to the total solid content of the composition” described above is read as “content (% by mass) of various components with respect to the total mass of the composition layer”. Specifically, the description that “the content of the resin X is preferably 5.0% by mass or more with respect to the total solid content of the composition” is read as “the content of the resin X is preferably 5.0% by mass or more with respect to the total mass of the composition layer”.

From the viewpoint of improving reliability, improving handleability of the transfer film, and improving laminating properties, a moisture content of the composition layer is preferably 3.0% by mass or less, more preferably 2.0% by mass or less, and still more preferably 1.0% by mass or less with respect to the total mass of the composition layer. The lower limit thereof is preferably 0.0001% by mass or more, more preferably 0.01% by mass or more, and still more preferably 0.1% by mass or more.

Specific examples of the moisture content in the composition layer include 2.5% by mass, 1.5% by mass, and 0.3% by mass with respect to the total mass of the composition layer.

From the viewpoint of improving reliability, improving handleability of the transfer film, and improving laminating properties, an amount of a residual solvent in the composition layer is preferably 6.0% by mass or less, more preferably 4.0% by mass or less, still more preferably 2.0% by mass or less, and particularly preferably 1.0% by mass or less with respect to the total mass of the composition layer. The lower limit thereof is preferably 0.0001% by mass or more, more preferably 0.01% by mass or more, and still more preferably 0.1% by mass or more.

Specific examples of the amount of a residual solvent in the composition layer include 3.5% by mass, 2.5% by mass, 1.5% by mass, and 0.3% by mass with respect to the total mass of the composition layer.

### <Thickness of Composition Layer>

An average thickness of the composition layer is preferably 0.5 to 40 μm, more preferably 0.5 to 25 μm, and still more preferably 3 to 20 μm. In a case where the average thickness of the composition layer is 40 μm or less, the resolution of the pattern is excellent, which is preferable; and in a case where the average thickness of the composition layer is 0.5 μm or more, the reliability is excellent, which is preferable.

### [Interlayer and Thermoplastic Resin Layer]

The transfer film may include an interlayer and/or a thermoplastic resin layer.

Examples of the interlayer and the thermoplastic resin layer include those described in paragraphs 0164 to 0204 of WO2021/166719A, the contents of which are incorporated in the present specification.

From the viewpoint of improving laminating properties, the transfer film preferably includes a thermoplastic resin layer, and more preferably includes a thermoplastic resin layer between the temporary support and the composition layer.

### <Alkali-Soluble Resin>

The thermoplastic resin layer preferably contains an alkali-soluble resin as a thermoplastic resin.

In the present specification, the “alkali-soluble” means that the solubility in 100 g of aqueous solution of 1% by mass sodium carbonate at 22° C. is 0.1 g or more.

Examples of the alkali-soluble resin include an acrylic resin, a polystyrene resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, a polyethyleneimine, a polyallylamine, and a polyalkylene glycol; and from the viewpoint of developability and adhesiveness to an adjacent layer, an acrylic resin is preferable. Here, the acrylic resin means a resin having at least one constitutional unit selected from the group consisting of a constitutional unit derived from (meth)acrylic acid, a constitutional unit derived from (meth)acrylic acid ester, and a constitutional unit derived from (meth)acrylic acid amide.

In addition, the alkali-soluble resin is preferably a polymer having an acid group.

Examples of the acid group include a carboxy group, a sulfo group, a phosphonic acid group, and a phosphoric acid group, and a carboxy group is preferable.

As the alkali-soluble resin, from the viewpoint of developability and adhesiveness to an adjacent layer, an acrylic resin having a constitutional unit derived from (meth)acrylic acid is particularly preferable.

The thermoplastic resin layer may contain one kind of alkali-soluble resin alone or two or more kinds thereof.

From the viewpoint of developability and adhesiveness to an adjacent layer, a content of the alkali-soluble resin is preferably 10% to 99% by mass, more preferably 20% to 90% by mass, still more preferably 40% to 80% by mass, and particularly preferably 50% to 70% by mass, with respect to the total mass of the thermoplastic resin layer.

The thermoplastic resin layer may contain other components in addition to the alkali-soluble resin.

Examples of the other components include a coloring agent, a compound which generates an acid, a base, or a radical by light (for example, a photoacid generator, a photoradical polymerization initiator, a photobase generator, or the like), a plasticizer, a surfactant, and a sensitizer.

Specific examples of the above-described various components include various components described in paragraphs 0164 to 0204 of WO2021/166719A.

A layer thickness of the thermoplastic resin layer is not particularly limited, but from the viewpoint of adhesiveness to an adjacent layer, is preferably 1 μm or more and more preferably 2 μm or more. The upper limit is not particularly limited, but from the viewpoint of developability and resolution, 20 μm or less is preferable, 10 μm or less is more preferable, and μm or less is still more preferable.

### [Cover Film]

The transfer film may include a cover film.

The number of fisheyes with a diameter of 80 μm or more in the cover film is preferably 5 pieces/m² or less. The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the film.

The number of particles having a diameter of 3 μm or more, included in the cover film, is preferably 30 particles/mm² or less, more preferably 10 particles/mm² or less, and still more preferably 5 particles/mm² or less. As a result, it is possible to suppress defects caused by ruggedness due to the particles contained in the cover film being transferred to the composition layer.

An arithmetic average roughness Ra of a surface of the cover film is preferably 0.01 μm or more, more preferably 0.02 μm or more, and still more preferably 0.03 μm or more. In a case where Ra is within such a range, for example, in a case where the transfer film has a long shape, take-up property in a case of winding the transfer film is excellent. In addition, from the viewpoint of suppressing defects during transfer, Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

Examples of the cover film include films described in paragraphs 0083 to 0087 and 0093 of JP2006-259138A.

Examples of the cover film include ALPHAN (registered trademark) FG-201 (manufactured by Oji F-Tex Co., Ltd.), ALPHAN (registered trademark) E-201F (manufactured by Oji F-Tex Co., Ltd.), Cerapeel (registered trademark) 25WZ (manufactured by TORAY ADVANCED FILM CO., LTD.), and LUMIRROR (registered trademark) 16QS62 (16KS40) (manufactured by Toray Industries, Inc.).

The cover film may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

### [Other Layers]

The transfer film may include a layer other than the above-described layers.

Examples of other layers include a layer of high refractive index.

Examples of the layer of high refractive index include those described in paragraphs 0168 to 0188 of WO2021/187549A, the contents of which are incorporated in the present specification.

### [Manufacturing Method of Transfer Film]

As a manufacturing method of the transfer film, a known manufacturing method can be adopted.

As the manufacturing method of the transfer film, it is preferable that the composition is applied onto the temporary support to form the composition layer.

Examples of the manufacturing method of the transfer film 100 shown in FIG. 2 include a method including a step of applying a composition onto a surface of the temporary support to form a coating film, and then drying the coating film to form the composition layer.

The transfer film 100 shown in FIG. 2 is manufactured by further compression-bonding a cover film to the composition layer of the transfer film manufactured by the above-described manufacturing method. In addition, the transfer film 100 shown in FIG. 2 may be wound after the manufacturing to be stored as the transfer film 100 in a roll form. The roll-shaped transfer film 100 is provided as it is in a bonding step described later with the base material in a roll-to-roll method.

In addition, as described above, the transfer film may include an interlayer and/or a thermoplastic resin layer between the temporary support and the composition layer.

Examples of a composition for forming the interlayer, a method for forming the interlayer, a composition for forming the thermoplastic resin layer, and a method for forming the thermoplastic resin layer include paragraphs 0133 to 0136 and paragraphs 0143 and 0144 of WO2021/033451A, the contents of which are incorporated in the present specification.

### <Method of Forming Composition Layer>

As a method of forming the composition layer, a known method can be used, and examples thereof include a method of forming the composition layer by applying and drying a composition.

As described above, the composition contains the resin X and a predetermined amount of a filler having an average particle diameter of 300 μm or less.

Examples of an applying method include slit coating, spin coating, curtain coating, and inkjet coating.

It is preferable that the composition further contains a solvent. The solvent has the same meaning as the solvent which can be contained in the above-described composition, and a suitable aspect thereof is also the same.

### [Applications]

A pattern (film) obtained from the composition layer formed of the above-described composition or the above-described transfer film can be applied to various applications. For example, these can be applied to an electrode protective film, an insulating film, a flattening film, an overcoat film, a hard coat film, a passivation film, a partition wall, a spacer, a microlens, an optical filter, an antireflection film, an etching resist, or a plating member.

More specific examples thereof include a protective film or an insulating film for a touch panel electrode, a protective film or an insulating film for a printed wiring board, a protective film or an insulating film for a TFT substrate, an interlayer insulating film in a build-up substrate of a semiconductor package, an organic interposer, a color filter, an overcoat film for a color filter, and an etching resist for a wiring line formation.

### [Manufacturing Method of Laminate]

A manufacturing method of a laminate is not particularly limited as long as it is a method using the above-described composition or the above-described transfer film.

Specifically, the manufacturing method of a laminate preferably includes a step X1 to a step X3, and more preferably includes a step X1 to a step X4.
Step X1: step of forming a composition layer on a base material using the composition or the transfer film
Step X2: step of exposing the composition layer in a patterned manner
Step X3: step of developing the exposed composition layer with a developer (for example, an alkali developer, an organic solvent developer, or the like) to form a pattern
Step X4: step of heat-treating the above-described pattern

The developer preferably includes at least one selected from the group consisting of cyclopentanone, a tetramethylammonium hydroxide aqueous solution, a sodium hydroxide aqueous solution, a sodium carbonate aqueous solution, and a potassium carbonate aqueous solution.

Hereinafter, each step of the manufacturing method of a laminate will be described in detail.

### <Step X1>

The step X1 is a step of forming a composition layer on a base material using the composition or the transfer film.

In a case where the composition is used, the step X1 is preferably a step of applying the composition onto a base material to form a composition layer.

Examples of a method of applying the composition include the method of forming the composition layer in the above-described manufacturing method of the transfer film.

In a case where the transfer film is used, the step X1 is preferably a step of bringing a surface of the composition layer on a side opposite to the temporary support side in the transfer film into contact with a base material to bond the transfer film to the base material.

A known laminator such as a laminator, a vacuum laminator, and an auto-cut laminator can be used for the bonding.

Examples of the bonding method include a known transfer method and a known laminating method; and a method in which the base material is superimposed on the surface of the composition layer and pressurization and heating are performed using a roll or the like is preferable.

Examples of the above-described laminating method include known laminators such as a vacuum laminator and an auto-cut laminator.

A laminating temperature is not particularly limited, but is preferably 70° C. to 130° C.

The step X1 is preferably carried out by a roll-to-roll method. The base material to which the transfer film is bonded is preferably a resin film or a resin film having a conductive layer.

The roll-to-roll method refers to a method in which, as the base material, a base material which can be wound up and unwound is used, a step of unwinding the base material before any of the steps included in the manufacturing method of a laminate according to the embodiment of the present invention, a step of winding the base material is included after any of the steps, and at least one of the steps (preferably, all steps or all steps other than the heating step) is performed while transporting the base material.

As an unwinding method in the unwinding step and a winding method in the winding step, a known method may be used in the manufacturing method to which the roll-to-roll method is adopted.

### (Base Material)

Examples of the base material include a glass substrate, a glass epoxy substrate, a silicon substrate, a resin substrate, and a substrate having a conductive layer.

A refractive index of the base material is preferably 1.50 to 1.52.

The base material may be composed of a translucent substrate such as a glass substrate, and for example, tempered glass typified by Gorilla glass of Corning Incorporated can also be used. In addition, examples of the material contained in the above-described base material also include materials used in JP2010-086684A, JP2010-152809A, and JP2010-257492A.

In a case where the above-described base material includes a resin substrate, as the resin substrate, a resin film having a small optical distortion and/or a high transparency is more preferable. Specific examples thereof include polyethylene terephthalate (PET), polyethylene naphthalate, polycarbonate, triacetyl cellulose, a cycloolefin polymer, and polyimide.

As the substrate having a conductive layer, from the viewpoint of manufacturing by a roll-to-roll method, a resin substrate having a conductive layer is preferable and a resin film having a conductive layer is more preferable.

Examples of the conductive layer include any conductive layer used for general circuit wiring or touch panel wiring.

As the conductive layer, from the viewpoint of conductivity and fine line formability, one or more layers selected from the group consisting of a metal layer (for example, a metal foil or the like), a conductive metal oxide layer, a graphene layer, a carbon nanotube layer, and a conductive polymer layer are preferable, a metal layer is more preferable, and a copper layer or a silver layer is still more preferable.

In addition, the conductive layer in the substrate having a conductive layer may be one layer or two or more layers.

In a case where the substrate having a conductive layer includes two or more conductive layers, it is preferable that each conductive layer is a conductive layer formed of different materials.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, preferably less than 1×10⁴ Ω·cm.

In a case where the number of conductive layers in the base material having a conductive layer is 2 or more, it is preferable that at least one conductive layer among the conductive layers includes the conductive metal oxide.

### <Step X2>

The step X2 is a step of exposing the composition layer in a patterned manner after the above-described step X1.

The “pattern exposure” refers to exposure in a patterned manner, that is, exposure in which an exposed portion and a non-exposed portion are present.

A positional relationship between the exposed portion and the non-exposed portion in the pattern exposure is not particularly limited and is appropriately adjusted.

The exposure may be performed from the side opposite to the base material of the composition layer, or may be performed from the base material side of the composition layer.

A light source used for the exposure can be appropriately selected as long as it irradiates various components (for example, a photopolymerization initiator, a photoacid generator, and the like) which can be photo-sensitized in the composition layer with light in a photosensitive wavelength range (for example, light in a wavelength range of 254 nm, 313 nm, 365 nm, 405 nm, and the like).

Specific examples thereof include an ultra-high pressure mercury lamp, a high pressure mercury lamp, a metal halide lamp, and a light emitting diode (LED).

An exposure amount is preferably 5 to 200 mJ/cm² and more preferably 10 to 200 mJ/cm².

In the step X2, the temporary support may be peeled off from the composition layer and then the pattern exposure may be performed, or before peeling off the temporary support, the pattern exposure may be performed through the temporary support and then the temporary support may be peeled off. In order to prevent mask contamination due to contact between the composition layer and the mask and to avoid an influence of foreign substance adhering to the mask on the exposure, it is preferable to perform the pattern exposure without peeling off the temporary support. The pattern exposure may be an exposure through a mask or a direct exposure using a laser or the like.

Examples of the mask in a case of exposure through the mask include a quartz mask, a soda-lime glass mask, and a film mask. From the viewpoint of excellent dimensional accuracy, a quartz mask is preferable, and from the viewpoint that it is easy to increase the size, a film mask is preferable.

As a material of the film mask, a polyester film is preferable, and a polyethylene terephthalate film is more preferable. Specific examples of the material of the film mask include XPR-7S SG (manufactured by Fujifilm Global Graphic Systems).

It is preferable that the temporary support is peeled off from the composition layer before the step X3 described later.

### <Step X3>

The step X3 is a step of developing the exposed composition layer with a developer (for example, an alkali developer, an organic solvent developer, or the like) to form a pattern, after the above-described step X2.

Examples of the developer include an alkali developer and an organic solvent developer.

The developer preferably includes at least one selected from the group consisting of cyclopentanone, a tetramethylammonium hydroxide aqueous solution, a sodium hydroxide aqueous solution, a sodium carbonate aqueous solution, and a potassium carbonate aqueous solution.

### (Alkali Developer)

As the alkali developer, an alkali aqueous solution is preferable.

An alkali aqueous solution-based developer containing a compound having a pKa of 7 to 13 at a concentration of 0.05 to 5 mol/L is preferable.

A content of the water in the alkali developer is preferably 50% by mass or more, more preferably 60% by mass or more, still more preferably 85% by mass or more, particularly preferably 90% by mass or more, and most preferably 95% by mass or more with respect to the total mass of the alkali developer. The upper limit thereof is preferably less than 100% by mass with respect to the total mass of the alkali developer.

Examples of the alkali developer include a sodium carbonate aqueous solution, a potassium carbonate aqueous solution, a sodium hydroxide aqueous solution, a potassium hydroxide aqueous solution, and a tetramethylammonium hydroxide aqueous solution. Examples of a concentration of the above-described alkali developer (alkali component constituting the alkali developer) include a 0.1% by mass aqueous solution, a 1.0% by mass aqueous solution, and a 2.38% by mass aqueous solution.

In addition, the alkali developer may contain a water-soluble organic solvent, a surfactant, and the like. Examples of the alkali developer include developers described in paragraph 0194 of WO2015/093271A.

### (Organic Solvent Developer)

Examples of the organic solvent developer include developers containing an organic solvent such as a ketone solvent, an ester solvent, an alcohol solvent, an amide solvent, an ether solvent, and a hydrocarbon solvent.

Examples of the organic solvent developer include cyclopentanone and propylene glycol monomethyl ether acetate; and cyclopentanone is preferable.

In the organic solvent developer, a plurality of organic solvents may be mixed, or may be mixed with an organic solvent other than the above or water. A content of water in the organic solvent developer is preferably less than 10% by mass with respect to the total mass of the organic solvent developer, and it is more preferable that the organic solvent developer does not substantially contain water. A content of the organic solvent in the organic solvent developer is preferably 50% by mass or more, more preferably 60% by mass or more, still more preferably 85% by mass or more, particularly preferably 90% by mass or more, and most preferably 95% by mass or more with respect to the total mass of the organic solvent developer. The upper limit thereof is preferably 100% by mass or less with respect to the total mass of the organic solvent developer.

Examples of the developing method include puddle development, shower development, spin development, and dip development. In the shower development, unnecessary portions can be removed by spraying the developer on the composition layer after the exposure with a shower. In addition, after the development, it is also preferable to spray a washing agent and the like with a shower and rub with a brush and the like to remove the developing residue. A liquid temperature of the developer is preferably 20° C. to 40° C.

### <Step X4>

It is preferable that the manufacturing method of a laminate includes a step X4 after the step X3.

The step X4 is a step of heat-treating the pattern obtained in the step X3.

In a case where the composition contains a polyimide precursor and a polybenzoxazole precursor, a ring closure reaction of the precursor is promoted by the step X4, and a polyimide and a polybenzoxazole can be generated.

In addition, a purity of the pattern can be improved by the step X4. The purity of the pattern means that the various components contained in the pattern are substantially composed of only polyimide and polybenzoxazole. Specifically, the total content of the polyimide and the polybenzoxazole is preferably 90% by mass or more and more preferably 95% by mass or more with respect to the total mass of the pattern. The upper limit thereof is preferably 100% by mass or less.

For example, the pattern obtained in the step X3 may contain a polymer or the like, derived from the polymerizable compound generated in the step X2. On the other hand, it is presumed that, in a case where the step X4 is performed, the above-described polymer or the like is depolymerized, the depolymerized product is removed, and by-products (for example, a compound generated by decomposition of a part of the group of the above-described precursor) generated by the ring closure reaction of the above-described precursor can also be removed, and as a result, the purity of the pattern can be improved.

The temperature and time of the heating treatment are not particularly limited as long as the temperature and time are such that the ring closure reaction of the above-described precursor is promoted.

The temperature of the heating treatment is preferably 120° C. to 400° C., more preferably 150° C. to 400° C., and still more preferably 190° C. to 350° C.

The time of the heating treatment is preferably 1 to 24 hours, more preferably 1 to 12 hours, and still more preferably 1 to 9 hours.

The heating treatment may be performed in any of an air environment or a nitrogen replacement environment.

The atmospheric pressure under the heating treatment environment is preferably 8.1 kPa or more, and more preferably 50.66 kPa or more. The upper limit thereof is preferably 121.6 kPa or less, more preferably 111.46 kPa or less, and still more preferably 101.3 kPa or less.

### [Other Steps]

The manufacturing method of a laminate may include other steps in addition to the above-described steps.

Examples of the other steps include the following steps.

### <Cover Film Peeling Step>

In a case where the transfer film in the above-described manufacturing method of a laminate includes a cover film, it is preferable that the manufacturing method of a laminate includes a step of peeling off the cover film of the transfer film.

As a method of peeling off the cover film, and a known method can be adopted.

### <Step of Reducing Visible Light Reflectivity>

In a case where the base material is a substrate having a conductive layer, the above-described manufacturing method of a laminate may further include a step of performing a treatment of reducing a visible light reflectivity of the conductive layer.

In a case where the above-described base material is a substrate having a plurality of conductive layers, the treatment of reducing the visible light reflectivity may be performed on some conductive layers or all conductive layers.

Examples of the treatment of reducing the visible light reflectivity include an oxidation treatment. For example, by oxidizing copper to copper oxide, the visible light reflectivity of the conductive layer can be reduced due to blackening.

Examples of a suitable aspect of the treatment of reducing the visible light reflectivity include the descriptions in paragraphs 0017 to 0025 of JP2014-150118A, and paragraphs 0041, 0042, 0048, and 0058 of JP2013-206315A, the contents of which are incorporated in the present specification.

### <Etching Step>

In a case where the base material is a substrate having a conductive layer, the above-described manufacturing method of a laminate may include a step (etching step) of etching, using the pattern (film) formed by the step X3 or the step X4 as an etching resist film, the conductive layer in a region where the etching resist film is not disposed.

Examples of a method of the etching treatment include a method by wet etching, which is described in paragraphs 0048 to 0054 of JP2010-152155A, and a method by dry etching such as a known plasma etching.

In the above-described manufacturing method of a laminate, it is also preferable to use a substrate having a plurality of conductive layers on both surfaces, and sequentially or simultaneously form patterns on the conductive layers formed on both surfaces.

With such a configuration, it is possible to form a first conductive pattern on one surface of the substrate and form a second conductive pattern on the other surface. It is also preferable to form the patterns from both surfaces of the base material by the roll-to-roll.

### [Manufacturing Method of Circuit Wiring]

A manufacturing method of a circuit wiring is not particularly limited as long as it is a method for manufacturing a circuit wiring using the composition or the transfer film.

It is preferable that the manufacturing method includes a step of bringing a surface of the composition layer in the above-described transfer film on a side opposite to the temporary support side into contact with the conductive layer in the substrate having a conductive layer to bond the transfer film and the substrate having a conductive layer, or a step of applying the composition onto the base material to form the composition layer; a step of exposing the composition layer in a patterned manner; a step of developing the exposed composition layer with a developer to form a pattern; and a step of etching the conductive layer in a region where the pattern is not disposed.

It is preferable that the manufacturing method of a circuit wiring includes a step of heat-treating the pattern between the step of forming the pattern and the step of performing the etching treatment. Examples of the step of performing the heating treatment include a step X4.

Examples of each step in the manufacturing method of a circuit wiring according to the present invention include each step in the manufacturing method of a laminate described above.

In the manufacturing method of a circuit wiring according to the present invention, it is also preferable that a plurality of sets of steps from the above-described bonding step or the step of forming the composition layer using the composition to the step of performing the etching treatment are repeated.

The film used as the etching resist film can also be used as a protective film (insulating film) for the formed circuit wiring.

### [Manufacturing Method of Semiconductor Package]

Examples of a manufacturing method of a semiconductor package include a known manufacturing method such as a manufacturing method of a build-up substrate.

Specific examples thereof include a manufacturing method including the step Z1 to the step Z5 in this order.
Step Z1: step of forming a composition layer on a substrate having a conductive layer using the composition or the transfer film
Step Z2: step of exposing the composition layer in a patterned manner
Step Z3: step of developing the exposed composition layer with a developer to form a pattern having a via
Step Z4: step of heat-treating the above-described pattern
Step Z5: step of forming a circuit pattern on the pattern

Examples of the step Z1, the step Z2, and the step Z4 in the manufacturing method of a semiconductor package include the step X1, the step X2, and the step X4, respectively.

### [Step Z3]

The step Z3 is a step of developing the exposed composition layer with a developer to form a pattern having a via.

Examples of a method of development with a developer include the method of development with a developer in the step X3.

Examples of a shape of the via included in the above-described pattern include a quadrangular, a trapezoidal, and an inverted trapezoidal as a cross-sectional shape; and a circular and a quadrangular as a front shape (a shape of the via in a case of observing the via from a direction in which the via bottom is visible).

As the shape of the via included in the above-described pattern, from the viewpoint of improving attachment property of a via wall surface to a plated copper, a reverse trapezoid is preferable as the cross-sectional shape.

A size (diameter) of the above-described via is usually 300 μm or less, preferably 200 m or less, more preferably less than 40 μm, still more preferably 30 μm or less, even more preferably 20 μm or less, particularly preferably 10 μm or less, and most preferably 5 μm or less. The lower limit thereof is preferably 1 μm or more and more preferably 5 μm or more.

The number of the above-described vias may be 1 or 2 or more, and is preferably 2 or more.

### [Step Z5]

The step Z5 is a step of forming a circuit pattern on the above-described pattern.

As a method of forming the circuit pattern, a semi-additive process is preferable from the viewpoint that a fine wiring can be formed.

In the semi-additive process, first, a seed layer is formed by performing an electroless copper plating treatment on the entire surface of the via bottom, the via wall surface, and the pattern after the above-described step Z3 using a palladium catalyst or the like.

The above-described seed layer is for forming a power feeding layer for performing the electrolytic copper plating, and a thickness of the seed layer is preferably 0.1 to 2.0 μm. In a case where the thickness of the above-described seed layer is 0.1 μm or more, the tendency is that the deterioration in connection reliability during the electroless copper plating can be suppressed, and in a case where the thickness of the above-described seed layer is 2.0 μm or less, the tendency is that it is not necessary to increase the etching amount in a case of flash-etching the seed layer between the wiring lines, and the damage to the wiring lines during the etching can be suppressed.

The electroless copper plating treatment is performed by precipitating metallic copper on the surface of the pattern having a via by a reaction between copper ions and a reducing agent.

Examples of the electroless plating treatment method and the electrolytic plating treatment method include known plating treatment methods.

As the catalyst in the electroless plating treatment step, a palladium-tin mixed catalyst is preferable. An average primary particle diameter of the above-described mixed catalyst is preferably 10 nm or less. In addition, as the plating composition of the electroless plating treatment step, it is preferable to contain hypophosphorous acid as a reducing agent.

Examples of a commercially available product of the electroless copper plating liquid include “MSK-DK” manufactured by Atotech Japan K.K. and “SULKACUP (registered trademark) PEA ver. 4” series manufactured by Uemura Kogyo Co., Ltd.

It is preferable that, after the electroless copper plating treatment, the surface of the composition layer in the transfer film on the side opposite to the temporary support is thermocompression-bonded to the electroless copper plating by a roll laminator.

From the viewpoint that the thickness of the above-described composition layer can be higher than the wiring line height after the electro copper plating, the thickness of the composition layer is preferably 5 to 30 μm.

After the thermal compression bonding of the transfer film, the composition layer is exposed through, for example, a mask on which a desired wiring pattern is drawn. Examples of the above-described exposing method include the exposing method in the step X2.

After the exposure, the temporary support of the transfer film is peeled off, and the exposed composition layer is developed with an alkali developer to form a pattern. In addition, after the above-described pattern is formed, the development residue of the composition may be removed using a plasma or the like.

After the development, the copper circuit layer is formed and the via filling is performed by performing the electro copper plating.

After the electro copper plating, the pattern is peeled off using an alkaline aqueous solution or an amine-based peeling agent.

After the pattern is peeled off, the seed layer between the wiring lines is removed (flash etching).

The flash etching is performed using, for example, an oxidative solution containing sulfuric acid and an acidic solution such as hydrogen peroxide. Examples of the oxidative solution include “SAC” manufactured by JCU CORPORATION and “CPE-800” manufactured by MITSUBISHI GAS CHEMICAL COMPANY, INC. After the flash etching, removal of palladium or the like adhering to a part between the wiring lines is performed as necessary. The removal of palladium can be performed using an acidic solution such as nitric acid and hydrochloric acid.

It is preferable to perform a post-baking treatment after the peeling of the pattern or after the flash etching step. The post-baking treatment sufficiently thermosets the unreacted thermosetting component, and further improves the electrical insulation reliability, the curing characteristics, and the adhesive strength with the plated copper.

The thermal curing conditions are preferably a curing temperature of 150° C. to 240° C. and a curing time of 15 to 500 minutes.

The manufacturing method of a semiconductor package may include a roughening step of roughening a pattern having a via. It is preferable that the above-described roughening step is performed after the above-described step Z4 and before the above-described step Z5.

By performing the roughening step, the above-described patterned surface can be roughened, and the adhesiveness with the circuit wiring can be improved. In addition, the smearing can be removed at the same time.

Examples of the roughening step include a known desmutting treatment, and a treatment of bringing the roughening liquid into contact is preferable.

Examples of the roughening liquid include a roughening liquid containing chromium and sulfuric acid, a roughening liquid containing an alkali permanganate (for example, a sodium permanganate roughening liquid or the like), and a roughening liquid containing sodium fluoride, chromium, and sulfuric acid.

Each of the above-described steps is repeated according to the required number of layers, thereby manufacturing a semiconductor package. In addition, it is preferable that a solder resist is formed on the outermost layer.

### [Manufacturing Method of Touch Panel]

A manufacturing method of a touch panel is not particularly limited as long as it is a manufacturing method of a touch panel using the composition or the transfer film.

It is preferable that the manufacturing method includes a step of bringing a surface of the composition layer in the transfer film on a side opposite to the temporary support side into contact with the conductive layer in the substrate having a conductive layer (preferably, a patterned conductive layer; specifically, a touch panel electrode pattern or a conductive pattern such as a wiring line) to bond the transfer film and the substrate having a conductive layer, or a step of applying the composition onto the base material to form the composition layer; a step of exposing the composition layer in a patterned manner; and a step of developing the exposed composition layer with a developer to form a patterned protective film or insulating film on the conductive layer.

### [Manufacturing Method of Semiconductor Device]

As a manufacturing method of a semiconductor device, a known manufacturing method can be applied.

Specific examples thereof include a manufacturing method of a semiconductor device, including the above-described manufacturing method of a laminate or the above-described manufacturing method of a semiconductor package.

Examples of the semiconductor device include various semiconductor devices such as a semiconductor package provided in an electrical product (for example, a computer, a mobile phone, a digital camera, and a television) and a vehicle (for example, a motorcycle, an automobile, a train, a ship, and an airplane).

### [Semiconductor Package]

The semiconductor package is not particularly limited as long as it includes a pattern (film) obtained from the composition layer formed of the above-described composition or the above-described transfer film.

The cured film may be used as an insulating film, and may be used as an organic interposer or an insulating film in a so-called build-up substrate.

### EXAMPLES

Hereinafter, the present invention will be described in more detail with reference to Examples. The material, the amount used, the proportion, the process contents, the process procedure, and the like shown in the following examples can be appropriately changed, within a range not departing from the gist of the present invention. Therefore, the scope of the present invention should not be construed as being limited to Examples.

In Examples, unless otherwise specified, “part” and “%” mean “part by mass” and “% by mass”, respectively.

### [Preparation of Composition]

Various components were mixed such that the solid content proportion was as shown in the table, and the mixture was further diluted so that the concentration of solid contents was 30% by mass, the concentration of methyl ethyl ketone (MEK) was 20% by mass, and the concentration of N-methylpyrrolidone (NMP) was 50% by mass, thereby preparing a composition. In a case where the silica was not a slurry (in a case of being powder), the silica was dispersed in a 50% by mass MEK solution and then finally mixed with the other components to prepare a composition. In addition, the contents of the sodium ion and the chloride ion in the composition were adjusted using the above-described method of adjusting the content of the impurities as necessary.

### [Resin]

Resins A to F are resins corresponding to the resin X.

### <Resin A>

4,4′-oxydiphthalic acid anhydride (used after being dried at 140° C. for 12 hours; 20.0 g, 64.5 mmol), 2-hydroxyethyl methacrylate (16.8 g, 129 mmol), hydroquinone (0.05 g), pyridine (20.4 g, 258 mmol), and diglyme (100 g) were mixed, and the mixture was stirred at 60° C. for 18 hours to produce a diester of 4,4′-oxydiphthalic acid and 2-hydroxyethyl methacrylate. Next, the obtained diester was chlorinated with SOCl₂ to obtain a reaction mixture.

Next, a solution obtained by dissolving 4,4′-diaminodiphenyl ether (11.08 g, 58.7 mmol) in N-methylpyrrolidone (100 mL) was added dropwise to the reaction mixture at −5° C. to 0° C. over 20 minutes. Next, the reaction mixture was reacted at 0° C. for 1 hour, ethanol (70 g) was added thereto, and the mixture was stirred at room temperature for 1 day. Next, a polyimide precursor was precipitated in 5 L of water, and the water-polyimide precursor mixture was stirred at a speed of 5,000 rpm for 15 minutes. The polyimide precursor was filtered and removed from the above-described mixture, and then stirred in 4 L of water for 30 minutes and filtered again. Next, the obtained polyimide precursor was dried at 45° C. for 3 days under reduced pressure to obtain a resin A as a polyimide precursor. A weight-average molecular weight of the resin A was 18,000.

### <Resin B>

4,4′-oxydiphthalic acid dianhydride (ODPA, Mw=310.22, 77.6 g) and diphenyl-3,3′,4,4′-tetracarboxylic acid dianhydride (BPDA, Mw=294.2, 73.6 g) were charged into a 2 L separable flask, 2-hydroxyethyl methacrylate (HEMA, 134.0 g) and γ-butyrolactone (400 mL) were added thereto with stirring at room temperature, and pyridine (79.1 g) further was added thereto to obtain a reaction mixture. After heat generation due to the reaction was stopped, the reaction mixture was further allowed to cool to room temperature and left to stand for 16 hours. Next, a solution obtained by dissolving dicyclohexylcarbodiimide (DCC, 206.3 g) in γ-butyrolactone (180 mL) was added to the reaction mixture over 40 minutes with stirring under ice cooling. Subsequently, a liquid obtained by suspending 4,4′-oxydianiline (ODA, Mw=200.24, 93.0 g) in γ-butyrolactone (350 mL) was added thereto over 60 minutes with stirring. After further stirring at room temperature for 2 hours, ethyl alcohol (30 mL) was added thereto and stirred for 1 hour, and then γ-butyrolactone (400 mL) was added thereto. The precipitate formed in the reaction mixture was removed by filtration to obtain a reaction solution. The obtained reaction solution was added to ethyl alcohol (3 L) to obtain a precipitate as a crude polymer. The obtained crude polymer was collected by filtration and dissolved in tetrahydrofuran (1.5 L) to obtain a crude polymer solution. The obtained crude polymer solution was purified using an anion exchange resin (Amberlite TM15, manufactured by Organo Corporation) to obtain a polymer solution. The obtained polymer solution was added dropwise to water (28 L) to precipitate a polymer, and the obtained precipitate was collected by filtration and then vacuum-dried to obtain a resin B as a powdery polyimide precursor. A weight-average molecular weight (Mw) of the resin B was 22,000. A content of the imide group in the polyimide obtained from the resin B was 27.4% by mass per repeating unit.

### <Resin C>

A resin C as a polyimide precursor was obtained using 4,4′-diaminodiphenyl ether as a diamine and 4,4′-oxydiphthalic acid dianhydride as a dianhydride. A weight-average molecular weight of the resin C was 15,000.

### <Resin D>

A resin D as a polybenzoxazole precursor was obtained using 2,2-bis(3-amino-4-hydroxyphenyl)hexafluoropropane as a diamine and 4,4′-oxybis(benzoyl chloride) as an acid chloride. A weight-average molecular weight of the resin D was 15,000.

### <Resin E>

After obtaining the resin D, a phenolic hydroxyl group in the resin D was further protected with a tetrahydrofuranyl (THF) group to obtain a resin E.

### <Resin F>

After obtaining the resin C, a carboxy group in the resin C was further protected with a tetrahydropyranyl (THP) group to obtain a resin F.

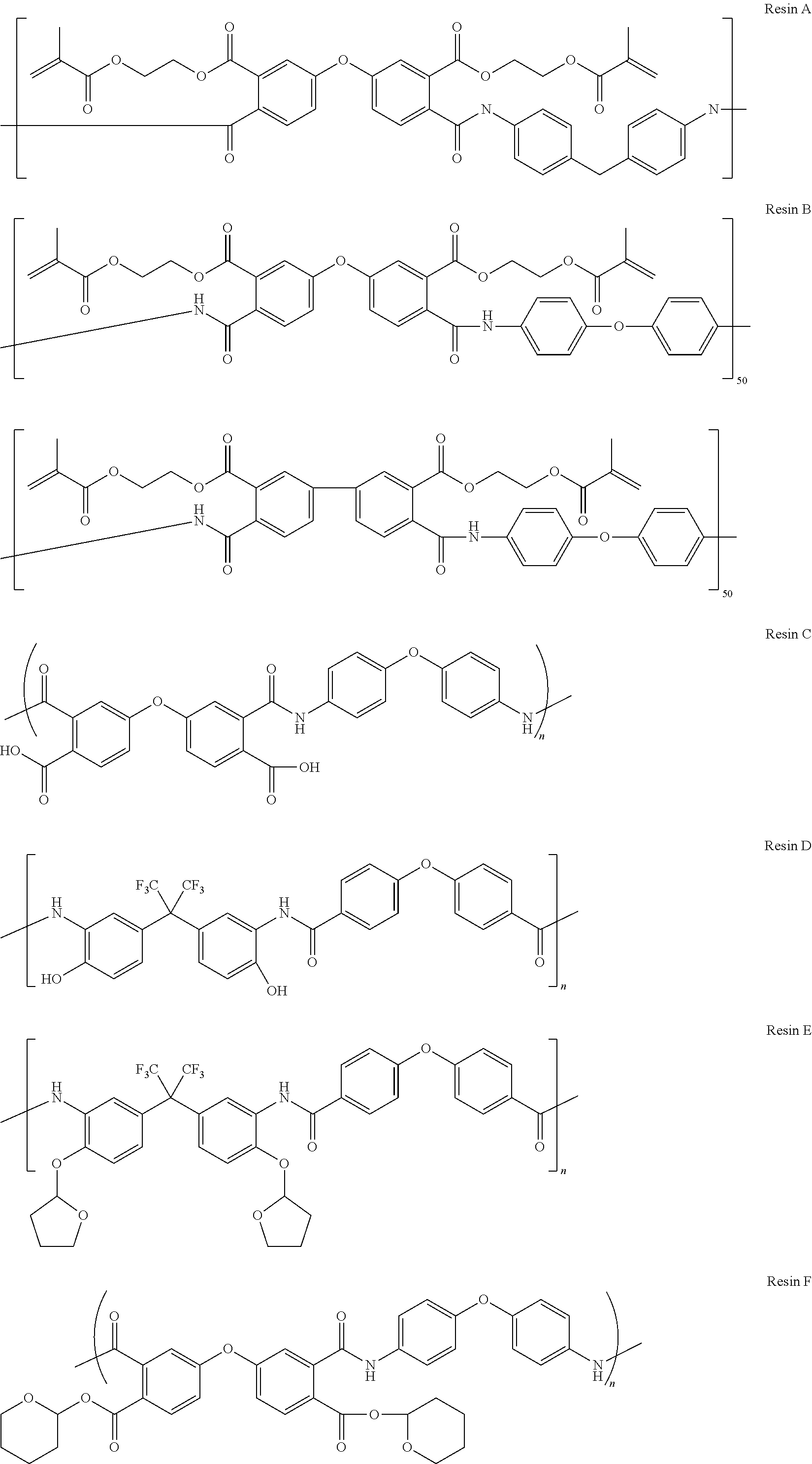

### [Filler]

YA050C-MJE: spherical silica slurry, surface-treated product, concentration of solid contents: 50% by mass, MEK slurry, manufactured by Admatechs Co., Ltd.
SFP-20M: silicon dioxide, surface-treated product, manufactured by Denka Company Limited
PMA-ST: silicon dioxide (spherical silica slurry), surface-treated product, manufactured by Nissan Chemical Corporation
MEK-ST-L: silicon dioxide (spherical silica slurry), surface-treated product, manufactured by Nissan Chemical Corporation
MEK-AC-5140Z: silicon dioxide (spherical silica slurry), surface-treated product, manufactured by Nissan Chemical Corporation
NHM-5N: silicon dioxide, surface-treated product, manufactured by TOKUYAMA CORPORATION
NHM-3N: silicon dioxide, surface-treated product, manufactured by TOKUYAMA CORPORATION
Y50SP-AM1: silicon dioxide (spherical silica slurry), surface-treated product, manufactured by Admatechs Co., Ltd.
Y50SZ-AM1: silicon dioxide (spherical silica slurry), surface-treated product, manufactured by Admatechs Co., Ltd.
NP-5N: silicon dioxide, surface-treated product, manufactured by TOKUYAMA CORPORATION
Pre-adjusted product A: filler produced by the following method

10 g of silica extracted from IPA-ST-ZL (silica dispersion liquid manufactured by Nissan Chemical Corporation, not surface-treated) by centrifugal separation and filter, 39 g of NMP, and 1 g of 3-methacryloxypropyltrimethoxysilane were mixed with each other, and ultrasonic dispersion was carried out with stirring to produce the pre-adjusted product A. An average primary particle diameter of the obtained pre-adjusted product A was confirmed to be 80 nm±10% using a zeta sizer.

### [Polymerizable Compound]

NK3G: NK ESTER 3G (bifunctional polyethylene glycol methacrylate), manufactured by Shin-Nakamura Chemical Co., Ltd.
NK4G: NK ESTER 4G (bifunctional polyethylene glycol methacrylate), manufactured by Shin-Nakamura Chemical Co., Ltd.
DPHA: dipentaerythritol hexaacrylate, manufactured by Tokyo Chemical Industry Co., Ltd.

### [Photopolymerization Initiator]

Oxe01: IRGACURE OXE-01, manufactured by BASF SE
Oxe02: IRGACURE OXE-02, manufactured by BASF SE
Omn819: Omnirad 819, manufactured by IGM Resins B.V.

### [Thermal-Base Generator]

Compound X (refer to the following structural formula)

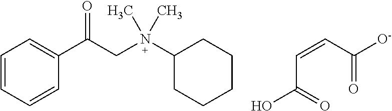

U-CAT SA506: p-toluenesulfonate of 1,8-diazabicyclo[5.4.0]undecene-7, manufactured by San-Apro Ltd.

### [Surfactant]

F551A: MEGAFACE (registered trademark) F551A, fluorine-based surfactant, manufactured by DIC Corporation
S-324: silicone-based surfactant, manufactured by DIC Corporation
S-506: silicone-based surfactant, manufactured by DIC Corporation

### [Photoacid Generator]

PAG1: compound having an oxime sulfonate structure (refer to the following structural formula)

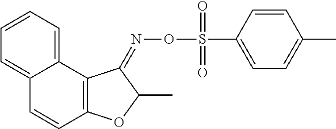 [SMILES: Cc1ccc(S(=O)(=O)O/N=C2/c3c(ccc4ccccc34)OC2C)cc1]

CPI-100P: compound having a sulfonium structure, manufactured by Sanyo Chemical Industries, Ltd.

### [Compound Y]

Ethyl phthalyl ethyl glycolate
Dihexyl phthalate
o-Acetyltrihydroxybutyl citrate
Benzyl 2-ethylhexyl phthalate

### [Additive]

HAT: 5-amino-1H-tetrazole
ATA: 3-amino-1,2,4-triazole

### [Others]

ZCR-1569H: comparative compound, acid-modified epoxy acrylate, manufactured by Nippon Kayaku Co., Ltd.
SC2050-LNF: silica slurry, surface-treated product, manufactured by Admatechs Co., Ltd.

### [Developer]

Cyclopentanone
Na₂CO₃ aq.: 1% by mass sodium carbonate aqueous solution
TMAH aq.: 2.38% by mass tetramethylammonium hydroxide aqueous solution

### [Measurement of Average Particle Diameter]

Each of the compositions of Examples and Comparative Examples was applied onto a glass substrate, and dried to form a coating film having a thickness of 4.0 μm.

A cross section of the obtained coating film along a normal direction of the surface was cut out, the cross section was observed with a scanning electron microscope, and a major diameter of all fillers observed in a region having a length of 3 μm in a longitudinal direction parallel to a thickness direction of the coating film and a length of 10 μm in a lateral direction orthogonal to the longitudinal direction was measured.

The above-described operation was performed at five different positions on the coating film, and an average value (arithmetic mean value) of the major diameters of all the fillers measured in each operation was defined as the average particle diameter of the filler.

In the compositions of each of Examples and Comparative Examples, in a case where the average particle diameter was measured as described above, the coating film was heated at 230° C. for 8 hours, and then an average particle diameter was measured according to the same operation as described above, the average particle diameter was the same value as the average particle diameter before the heating treatment.

### [Content of Surface Modifier]

Each composition was applied onto a base material and dried (drying temperature: 100° C., drying time: 3 minutes) so that the thickness after drying was 10 μm, thereby forming a composition layer. Next, the obtained composition layer was dissolved in a mixed solvent of MEK:NMP=1:1. Thereafter, the obtained solution was centrifuged and filtered using a 0.2 μm filter to separate the filler. The obtained filler was dried (drying temperature: 100° C., drying time: 30 minutes) to obtain 30 mg of a filler for measurement. With the filler for measurement, a weight loss rate was measured three times under conditions of temperature rising (10° C./min) from room temperature to 1,000° C. in an air atmosphere using a TG-DTA device (TG/DTA7300) manufactured by Hitachi High-Tech Science Corporation, and a content (a value with respect to the total solid content of the composition) of the surface modifier was calculated from the arithmetic mean value thereof

[Content of Na⁺ and Cl⁻]

Each composition (1 g) was dissolved in acetone and then diluted with ultrapure water to prepare a solution of acetone:ultrapure water=1:9. A content (a value with respect to the total solid content of the composition) of Na⁺ and Cl⁻ in the supernatant of the solution was measured by ion chromatography. ICS-2100 manufactured by Thermo Fisher Scientific Inc. was used as an analysis apparatus; IonPac AS11HC manufactured by Thermo Fisher Scientific Inc. was used as a column in a case of Cl⁻, and IonPac CS12 manufactured by Thermo Fisher Scientific Inc. was used as a column in a case of Na⁺, and a column temperature was set to 35° C.

### [Various Measurements and Evaluations]

Regarding the compositions described in Tables 1 to 5 later, a measurement sample was produced according to the following method X.

A copper-clad polyimide film (METALOYAL, manufactured by Toray Industries, Inc.) was used as a base material, and the compositions shown in Tables 1 to 5 were applied to the base material and dried to obtain a laminate including a composition layer with a thickness of 10.0 μm on the base material. The obtained laminate was exposed (high pressure mercury lamp, integrated illuminance of 100 mJ/cm² measured with a 365 nm-wavelength illuminance meter) from a side of the composition layer opposite to the base material side, subjected to a heating treatment (230° C., 8 hours) in an oven, immersed in a 2 M hydrochloric acid for 8 hours for a peeling treatment, rinsed (with pure water at normal temperature for 1 hour), and then peeled off from the base material to obtain a self-supporting film derived from the composition layer. In a case where the self-supporting film could not be peeled off in the above-described peeling treatment, the film was further immersed in a 2 M hydrochloric acid for approximately 1 week and peeled off. The obtained self-supporting film was cut into strips to obtain a measurement sample.

Regarding the compositions described in Table 6 later, a measurement sample was produced according to the following method Y.

A copper-clad polyimide film (METALOYAL, manufactured by Toray Industries, Inc.) was used as a base material, and the compositions shown in Table 6 were applied to the base material and dried to obtain a laminate including a composition layer with a thickness of 10.0 m on the base material. The obtained laminate was subjected to a heating treatment (230° C., 8 hours) in an oven, immersed in a 2 M hydrochloric acid for 8 hours for a peeling treatment, rinsed (with pure water at normal temperature for 1 hour), and then peeled off from the base material to obtain a self-supporting film derived from the composition layer. In a case where the self-supporting film could not be peeled off in the above-described peeling treatment, the film was further immersed in a 2 M hydrochloric acid for approximately 1 week and peeled off. The obtained self-supporting film was cut into strips to obtain a measurement sample.

### [Coefficient of Thermal Expansion (CTE)]

The measurement sample obtained by the method X or the method Y was processed into 19 mm×5 mm, and CTE was measured using a thermomechanical analyzer (TMA, TMA450EM manufactured by TA Instruments). The measurement conditions were set to a temperature rising rate of 10° C./min, a distance between chucks of 16 mm, and a load of 49 mN. The measurement was performed in a temperature range of −60° C. to 350° C. The CTE was defined as an average value X (ppm/K) in a range of 50° C. to 100° C. during temperature rise, and an average value Y (ppm/K) in a range of 190° C. to 210° C. The measurement was performed on three samples, and an average value thereof was used.

### <Evaluation Standard for CTE>

A: average value X was 17 ppm/K or less.

B: average value X was more than 17 ppm/K and 20 ppm/K or less.

C: average value X was more than 20 ppm/K.

### <Evaluation Standard for Average Value Y/Average Value X>

A: average value Y/average value X was less than 0.9.

B: average value Y/average value X was 0.9 to 2.0.

C: average value Y/average value X was more than 2.0.

### [Average Relative Permittivity and Average Dielectric Loss Tangent]

For the measurement sample obtained by the method X or the method Y, an average relative permittivity and an average dielectric loss tangent were measured using a 28 GHz split cylinder-type resonator (manufactured by Kanto Electronics Application & Development Inc.). The measurement was performed on three samples, and an average value thereof was used.

### <Evaluation Standard for Average Relative Permittivity>

A: average relative permittivity was 3.0 or less.

B: average relative permittivity was more than 3.0 and 3.5 or less.

C: average relative permittivity was more than 3.5.

### <Evaluation Standard for Average Dielectric Loss Tangent>

A: average dielectric loss tangent was 0.0020 or less.

B: average dielectric loss tangent was more than 0.0020 and 0.0030 or less.

C: average dielectric loss tangent was more than 0.0030.

### [Photolithography Properties]

The composition shown in the table was applied onto a glass (Corning glass, 5 cm in length×5 cm in width×1.1 mm in thickness) and dried so that a thickness after drying was 10 μm, thereby forming a composition layer.

A temporary support (PET film, LUMIRROR 16FB40, thickness: 16 μm, manufactured by Toray Industries, Inc.) and a photo mask were laminated on the obtained composition layer in this order to obtain a laminate.

In a case where the compositions shown in Tables 1 to 5 were used, a photo mask having a plurality of circular light shielding units having a diameter of 50 μm and a diameter of m, and having a distance between the light shielding units (distance from a center of a circle to a center of a circle) of 150 μm or more was used as the photo mask.

In addition, in a case where the compositions shown in Table 6 were used, a photo mask having a plurality of circular opening portions having a diameter of 50 μm and a diameter of 30 m, and having a distance between the opening portions (distance from a center of a circle to a center of a circle) of 150 μm or more was used as the photo mask.

The obtained laminate was subjected to pattern exposure from a side of the photo mask opposite to the temporary support using an ultra-high pressure mercury lamp. In this case, an integrated exposure amount measured with a 365 nm-wavelength illuminance meter was 5 mJ/cm². Thereafter, the photo mask was removed from the laminate.

After the exposure, the laminate was allowed to stand for 30 minutes, and the temporary support and the photo mask were peeled off from the laminate, and the laminate was developed at room temperature for 90 seconds using a developer shown in the tables. After the development, the laminate was rinsed with a rinsing liquid for 20 seconds at room temperature, and air was further blown to remove the residual rinsing liquid. As the rinsing liquid, water was used in a case where the developer was an aqueous solution, and propylene glycol monoethyl ether acetate was used in a case where the developer was an organic solvent. Vias having each diameter in the sample after the development were observed and evaluated according to the following evaluation standards.

<Evaluation Standard for Photolithography Properties (Diameter of 50 μm)>

A: vias having a diameter of 50 μm or less were able to be formed, there was no film reduction, and there was no residue at the bottom portion of the vias.

B: vias having a diameter of 50 μm or less were able to be formed, and there was no film reduction, but residues were found in a part of the bottom portion of the vias.

C: vias having a diameter of 50 μm or less were able to be formed, a film reduction of 5% or more and less than 10% occurred with respect to the thickness of the composition layer, and residues remained in a part of the bottom portion of the vias.

D: vias having a diameter of 50 μm or less were not able to be formed (including a case where photosensitivity was not exhibited and evaluation was not able to be carried out).

<Evaluation Standard for Photolithography Properties (Diameter of 30 μm)>

A: vias having a diameter of 30 μm or less were able to be formed, there was no film reduction, and there was no residue at the bottom portion of the vias.

B: vias having a diameter of 30 μm or less were able to be formed, and there was no film reduction, but residues were found in a part of the bottom portion of the vias.

C: vias having a diameter of 30 μm or less were able to be formed, a film reduction of 5% or more and less than 10% occurred with respect to the thickness of the composition layer, and residues remained in a part of the bottom portion of the vias.

D: vias having a diameter of 30 μm or less were not able to be formed (including a case where photosensitivity was not exhibited and evaluation was not able to be carried out).

### [Cycle Thermo Characteristics]

The composition was applied onto a copper pattern (line/space=10 μm/10 μm) having a thickness of 4 μm, which was formed as a wiring line in a comb shape on a silicon wafer base material, such that a thickness of the composition layer on the copper pattern was 10 μm, and dried to form a composition layer.

Next, in a case where the compositions shown in Tables 1 to 5 were used, the obtained composition layer was exposed using an ultra-high pressure mercury lamp. In this case, an integrated exposure amount measured with a 365 nm-wavelength illuminance meter was 5 mJ/cm². After the exposure, a heating treatment was performed at 230° C. for 180 minutes to produce a sample for evaluation.

In addition, in a case where the composition shown in Table 6 was used, the obtained composition layer was subjected to a heating treatment at 230° C. for 180 minutes to produce a sample for evaluation.

The sample for evaluation was left in a vapor phase at a temperature of −45° C. and 160° C. for 30 minutes using a vapor phase cold/heat tester, this cycle was repeated 100 times, and then the number of cracks in a region of 5 cm×5 cm of the sample for evaluation was observed and evaluated according to the following standard.

### <Evaluation Standard for Cycle Thermo Characteristics>

A: number of cracks was 3 or less.

B: number of cracks was more than 3 and 10 or less.

C: number of cracks was more than 10 and 20 or less.

D: number of cracks was more than 20.

### [Migration Resistance]

Each of the compositions was applied onto a copper pattern (line/space=10 μm/10 μm) having a thickness of 2.5 μm, which was formed as a wiring line in a comb shape on a silicon wafer base material, such that a thickness of the composition layer on the copper pattern was 10 μm, and dried to form a composition layer.

Next, in a case where the compositions described in Examples 1 to 100, 1-101, 1-102, 1-103, and Comparative Example 1 were used, the obtained composition layer was exposed using an ultra-high pressure mercury lamp. In this case, an integrated exposure amount measured with a 365 nm-wavelength illuminance meter was 100 mJ/cm². After the exposure, a heating treatment was performed at 230° C. for 180 minutes in a nitrogen atmosphere to produce a sample for evaluation.

In addition, in a case where the compositions described in Examples 101 to 136 were used, the obtained composition layer was subjected to a heating treatment at 230° C. for 180 minutes in a nitrogen atmosphere to produce a sample for evaluation.

The sample for evaluation was installed in a chamber at 130° C. and 85% RH (relative humidity) using a HAST tester, and the time at which migration occurred in a case where a voltage of 15 V was applied was measured. In a sample in which the initial resistance value measured at room temperature was 1×10¹⁴Ω or more, the time at which migration occurred at a time when the resistance value was 1×10³Ω or less was evaluated according to the following standard.

### <Evaluation Standard for Migration Resistance>

A: migration occurred in 72 hours or more, or did not occur.

B: migration occurred in 24 hours or more and 72 hours or less.

C: migration occurred in less than 24 hours.

Hereinafter, the content of various components and the evaluation results are shown.

The column of “Content in solid content” indicates a concentration of solid contents (% by mass) of the various components in the composition with respect to the total solid content.

The column of “e/a” indicates a mass ratio of the content of the thermal-base generator to the content of the resin X.

The column of “Developer in evaluation of photolithography properties” indicates a developer used in the evaluation of photolithography properties.

The column of “Content of surface modifier” indicates a content (% by mass) of the surface modifier with respect to the total mass of the filler.

The column of “Content of Na⁺ (ppm by mass)” indicates a content (ppm by mass) of the sodium ion with respect to the total solid content in the composition.

The column of “Content of Cl⁻ (ppm by mass)” indicates a content (ppm by mass) of the chloride ion with respect to the total solid content in the composition.

TABLE 1

| | | | | | | | (D) Photopoly- | |
|---|---|---|---|---|---|---|---|---|
| | | | | | (C) Polymerizable | | merization | |
| | (A) Resin | | (B) Filler | | compound | | initiator | |
| | | Content | | Content | | Content | | Content |
| | | in solid | | in solid | | in solid | | in solid |
| Table1-1 | Type | content | Type | content | Type | content | Type | content |
| Example 1 | Resin A | 17.6% | YA050C-MJE | 70.5% | NK3G | 10.6% | Oxe01 | 0.7% |
| Example 2 | Resin A | 17.9% | YA050C-MJE | 71.7% | NK3G | 9.0% | Oxe01 | 0.7% |
| Example 3 | Resin A | 20.5% | YA050C-MJE | 75.0% | NK3G | 3.1% | Oxe01 | 0.7% |
| Example 4 | Resin A | 16.4% | YA050C-MJE | 65.8% | NK3G | 16.4% | Oxe01 | 0.7% |
| Example 5 | Resin A | 13.6% | YA050C-MJE | 75.0% | NK3G | 10.0% | Oxe01 | 0.7% |
| Example 6 | Resin A | 27.5% | YA050C-MJE | 55.0% | NK3G | 16.1% | Oxe01 | 0.7% |
| Example 7 | Resin A | 17.6% | SFP-20M | 70.5% | NK3G | 10.6% | Oxe01 | 0.7% |
| Example 8 | Resin A | 27.5% | SFP-20M | 55.0% | NK3G | 16.1% | Oxe01 | 0.7% |
| Example 9 | Resin A | 17.6% | PMA-ST | 70.5% | NK3G | 10.6% | Oxe01 | 0.7% |
| Example 10 | Resin A | 17.6% | MEK-ST-L | 70.5% | NK3G | 10.6% | Oxe01 | 0.7% |
| Example 11 | Resin A | 17.6% | MEK-AC- | 70.5% | NK3G | 10.6% | Oxe01 | 0.7% |
| | | | 5140Z | | | | | |
| Example 12 | Resin A | 17.6% | NHM-5N | 70.5% | NK3G | 10.6% | Oxe01 | 0.7% |
| Example 13 | Resin A | 17.6% | Y50SP-AM1 | 70.5% | NK3G | 10.6% | Oxe01 | 0.7% |
| Example 14 | Resin A | 17.6% | Y50SZ-AM1 | 70.5% | NK3G | 10.6% | Oxe01 | 0.7% |
| Example 15 | Resin A | 17.6% | YA050C-MJE | 70.5% | NK4G | 10.6% | Oxe01 | 0.7% |
| Example 16 | Resin A | 17.9% | YA050C-MJE | 71.7% | NK4G | 9.0% | Oxe01 | 0.7% |
| Example 17 | Resin A | 20.5% | YA050C-MJE | 75.0% | NK4G | 3.1% | Oxe01 | 0.7% |

| | (E) Thermal-base generator | | | (G) Surfactant | | (H) Compound Y | |
|---|---|---|---|---|---|---|---|
| | | | Content | | Content | | Content |
| | | | in solid | | in solid | | in solid |
| Table1-2 | Type | e/a | content | Type | content | Type | content |
| Example 1 | Compound X | 0.02 | 0.4% | F551A | 0.2% | — | — |
| Example 2 | Compound X | 0.02 | 0.4% | F551A | 0.3% | — | — |
| Example 3 | Compound X | 0.02 | 0.5% | F551A | 0.2% | — | — |
| Example 4 | Compound X | 0.02 | 0.4% | F551A | 0.3% | — | — |
| Example 5 | Compound X | 0.03 | 0.4% | F551A | 0.3% | — | — |
| Example 6 | Compound X | 0.02 | 0.5% | F551A | 0.2% | — | — |
| Example 7 | Compound X | 0.02 | 0.4% | F551A | 0.2% | — | — |
| Example 8 | Compound X | 0.02 | 0.5% | F551A | 0.2% | — | — |
| Example 9 | Compound X | 0.02 | 0.4% | F551A | 0.2% | — | — |
| Example 10 | Compound X | 0.02 | 0.4% | F551A | 0.2% | — | — |
| Example 11 | Compound X | 0.02 | 0.4% | F551A | 0.2% | — | — |
| Example 12 | Compound X | 0.02 | 0.4% | F551A | 0.2% | — | — |
| Example 13 | Compound X | 0.02 | 0.4% | F551A | 0.2% | — | — |
| Example 14 | Compound X | 0.02 | 0.4% | F551A | 0.2% | — | — |
| Example 15 | Compound X | 0.02 | 0.4% | F551A | 0.2% | — | — |
| Example 16 | Compound X | 0.02 | 0.4% | F551A | 0.3% | — | — |
| Example 17 | Compound X | 0.02 | 0.5% | F551A | 0.2% | — | — |

| | (I) Additive | | Developer in | Measurement | | | | |
|---|---|---|---|---|---|---|---|---|
| | | Content | evaluation of | Average | | | | |
| | | in solid | photolithography | particle | | CTE | CTE | Relative |
| Table1-3 | Type | content | properties | diameter | | (X) | (Y/X) | permittivity |
| Example 1 | — | — | Cyclopentanone | 50 | nm | A | A | A |
| Example 2 | — | — | Cyclopentanone | 50 | nm | A | A | A |
| Example 3 | — | — | Cyclopentanone | 50 | nm | A | A | A |
| Example 4 | — | — | Cyclopentanone | 50 | nm | A | A | A |
| Example 5 | — | — | Cyclopentanone | 50 | nm | A | A | A |
| Example 6 | — | — | Cyclopentanone | 50 | nm | B | A | B |
| Example 7 | — | — | Cyclopentanone | 300 | nm | A | A | A |
| Example 8 | — | — | Cyclopentanone | 300 | nm | B | A | B |
| Example 9 | — | — | Cyclopentanone | 12 | nm | A | A | A |
| Example 10 | — | — | Cyclopentanone | 45 | nm | A | A | A |
| Example 11 | — | — | Cyclopentanone | 80 | nm | A | A | A |
| Example 12 | — | — | Cyclopentanone | 100 | nm | A | A | A |
| Example 13 | — | — | Cyclopentanone | 50 | nm | A | A | A |
| Example 14 | — | — | Cyclopentanone | 50 | nm | A | A | A |
| Example 15 | — | — | Cyclopentanone | 50 | nm | A | A | A |
| Example 16 | — | — | Cyclopentanone | 50 | nm | A | A | A |
| Example 17 | — | — | Cyclopentanone | 50 | nm | A | A | A |

| | Measurement | | | | Evaluation | | | |
|---|---|---|---|---|---|---|---|---|
| | | | Content | Content | Photoli- | Photoli- | Cycle | |
| | Dielectric | Content of | of Na⁺ | of Cl⁻ | thography | thography | thermo | |
| | loss | surface | (ppm by | (ppm by | properties | properties | character- | Migration |
| Table1-4 | tangent | modifier | mass) | mass) | φ50 μm | Φ30 μm | istics | resistance |
| Example 1 | A | 2% | 20 | 20 | A | A | A | B |
| Example 2 | A | 2% | 20 | 20 | A | A | A | B |
| Example 3 | A | 2% | 20 | 20 | A | A | A | B |
| Example 4 | B | 2% | 20 | 20 | A | A | A | B |
| Example 5 | A | 2% | 20 | 20 | A | A | A | B |
| Example 6 | B | 2% | 20 | 20 | A | A | C | B |
| Example 7 | A | 1% | 7 | 7 | B | B | B | A |
| Example 8 | B | 1% | 7 | 7 | B | B | C | A |
| Example 9 | A | 2% | 20 | 20 | A | A | A | B |
| Example 10 | A | 2% | 20 | 20 | A | A | A | B |
| Example 11 | A | 2% | 20 | 20 | A | A | A | B |
| Example 12 | A | 1% | 6 | 6 | A | A | A | A |
| Example 13 | A | 2% | 20 | 20 | A | A | A | B |
| Example 14 | A | 2% | 20 | 20 | A | A | A | B |
| Example 15 | A | 2% | 20 | 20 | A | A | A | B |
| Example 16 | A | 2% | 20 | 20 | A | A | A | B |
| Example 17 | A | 2% | 20 | 20 | A | A | A | B |

TABLE 2

| | | | | | | | (D) Photopoly- | |
|---|---|---|---|---|---|---|---|---|
| | | | | | (C) Polymerizable | | merization | |
| | (A) Resin | | (B) Filler | | compound | | initiator | |
| | | Content | | Content | | Content | | Content |
| | | in solid | | in solid | | in solid | | in solid |
| Table2-1 | Type | content | Type | content | Type | content | Type | content |
| Example 18 | Resin A | 16.4% | YA050C-MJE | 65.8% | NK4G | 16.4% | Oxe01 | 0.7% |
| Example 19 | Resin A | 13.6% | YA050C-MJE | 75.0% | NK4G | 10.0% | Oxe01 | 0.7% |
| Example 20 | Resin A | 27.5% | SFP-20M | 55.0% | NK4G | 16.1% | Oxe01 | 0.7% |
| Example 21 | Resin A | 17.6% | YA050C-MJE | 70.5% | NK3G | 10.6% | Oxe02 | 0.7% |
| Example 22 | Resin A | 17.6% | YA050C-MJE | 70.5% | NK3G | 10.6% | Oxe01 | 0.7% |
| Example 23 | Resin A | 17.6% | YA050C-MJE | 70.5% | NK3G | 10.6% | Oxe01 | 0.7% |
| Example 24 | Resin B | 17.6% | YA050C-MJE | 70.5% | NK3G | 10.6% | Oxe01 | 0.7% |
| Example 25 | Resin B | 17.9% | YA050C-MJE | 71.7% | NK3G | 9.0% | Oxe01 | 0.7% |
| Example 26 | Resin B | 20.5% | YA050C-MJE | 75.0% | NK3G | 3.1% | Oxe01 | 0.7% |
| Example 27 | Resin B | 16.4% | YA050C-MJE | 65.8% | NK3G | 16.4% | Oxe01 | 0.7% |
| Example 28 | Resin B | 13.6% | YA050C-MJE | 75.0% | NK3G | 10.0% | Oxe01 | 0.7% |
| Example 29 | Resin B | 27.5% | SFP-20M | 55.0% | NK3G | 16.1% | Oxe01 | 0.7% |
| Example 30 | Resin B | 17.6% | PMA-ST | 70.5% | NK3G | 10.6% | Oxe01 | 0.7% |
| Example 31 | Resin B | 17.6% | MEK-ST-L | 70.5% | NK3G | 10.6% | Oxe01 | 0.7% |
| Example 32 | Resin B | 17.6% | MEK-AC- | 70.5% | NK3G | 10.6% | Oxe01 | 0.7% |
| | | | 5140Z | | | | | |
| Example 33 | Resin B | 17.6% | YA050C-MJE | 70.5% | NK4G | 10.6% | Oxe01 | 0.7% |
| Example 34 | Resin B | 17.9% | YA050C-MJE | 71.7% | NK4G | 9.0% | Oxe01 | 0.7% |
| Example 35 | Resin B | 13.6% | YA050C-MJE | 75.0% | NK4G | 10.0% | Oxe01 | 0.7% |

| | (E) Thermal-base generator | | | (G) Surfactant | | (H) Compound Y | |
|---|---|---|---|---|---|---|---|
| | | | Content | | Content | | Content |
| | | | in solid | | in solid | | in solid |
| Table2-2 | Type | e/a | content | Type | content | Type | content |
| Example 18 | Compound X | 0.02 | 0.4% | F551A | 0.3% | — | — |
| Example 19 | Compound X | 0.03 | 0.4% | F551A | 0.3% | — | — |
| Example 20 | Compound X | 0.02 | 0.5% | F551A | 0.2% | — | — |
| Example 21 | Compound X | 0.02 | 0.4% | F551A | 0.2% | — | — |
| Example 22 | U-CAT SA506 | 0.02 | 0.4% | F551A | 0.2% | — | — |
| Example 23 | Compound X | 0.02 | 0.4% | S-324 | 0.2% | — | — |
| Example 24 | Compound X | 0.02 | 0.4% | F551A | 0.2% | — | — |
| Example 25 | Compound X | 0.02 | 0.4% | F551A | 0.3% | — | — |
| Example 26 | Compound X | 0.02 | 0.5% | F551A | 0.2% | — | — |
| Example 27 | Compound X | 0.02 | 0.4% | F551A | 0.3% | — | — |
| Example 28 | Compound X | 0.03 | 0.4% | F551A | 0.3% | — | — |
| Example 29 | Compound X | 0.02 | 0.5% | F551A | 0.2% | — | — |
| Example 30 | Compound X | 0.02 | 0.4% | F551A | 0.2% | — | — |
| Example 31 | Compound X | 0.02 | 0.4% | F551A | 0.2% | — | — |
| Example 32 | Compound X | 0.02 | 0.4% | F551A | 0.2% | — | — |
| Example 33 | Compound X | 0.02 | 0.4% | F551A | 0.2% | — | — |
| Example 34 | Compound X | 0.02 | 0.4% | F551A | 0.3% | — | — |
| Example 35 | Compound X | 0.03 | 0.4% | F551A | 0.3% | — | — |

| | (I) Additive | | Developer in | Measurement | | | | |
|---|---|---|---|---|---|---|---|---|
| | | Content | evaluation of | Average | | | | |
| | | in solid | photolithography | particle | | CTE | CTE | Relative |
| Table2-3 | Type | content | properties | diameter | | (X) | (Y/X) | permittivity |
| Example 18 | — | — | Cyclopentanone | 50 | nm | A | A | A |
| Example 19 | — | — | Cyclopentanone | 50 | nm | A | A | A |
| Example 20 | — | — | Cyclopentanone | 300 | nm | B | A | B |
| Example 21 | — | — | Cyclopentanone | 50 | nm | A | A | A |
| Example 22 | — | — | Cyclopentanone | 50 | nm | A | A | A |
| Example 23 | — | — | Cyclopentanone | 50 | nm | A | A | A |
| Example 24 | — | — | Cyclopentanone | 50 | nm | A | A | A |
| Example 25 | — | — | Cyclopentanone | 50 | nm | A | A | A |
| Example 26 | — | — | Cyclopentanone | 50 | nm | A | A | A |
| Example 27 | — | — | Cyclopentanone | 50 | nm | A | A | A |
| Example 28 | — | — | Cyclopentanone | 50 | nm | A | A | A |
| Example 29 | — | — | Cyclopentanone | 300 | nm | B | A | B |
| Example 30 | — | — | Cyclopentanone | 12 | nm | A | A | A |
| Example 31 | — | — | Cyclopentanone | 45 | nm | A | A | A |
| Example 32 | — | — | Cyclopentanone | 80 | nm | A | A | A |
| Example 33 | — | — | Cyclopentanone | 50 | nm | A | A | A |
| Example 34 | — | — | Cyclopentanone | 50 | nm | A | A | A |
| Example 35 | — | — | Cyclopentanone | 50 | nm | A | A | A |

| | Measurement | | | | Evaluation | | | |
|---|---|---|---|---|---|---|---|---|
| | | | Content | Content | Photoli- | Photoli- | Cycle | |
| | Dielectric | Content of | of Na⁺ | of Cl⁻ | thography | thography | thermo | |
| | loss | surface | (ppm by | (ppm by | properties | properties | character- | Migration |
| Table2-4 | tangent | modifier | mass) | mass) | φ50 μm | Φ30 μm | istics | resistance |
| Example 18 | B | 2% | 20 | 20 | A | A | A | B |
| Example 19 | A | 2% | 20 | 20 | A | A | A | B |
| Example 20 | B | 1% | 7 | 7 | B | B | C | A |
| Example 21 | A | 2% | 20 | 20 | A | A | A | B |
| Example 22 | A | 2% | 20 | 20 | A | A | A | B |
| Example 23 | A | 2% | 20 | 20 | A | A | A | B |
| Example 24 | A | 2% | 20 | 20 | A | B | A | B |
| Example 25 | A | 2% | 20 | 20 | A | B | A | B |
| Example 26 | A | 2% | 20 | 20 | A | B | A | B |
| Example 27 | B | 2% | 20 | 20 | A | B | A | B |
| Example 28 | A | 2% | 20 | 20 | A | B | A | B |
| Example 29 | B | 1% | 7 | 7 | B | C | C | A |
| Example 30 | A | 2% | 20 | 20 | A | B | A | B |
| Example 31 | A | 2% | 20 | 20 | A | B | A | B |
| Example 32 | A | 2% | 20 | 20 | A | B | A | B |
| Example 33 | A | 2% | 20 | 20 | A | B | A | B |
| Example 34 | A | 2% | 20 | 20 | A | B | A | B |
| Example 35 | A | 2% | 20 | 20 | A | B | A | B |

TABLE 3

| | | | (D) Photopoly- |
|---|---|---|---|
| | | (C) Polymerizable | merization |
| (A) Resin | (B) Filler | compound | initiator |

| | | Content | | Content | | Content | | Content |
|---|---|---|---|---|---|---|---|---|
| | | in solid | | in solid | | in solid | | in solid |
| Table3-1 | Type | content | Type | content | Type | content | Type | content |
| Example 36 | Resin C | 17.6% | YA050C-MJE | 70.5% | NK3G | 10.6% | Oxe01 | 0.7% |
| Example 37 | Resin C | 17.9% | YA050C-MJE | 71.7% | NK3G | 9.0% | Oxe01 | 0.7% |
| Example 38 | Resin C | 20.5% | YA050C-MJE | 75.0% | NK3G | 3.1% | Oxe01 | 0.7% |
| Example 39 | Resin C | 16.4% | YA050C-MJE | 65.8% | NK3G | 16.4% | Oxe01 | 0.7% |
| Example 40 | Resin C | 13.6% | YA050C-MJE | 75.0% | NK3G | 10.0% | Oxe01 | 0.7% |
| Example 41 | Resin C | 27.5% | SFP-20M | 55.0% | NK3G | 16.1% | Oxe01 | 0.7% |
| Example 42 | Resin D | 17.6% | YA050C-MJE | 70.5% | NK3G | 10.6% | Oxe01 | 0.7% |
| Example 43 | Resin D | 17.9% | YA050C-MJE | 71.7% | NK3G | 9.0% | Oxe01 | 0.7% |
| Example 44 | Resin D | 20.5% | YA050C-MJE | 75.0% | NK3G | 3.1% | Oxe01 | 0.7% |
| Example 45 | Resin D | 16.4% | YA050C-MJE | 65.8% | NK3G | 16.4% | Oxe01 | 0.7% |
| Example 46 | Resin D | 13.6% | YA050C-MJE | 75.0% | NK3G | 10.0% | Oxe01 | 0.7% |
| Example 47 | Resin D | 27.5% | SFP-20M | 55.0% | NK3G | 16.1% | Oxe01 | 0.7% |
| Example 48 | Resin A | 28.2% | YA050C-MJE | 70.5% | — | — | Oxe01 | 0.7% |
| Example 49 | Resin A | 23.6% | YA050C-MJE | 75.0% | — | — | Oxe01 | 0.7% |
| Comparative | ZCR-1569H | 38.0% | SC2050-LNF | 50.0% | DPHA | 6.0% | Omi819 | 6.0% |
| Example 1 | | | | | | | | |

| | | |
|---|---|---|
| (E) Thermal-base generator | (G) Surfactant | (H) Compound Y |

| | | | Content | | Content | | Content |
|---|---|---|---|---|---|---|---|
| | | | in solid | | in solid | | in solid |
| Table3-2 | Type | e/a | content | Type | content | Type | content |
| Example 36 | Compound X | 0.02 | 0.4% | F551A | 0.2% | — | — |
| Example 37 | Compound X | 0.02 | 0.4% | F551A | 0.3% | — | — |
| Example 38 | Compound X | 0.02 | 0.5% | F551A | 0.2% | — | — |
| Example 39 | Compound X | 0.02 | 0.4% | F551A | 0.3% | — | — |
| Example 40 | Compound X | 0.03 | 0.4% | F551A | 0.3% | — | — |
| Example 41 | Compound X | 0.02 | 0.5% | F551A | 0.2% | — | — |
| Example 42 | Compound X | 0.02 | 0.4% | F551A | 0.2% | — | — |
| Example 43 | Compound X | 0.02 | 0.4% | F551A | 0.3% | — | — |
| Example 44 | Compound X | 0.02 | 0.5% | F551A | 0.2% | — | — |
| Example 45 | Compound X | 0.02 | 0.4% | F551A | 0.3% | — | — |
| Example 46 | Compound X | 0.03 | 0.4% | F551A | 0.3% | — | — |
| Example 47 | Compound X | 0.02 | 0.5% | F551A | 0.2% | — | — |
| Example 48 | Compound X | 0.01 | 0.4% | F551A | 0.2% | — | — |
| Example 49 | Compound X | 0.02 | 0.5% | F551A | 0.2% | — | — |
| Comparative | — | — | — | — | — | — | — |
| Example 1 | | | | | | | |

| | (I) Additive | | Developer in | Measurement | | | | |
|---|---|---|---|---|---|---|---|---|
| | | Content | evaluation of | Average | | | | |
| | | in solid | photolithography | particle | | CTE | CTE | Relative |
| Table3-3 | Type | content | properties | diameter | | (X) | (Y/X) | permittivity |
| Example 36 | — | — | Na₂CO₃aq. | 50 | nm | A | A | A |
| Example 37 | — | — | Na₂CO₃aq. | 50 | nm | A | A | A |
| Example 38 | — | — | Na₂CO₃aq. | 50 | nm | A | A | A |
| Example 39 | — | — | Na₂CO₃aq. | 50 | nm | A | A | A |
| Example 40 | — | — | Na₂CO₃aq. | 50 | nm | A | A | A |
| Example 41 | — | — | Na₂CO₃aq. | 300 | nm | B | A | B |
| Example 42 | — | — | TMAHaq. | 50 | nm | A | A | A |
| Example 43 | — | — | TMAHaq. | 50 | nm | A | A | A |
| Example 44 | — | — | TMAHaq. | 50 | nm | A | A | A |
| Example 45 | — | — | TMAHaq. | 50 | nm | A | A | A |
| Example 46 | — | — | TMAHaq. | 50 | nm | A | A | A |
| Example 47 | — | — | TMAHaq. | 300 | nm | B | A | B |
| Example 48 | — | — | Cyclopentanone | 50 | nm | A | A | A |
| Example 49 | — | — | Cyclopentanone | 50 | nm | A | A | A |
| Comparative | — | — | Na₂CO₃aq. | 500 | nm | C | B | C |
| Example 1 | | | | | | | | |

| | Measurement | | | | Evaluation | | | |
|---|---|---|---|---|---|---|---|---|
| | | | Content | Content | Photoli- | Photoli- | Cycle | |
| | Dielectric | Content of | of Na⁺ | of Cl⁻ | thography | thography | thermo | |
| | loss | surface | (ppm by | (ppm by | properties | properties | character- | Migration |
| Table3-4 | tangent | modifier | mass) | mass) | φ50 μm | Φ30 μm | istics | resistance |
| Example 36 | A | 2% | 20 | 20 | A | B | A | B |
| Example 37 | A | 2% | 20 | 20 | A | B | A | B |
| Example 38 | A | 2% | 20 | 20 | A | B | A | B |
| Example 39 | B | 2% | 20 | 20 | A | B | A | B |
| Example 40 | A | 2% | 20 | 20 | A | B | A | B |
| Example 41 | B | 1% | 7 | 7 | B | C | C | A |
| Example 42 | A | 2% | 20 | 20 | A | B | A | B |
| Example 43 | A | 2% | 20 | 20 | A | B | A | B |
| Example 44 | A | 2% | 20 | 20 | A | B | A | B |
| Example 45 | B | 2% | 20 | 20 | A | B | A | B |
| Example 46 | A | 2% | 20 | 20 | A | B | A | B |
| Example 47 | B | 1% | 7 | 7 | B | C | C | A |
| Example 48 | A | 2% | 20 | 20 | C | C | A | B |
| Example 49 | A | 2% | 20 | 20 | C | C | A | B |
| Comparative | C | 4% | 30 | 30 | D | D | D | C |
| Example 1 | | | | | | | | |

TABLE 4

| | | | | | | | (D) Photopoly- | |
|---|---|---|---|---|---|---|---|---|
| | | | | | (C) Polymerizable | | merization | |
| | (A) Resin | | (B) Filler | | compound | | initiator | |
| | | Content | | Content | | Content | | Content |
| | | in solid | | in solid | | in solid | | in solid |
| Table4-1 | Type | content | Type | content | Type | content | Type | content |
| Example 50 | Resin A | 21.0% | NHM-5N | 55.0% | NK3G | 22.9% | Oxe01 | 0.20% |
| Example 51 | Resin A | 15.3% | NHM-5N | 60.7% | NK3G | 22.9% | Oxe01 | 0.20% |
| Example 52 | Resin A | 16.8% | NHM-5N | 66.4% | NK3G | 15.7% | Oxe01 | 0.20% |
| Example 53 | Resin A | 18.2% | NHM-5N | 71.7% | NK3G | 9.0% | Oxe01 | 0.20% |
| Example 54 | Resin A | 21.0% | NHM-5N | 55.0% | — | 0% | Oxe01 | 0.20% |
| Example 55 | Resin A | 15.3% | NHM-5N | 60.7% | — | 0% | Oxe01 | 0.20% |
| Example 56 | Resin A | 16.8% | NHM-5N | 66.4% | — | 0% | Oxe01 | 0.20% |
| Example 57 | Resin A | 18.2% | NHM-5N | 71.7% | — | 0% | Oxe01 | 0.20% |
| Example 58 | Resin A | 15.3% | NHM-5N | 60.7% | NK4G | 22.9% | Oxe01 | 0.20% |
| Example 59 | Resin A | 15.3% | NHM-5N | 60.7% | — | 0% | Oxe01 | 0.20% |
| Example 60 | Resin A | 15.3% | NHM-5N | 60.7% | — | 0% | Oxe01 | 0.20% |
| Example 61 | Resin A | 15.3% | NHM-5N | 60.7% | — | 0% | Oxe01 | 0.20% |
| Example 62 | Resin A | 15.3% | NP-5N | 60.7% | NK3G | 22.9% | Oxe01 | 0.20% |
| Example 63 | Resin A | 15.3% | NP-5N | 60.7% | NK4G | 22.9% | Oxe01 | 0.20% |
| Example 64 | Resin A | 15.3% | NP-5N | 60.7% | — | 0% | Oxe01 | 0.20% |
| Example 65 | Resin A | 15.3% | NP-5N | 60.7% | — | 0% | Oxe01 | 0.20% |
| Example 66 | Resin A | 15.3% | NP-5N | 60.7% | — | 0% | Oxe01 | 0.20% |
| Example 67 | Resin A | 15.3% | NP-5N | 60.7% | — | 0% | Oxe01 | 0.20% |
| Example 68 | Resin A | 15.3% | NHM-3N | 60.7% | NK3G | 22.9% | Oxe01 | 0.20% |
| Example 69 | Resin A | 15.3% | NHM-3N | 60.7% | NK4G | 22.9% | Oxe01 | 0.20% |
| Example 70 | Resin A | 15.3% | NHM-3N | 60.7% | — | 0% | Oxe01 | 0.20% |
| Example 71 | Resin A | 15.3% | NHM-3N | 60.7% | — | 0% | Oxe01 | 0.20% |
| Example 72 | Resin A | 15.3% | NHM-3N | 60.7% | — | 0% | Oxe01 | 0.20% |
| Example 73 | Resin A | 15.3% | NHM-3N | 60.7% | — | 0% | Oxe01 | 0.20% |
| Example 74 | Resin A | 15.2% | NHM-5N | 60.7% | NK3G | 22.4% | Oxe01 | 0.80% |
| Example 75 | Resin A | 15.2% | NHM-5N | 60.7% | NK4G | 22.4% | Oxe01 | 0.80% |
| Example 76 | Resin A | 15.2% | NHM-5N | 60.7% | — | 0% | Oxe01 | 0.80% |

| | | |
|---|---|---|
| (E) Thermal-base generator | (G) Surfactant | (H) Compound Y |

| | | | Content | | Content | | Content |
|---|---|---|---|---|---|---|---|
| | | | in solid | | in solid | | in solid |
| Table4-2 | Type | e/a | content | Type | content | Type | content |
| Example 50 | Compound X | 0.02 | 0.4% | F551A | 0.2% | — | — |
| Example 51 | Compound X | 0.03 | 0.4% | F551A | 0.2% | — | — |
| Example 52 | Compound X | 0.02 | 0.4% | F551A | 0.2% | — | — |
| Example 53 | Compound X | 0.02 | 0.4% | F551A | 0.2% | — | — |
| Example 54 | Compound X | 0.02 | 0.4% | F551A | 0.2% | Ethyl phthalyl | 22.9% |
| | | | | | | ethyl glycolate | |
| Example 55 | Compound X | 0.03 | 0.4% | F551A | 0.2% | Ethyl phthalyl | 22.9% |
| | | | | | | ethyl glycolate | |
| Example 56 | Compound X | 0.02 | 0.4% | F551A | 0.2% | Ethyl phthalyl | 15.7% |
| | | | | | | ethyl glycolate | |
| Example 57 | Compound X | 0.02 | 0.4% | F551A | 0.2% | Ethyl phthalyl | 9.0% |
| | | | | | | ethyl glycolate | |
| Example 58 | Compound X | 0.03 | 0.4% | F551A | 0.2% | — | — |
| Example 59 | Compound X | 0.03 | 0.4% | F551A | 0.2% | Dihexyl phthalate | 22.9% |
| Example 60 | Compound X | 0.03 | 0.4% | F551A | 0.2% | o-Acetyltrihydroxybutyl | 22.9% |
| | | | | | | citrate | |
| Example 61 | Compound X | 0.03 | 0.4% | F551A | 0.2% | Benzyl 2-ethylhexyl | 22.9% |
| | | | | | | phthalate | |
| Example 62 | Compound X | 0.03 | 0.4% | F551A | 0.2% | — | — |
| Example 63 | Compound X | 0.03 | 0.4% | F551A | 0.2% | — | — |
| Example 64 | Compound X | 0.03 | 0.4% | F551A | 0.2% | Ethyl phthalyl | 22.9% |
| | | | | | | ethyl glycolate | |
| Example 65 | Compound X | 0.03 | 0.4% | F551A | 0.2% | Dihexyl phthalate | 22.9% |
| Example 66 | Compound X | 0.03 | 0.4% | F551A | 0.2% | o-Acetyltrihydroxybutyl | 22.9% |
| | | | | | | citrate | |
| Example 67 | Compound X | 0.03 | 0.4% | F551A | 0.2% | Benzyl 2-ethylhexyl | 22.9% |
| | | | | | | phthalate | |
| Example 68 | Compound X | 0.03 | 0.4% | F551A | 0.2% | — | — |
| Example 69 | Compound X | 0.03 | 0.4% | F551A | 0.2% | — | — |
| Example 70 | Compound X | 0.03 | 0.4% | F551A | 0.2% | Ethyl phthalyl ethyl | 22.9% |
| | | | | | | glycolate | |
| Example 71 | Compound X | 0.03 | 0.4% | F551A | 0.2% | Dihexyl phthalate | 22.9% |
| Example 72 | Compound X | 0.03 | 0.4% | F551A | 0.2% | o-Acetyltrihydroxybutyl | 22.9% |
| | | | | | | citrate | |
| Example 73 | Compound X | 0.03 | 0.4% | F551A | 0.2% | Benzyl 2-ethylhexyl | 22.9% |
| | | | | | | phthalate | |
| Example 74 | Compound X | 0.03 | 0.4% | F551A | 0.2% | — | — |
| Example 75 | Compound X | 0.03 | 0.4% | F551A | 0.2% | — | — |
| Example 76 | Compound X | 0.03 | 0.4% | F551A | 0.2% | Ethyl phthalyl | 22.4% |
| | | | | | | ethyl glycolate | |

| | (I) Additive | | Developer in | Measurement | | | |
|---|---|---|---|---|---|---|---|
| | | Content | evaluation of | Average | | | |
| | | in solid | photolithography | particle | CTE | CTE | Relative |
| Table4-3 | Type | content | properties | diameter | (X) | (Y/X) | permittivity |
| Example 50 | HAT | 0.3% | Cyclopentanone | 100 nm | B | A | A |
| Example 51 | HAT | 0.3% | Cyclopentanone | 100 nm | A | A | A |
| Example 52 | HAT | 0.3% | Cyclopentanone | 100 nm | A | A | A |
| Example 53 | HAT | 0.3% | Cyclopentanone | 100 nm | A | A | A |
| Example 54 | HAT | 0.3% | Cyclopentanone | 100 nm | B | A | A |
| Example 55 | HAT | 0.3% | Cyclopentanone | 100 nm | A | A | A |
| Example 56 | HAT | 0.3% | Cyclopentanone | 100 nm | A | A | A |
| Example 57 | HAT | 0.3% | Cyclopentanone | 100 nm | A | A | A |
| Example 58 | HAT | 0.3% | Cyclopentanone | 100 nm | A | A | A |
| Example 59 | HAT | 0.3% | Cyclopentanone | 100 nm | A | A | A |
| Example 60 | HAT | 0.3% | Cyclopentanone | 100 nm | A | A | A |
| Example 61 | HAT | 0.3% | Cyclopentanone | 100 nm | A | A | A |
| Example 62 | HAT | 0.3% | Cyclopentanone | 100 nm | A | A | A |
| Example 63 | HAT | 0.3% | Cyclopentanone | 100 nm | A | A | A |
| Example 64 | HAT | 0.3% | Cyclopentanone | 100 nm | A | A | A |
| Example 65 | HAT | 0.3% | Cyclopentanone | 100 nm | A | A | A |
| Example 66 | HAT | 0.3% | Cyclopentanone | 100 nm | A | A | A |
| Example 67 | HAT | 0.3% | Cyclopentanone | 100 nm | A | A | A |
| Example 68 | HAT | 0.3% | Cyclopentanone | 150 nm | A | A | A |
| Example 69 | HAT | 0.3% | Cyclopentanone | 150 nm | A | A | A |
| Example 70 | HAT | 0.3% | Cyclopentanone | 150 nm | A | A | A |
| Example 71 | HAT | 0.3% | Cyclopentanone | 150 nm | A | A | A |
| Example 72 | HAT | 0.3% | Cyclopentanone | 150 nm | A | A | A |
| Example 73 | HAT | 0.3% | Cyclopentanone | 150 nm | A | A | A |
| Example 74 | HAT | 0.3% | Cyclopentanone | 100 nm | A | A | A |
| Example 75 | HAT | 0.3% | Cyclopentanone | 100 nm | A | A | A |
| Example 76 | HAT | 0.3% | Cyclopentanone | 100 nm | A | A | A |

| | Measurement | | | | Evaluation | | | |
|---|---|---|---|---|---|---|---|---|
| | | | Content | Content | Photoli- | Photoli- | Cycle | |
| | Dielectric | Content of | of Na⁺ | of Cl⁻ | thography | thography | thermo | |
| | loss | surface | (ppm by | (ppm by | properties | properties | character- | Migration |
| Table4-4 | tangent | modifier | mass) | mass) | φ50 μm | Φ30 μm | istics | resistance |
| Example 50 | A | 1% | 6 | 6 | A | A | A | A |
| Example 51 | A | 1% | 6 | 6 | A | A | A | A |
| Example 52 | A | 1% | 6 | 6 | A | A | A | A |
| Example 53 | A | 1% | 6 | 6 | A | A | A | A |
| Example 54 | A | 1% | 6 | 6 | A | A | A | A |
| Example 55 | A | 1% | 6 | 6 | A | A | A | A |
| Example 56 | A | 1% | 6 | 6 | A | A | A | A |
| Example 57 | A | 1% | 6 | 6 | A | A | A | A |
| Example 58 | A | 1% | 6 | 6 | A | A | A | A |
| Example 59 | A | 1% | 6 | 6 | A | A | A | A |
| Example 60 | A | 1% | 6 | 6 | A | A | A | A |
| Example 61 | A | 1% | 6 | 6 | A | A | A | A |
| Example 62 | A | 1% | 6 | 6 | A | A | A | A |
| Example 63 | A | 1% | 6 | 6 | A | A | A | A |
| Example 64 | A | 1% | 6 | 6 | A | A | A | A |
| Example 65 | A | 1% | 6 | 6 | A | A | A | A |
| Example 66 | A | 1% | 6 | 6 | A | A | A | A |
| Example 67 | A | 1% | 6 | 6 | A | A | A | A |
| Example 68 | A | 1% | 6 | 6 | B | A | A | A |
| Example 69 | A | 1% | 6 | 6 | B | A | A | A |
| Example 70 | A | 1% | 6 | 6 | B | A | A | A |
| Example 71 | A | 1% | 6 | 6 | B | A | A | A |
| Example 72 | A | 1% | 6 | 6 | B | A | A | A |
| Example 73 | A | 1% | 6 | 6 | B | A | A | A |
| Example 74 | A | 1% | 6 | 6 | A | A | A | A |
| Example 75 | A | 1% | 6 | 6 | A | A | A | A |
| Example 76 | A | 1% | 6 | 6 | A | A | A | A |

TABLE 5

| | | | | | | | (D) Photopoly- | |
|---|---|---|---|---|---|---|---|---|
| | | | | | (C) Polymerizable | | merization | |
| | (A) Resin | | (B) Filler | | compound | | initiator | |
| | | Content | | Content | | Content | | Content |
| | | in solid | | in solid | | in solid | | in solid |
| Table5-1 | Type | content | Type | content | Type | content | Type | content |
| Example 77 | Resin A | 15.1% | NHM-5N | 60.7% | NK3G | 22.5% | Oxe01 | 0.20% |
| Example 78 | Resin A | 15.1% | NHM-5N | 60.7% | NK4G | 22.5% | Oxe01 | 0.20% |
| Example 79 | Resin A | 15.1% | NHM-5N | 60.7% | — | 0% | Oxe01 | 0.20% |
| Example 80 | Resin A | 15.3% | NHM-5N | 60.7% | NK3G | 22.7% | Oxe01 | 0.20% |
| Example 81 | Resin A | 15.3% | NHM-5N | 60.7% | NK4G | 22.7% | Oxe01 | 0.20% |
| Example 82 | Resin A | 15.3% | NHM-5N | 60.7% | — | 0% | Oxe01 | 0.20% |
| Example 83 | Resin A | 15.3% | NHM-5N | 60.7% | NK3G | 22.7% | Oxe01 | 0.20% |
| Example 84 | Resin A | 15.3% | NHM-5N | 60.7% | NK4G | 22.7% | Oxe01 | 0.20% |
| Example 85 | Resin A | 15.3% | NHM-5N | 60.7% | — | 0% | Oxe01 | 0.20% |
| Example 86 | Resin A | 15.3% | NHM-5N | 60.7% | NK3G | 22.3% | Oxe01 | 0.20% |
| Example 87 | Resin A | 15.3% | NHM-5N | 60.7% | NK4G | 22.3% | Oxe01 | 0.20% |
| Example 88 | Resin A | 15.3% | NHM-5N | 60.7% | — | 0% | Oxe01 | 0.20% |
| Example 89 | Resin A | 15.3% | NHM-5N | 60.7% | NK3G | 22.9% | Oxe02 | 0.20% |
| Example 90 | Resin A | 15.3% | NHM-5N | 60.7% | NK3G | 22.9% | Oxe01 | 0.20% |
| Example 91 | Resin A | 15.3% | NHM-5N | 60.7% | NK3G | 22.9% | Oxe01 | 0.20% |
| Example 92 | Resin A | 15.3% | NHM-5N | 60.7% | NK3G | 23.2% | Oxe01 | 0.20% |
| Example 93 | Resin A | 15.3% | NHM-5N | 60.7% | — | 0% | Oxe02 | 0.20% |
| Example 94 | Resin A | 15.3% | NHM-5N | 60.7% | — | 0% | Oxe01 | 0.20% |
| Example 95 | Resin A | 15.3% | NHM-5N | 60.7% | — | 0% | Oxe01 | 0.20% |
| Example 96 | Resin A | 15.3% | NHM-5N | 60.7% | — | 0% | Oxe01 | 0.20% |
| Example 97 | Resin B | 15.3% | NHM-5N | 60.7% | NK3G | 22.9% | Oxe01 | 0.20% |
| Example 98 | Resin B | 15.3% | NHM-5N | 60.7% | — | 0% | Oxe01 | 0.20% |
| Example 99 | Resin C | 15.3% | NHM-5N | 60.7% | NK3G | 22.9% | Oxe01 | 0.20% |
| Example 100 | Resin C | 15.3% | NHM-5N | 60.7% | NK4G | 22.9% | Oxe01 | 0.20% |
| Example 1-101 | Resin D | 15.3% | NHM-5N | 60.7% | NK3G | 22.9% | Oxe01 | 0.20% |
| Example 1-102 | Resin D | 15.3% | NHM-5N | 60.7% | NK4G | 22.9% | Oxe01 | 0.20% |
| Example 1-103 | Resin A | 15.3% | Pre-adjusted | 64.0% | NK3G | 19.9% | Oxe01 | 0.20% |
| | | | product A | | | | | |

| | (E) Thermal-base generator | | | (G) Surfactant | | (H) Compound Y | |
|---|---|---|---|---|---|---|---|
| | | | Content | | Content | | Content |
| | | | in solid | | in solid | | in solid |
| Table5-2 | Type | e/a | content | Type | content | Type | content |
| Example 77 | Compound X | 0.07 | 1.0% | F551A | 0.2% | — | — |
| Example 78 | Compound X | 0.07 | 1.0% | F551A | 0.2% | — | — |
| Example 79 | Compound X | 0.07 | 1.0% | F551A | 0.2% | Ethyl phthalyl | 22.5% |
| | | | | | | ethyl glycolate | |
| Example 80 | Compound X | 0.03 | 0.4% | S-324 | 0.4% | — | — |
| Example 81 | Compound X | 0.03 | 0.4% | S-324 | 0.4% | — | — |
| Example 82 | Compound X | 0.03 | 0.4% | S-324 | 0.4% | Ethyl phthalyl | 22.7% |
| | | | | | | ethyl glycolate | |
| Example 83 | Compound X | 0.03 | 0.4% | S-506 | 0.4% | — | — |
| Example 84 | Compound X | 0.03 | 0.4% | S-506 | 0.4% | — | — |
| Example 85 | Compound X | 0.03 | 0.4% | S-506 | 0.4% | Ethyl phthalyl | 22.7% |
| | | | | | | ethyl glycolate | |
| Example 86 | Compound X | 0.03 | 0.4% | F551A | 0.2% | — | — |
| Example 87 | Compound X | 0.03 | 0.4% | F551A | 0.2% | — | — |
| Example 88 | Compound X | 0.03 | 0.4% | F551A | 0.2% | Ethyl phthalyl | 22.3% |
| | | | | | | ethyl glycolate | |
| Example 89 | Compound X | 0.03 | 0.4% | F551A | 0.2% | — | — |
| Example 90 | U-CAT SA506 | 0.03 | 0.4% | F551A | 0.2% | — | — |
| Example 91 | Compound X | 0.03 | 0.4% | F551A | 0.2% | — | — |
| Example 92 | Compound X | 0.03 | 0.4% | F551A | 0.2% | — | — |
| Example 93 | Compound X | 0.03 | 0.4% | F551A | 0.2% | Ethyl phthalyl | 22.9% |
| | | | | | | ethyl glycolate | |
| Example 94 | U-CAT SA506 | 0.03 | 0.4% | F551A | 0.2% | Ethyl phthalyl | 22.9% |
| | | | | | | ethyl glycolate | |
| Example 95 | Compound X | 0.03 | 0.4% | F551A | 0.2% | Ethyl phthalyl | 22.9% |
| | | | | | | ethyl glycolate | |
| Example 96 | Compound X | 0.03 | 0.4% | F551A | 0.2% | Ethyl phthalyl | 23.2% |
| | | | | | | ethyl glycolate | |
| Example 97 | Compound X | 0.03 | 0.4% | F551A | 0.2% | — | — |
| Example 98 | Compound X | 0.03 | 0.4% | F551A | 0.2% | Ethyl phthalyl | 22.9% |
| | | | | | | ethyl glycolate | |
| Example 99 | Compound X | 0.03 | 0.4% | F551A | 0.2% | — | — |
| Example 100 | Compound X | 0.03 | 0.4% | F551A | 0.2% | — | — |
| Example 1-101 | Compound X | 0.03 | 0.4% | F551A | 0.2% | — | — |
| Example 1-102 | Compound X | 0.03 | 0.4% | F551A | 0.2% | — | — |
| Example 1-103 | Compound X | 0.03 | 0.4% | F551A | 0.2% | — | — |

| | (I) Additive | | Developer in | Measurement | | | |
|---|---|---|---|---|---|---|---|
| | | Content | evaluation of | Average | | | |
| | | in solid | photolithography | particle | CTE | CTE | Relative |
| Table5-3 | Type | content | properties | diameter | (X) | (Y/X) | permittivity |
| Example 77 | HAT | 0.3% | Cyclopentanone | 100 nm | A | A | A |
| Example 78 | HAT | 0.3% | Cyclopentanone | 100 nm | A | A | A |
| Example 79 | HAT | 0.3% | Cyclopentanone | 100 nm | A | A | A |
| Example 80 | HAT | 0.3% | Cyclopentanone | 100 nm | A | A | A |
| Example 81 | HAT | 0.3% | Cyclopentanone | 100 nm | A | A | A |
| Example 82 | HAT | 0.3% | Cyclopentanone | 100 nm | A | A | A |
| Example 83 | HAT | 0.3% | Cyclopentanone | 100 nm | A | A | A |
| Example 84 | HAT | 0.3% | Cyclopentanone | 100 nm | A | A | A |
| Example 85 | HAT | 0.3% | Cyclopentanone | 100 nm | A | A | A |
| Example 86 | HAT | 0.9% | Cyclopentanone | 100 nm | A | A | A |
| Example 87 | HAT | 0.9% | Cyclopentanone | 100 nm | A | A | A |
| Example 88 | HAT | 0.9% | Cyclopentanone | 100 nm | A | A | A |
| Example 89 | HAT | 0.3% | Cyclopentanone | 100 nm | A | A | A |
| Example 90 | HAT | 0.3% | Cyclopentanone | 100 nm | A | A | A |
| Example 91 | ATA | 0.3% | Cyclopentanone | 100 nm | A | A | A |
| Example 92 | — | — | Cyclopentanone | 100 nm | A | A | A |
| Example 93 | HAT | 0.3% | Cyclopentanone | 100 nm | A | A | A |
| Example 94 | HAT | 0.3% | Cyclopentanone | 100 nm | A | A | A |
| Example 95 | ATA | 0.3% | Cyclopentanone | 150 nm | A | A | A |
| Example 96 | — | — | Cyclopentanone | 100 nm | A | A | A |
| Example 97 | HAT | 0.3% | Cyclopentanone | 100 nm | A | A | A |
| Example 98 | HAT | 0.3% | Cyclopentanone | 100 nm | A | A | A |
| Example 99 | HAT | 0.3% | Cyclopentanone | 100 nm | A | A | A |
| Example 100 | HAT | 0.3% | Cyclopentanone | 100 nm | A | A | A |
| Example 1-101 | HAT | 0.3% | Cyclopentanone | 100 nm | A | A | A |
| Example 1-102 | HAT | 0.3% | Cyclopentanone | 100 nm | A | A | A |
| Example 1-103 | — | — | Cyclopentanone | 100 nm | C | B | C |

| | Measurement | | | | Evaluation | | | |
|---|---|---|---|---|---|---|---|---|
| | | | Content | Content | Photoli- | Photoli- | Cycle | |
| | Dielectric | Content of | of Na⁺ | of Cl⁻ | thography | thography | thermo | |
| | loss | surface | (ppm by | (ppm by | properties | properties | character- | Migration |
| Table5-4 | tangent | modifier | mass) | mass) | φ50 μm | Φ30 μm | istics | resistance |
| Example 77 | A | 1% | 6 | 6 | A | A | A | A |
| Example 78 | A | 1% | 6 | 6 | A | A | A | A |
| Example 79 | A | 1% | 6 | 6 | A | A | A | A |
| Example 80 | A | 1% | 6 | 6 | A | A | A | A |
| Example 81 | A | 1% | 6 | 6 | A | A | A | A |
| Example 82 | A | 1% | 6 | 6 | A | A | A | A |
| Example 83 | A | 1% | 6 | 6 | A | A | A | A |
| Example 84 | A | 1% | 6 | 6 | A | A | A | A |
| Example 85 | A | 1% | 6 | 6 | A | A | A | A |
| Example 86 | A | 1% | 6 | 6 | A | A | A | A |
| Example 87 | A | 1% | 6 | 6 | A | A | A | A |
| Example 88 | A | 1% | 6 | 6 | A | A | A | A |
| Example 89 | A | 1% | 6 | 6 | A | A | A | A |
| Example 90 | A | 1% | 6 | 6 | A | A | A | A |
| Example 91 | A | 1% | 6 | 6 | A | A | A | A |
| Example 92 | A | 1% | 6 | 6 | A | A | A | A |
| Example 93 | A | 1% | 6 | 6 | A | A | A | A |
| Example 94 | A | 1% | 6 | 6 | A | A | A | A |
| Example 95 | A | 1% | 6 | 6 | A | A | A | A |
| Example 96 | A | 1% | 6 | 6 | A | A | A | A |
| Example 97 | A | 1% | 6 | 6 | A | A | A | A |
| Example 98 | A | 1% | 6 | 6 | A | A | A | A |
| Example 99 | A | 1% | 6 | 6 | A | A | A | A |
| Example 100 | A | 1% | 6 | 6 | A | A | A | A |
| Example 1-101 | A | 1% | 6 | 6 | A | A | A | A |
| Example 1-102 | A | 1% | 6 | 6 | A | A | A | A |
| Example 1-103 | C | 6% | 100 | 100 | C | C | C | C |

TABLE 6

| | | | |
|---|---|---|---|
| | | (F) Photoacid | |
| (A) Resin | (B) Filler | generator | (G) Surfactant |

| | | Content | | Content | | Content | | Content |
|---|---|---|---|---|---|---|---|---|
| | | in solid | | in solid | | in solid | | in solid |
| Table6-1 | Type | content | Type | content | Type | content | Type | content |
| Example 101 | Resin E | 26.6% | YA050C-MJE | 72.0% | PAG1 | 1.2% | F551A | 0.2% |
| Example 102 | Resin E | 23.6% | YA050C-MJE | 75.0% | PAG1 | 1.1% | F551A | 0.3% |
| Example 103 | Resin E | 20.3% | YA050C-MJE | 78.5% | PAG1 | 1.0% | F551A | 0.2% |
| Example 104 | Resin E | 40.8% | SFP-20M | 55.0% | PAG1 | 4.0% | F551A | 0.2% |
| Example 105 | Resin E | 23.7% | PMA-ST | 75.0% | PAG1 | 1.1% | F551A | 0.2% |
| Example 106 | Resin E | 23.7% | MEK-ST-L | 75.0% | PAG1 | 1.1% | F551A | 0.2% |
| Example 107 | Resin E | 23.7% | MEK-AC- | 75.0% | PAG1 | 1.1% | F551A | 0.2% |
| | | | 5140Z | | | | | |
| Example 108 | Resin E | 23.7% | NHM-5N | 75.0% | PAG1 | 1.1% | F551A | 0.2% |
| Example 109 | Resin E | 23.7% | Y50SP-AM1 | 75.0% | PAG1 | 1.1% | F551A | 0.2% |
| Example 110 | Resin E | 23.7% | Y50SZ-AM1 | 75.0% | PAG1 | 1.1% | F551A | 0.2% |
| Example 111 | Resin E | 26.6% | YA050C-MJE | 72.0% | CPI-100P | 1.2% | F551A | 0.2% |
| Example 112 | Resin E | 23.6% | YA050C-MJE | 75.0% | CPI-100P | 1.1% | F551A | 0.3% |
| Example 113 | Resin E | 20.3% | YA050C-MJE | 78.5% | CPI-100P | 1.0% | F551A | 0.2% |
| Example 114 | Resin F | 26.6% | YA050C-MJE | 72.0% | PAG1 | 1.2% | F551A | 0.2% |
| Example 115 | Resin F | 23.6% | YA050C-MJE | 75.0% | PAG1 | 1.1% | F551A | 0.3% |
| Example 116 | Resin F | 20.3% | YA050C-MJE | 78.5% | PAG1 | 1.0% | F551A | 0.2% |
| Example 117 | Resin F | 40.6% | SFP-20M | 55.0% | PAG1 | 4.0% | F551A | 0.2% |
| Example 118 | Resin F | 23.7% | PMA-ST | 75.0% | PAG1 | 1.1% | F551A | 0.2% |
| Example 119 | Resin F | 23.7% | MEK-ST-L | 75.0% | PAG1 | 1.1% | F551A | 0.2% |
| Example 120 | Resin F | 23.7% | MEK-AC- | 75.0% | PAG1 | 1.1% | F551A | 0.2% |
| | | | 5140Z | | | | | |
| Example 121 | Resin E | 33.0% | NHM-5N | 65.0% | PAG1 | 1.5% | F551A | 0.2% |
| Example 122 | Resin E | 28.1% | NHM-5N | 70.0% | PAG1 | 1.3% | F551A | 0.3% |
| Example 123 | Resin E | 23.4% | NHM-5N | 75.0% | PAG1 | 1.1% | F551A | 0.2% |
| Example 124 | Resin E | 28.1% | NP-5N | 70.0% | PAG1 | 1.3% | F551A | 0.3% |
| Example 125 | Resin E | 28.1% | NHM-3N | 70.0% | PAG1 | 1.3% | F551A | 0.3% |
| Example 126 | Resin E | 28.1% | NHM-5N | 70.0% | PAG1 | 1.3% | F551A | 0.3% |
| Example 127 | Resin E | 28.4% | NHM-5N | 70.0% | PAG1 | 1.3% | F551A | 0.3% |
| Example 128 | Resin F | 33.0% | NHM-5N | 65.0% | PAG1 | 1.5% | F551A | 0.2% |
| Example 129 | Resin F | 28.1% | NHM-5N | 70.0% | PAG1 | 1.3% | F551A | 0.3% |
| Example 130 | Resin F | 23.4% | NHM-5N | 75.0% | PAG1 | 1.1% | F551A | 0.2% |
| Example 131 | Resin F | 28.1% | NP-5N | 70.0% | PAG1 | 1.3% | F551A | 0.3% |
| Example 132 | Resin F | 28.1% | NHM-3N | 70.0% | PAG1 | 1.3% | F551A | 0.3% |
| Example 133 | Resin F | 28.1% | NHM-5N | 70.0% | PAG1 | 1.3% | F551A | 0.3% |
| Example 134 | Resin F | 28.4% | NHM-5N | 70.0% | PAG1 | 1.3% | F551A | 0.30% |
| Example 135 | Resin E | 15.3% | NHM-5N | 60.5% | PAG1 | 0.7% | F551A | 0.30% |
| Example 136 | Resin F | 15.3% | NHM-5N | 60.5% | PAG1 | 0.7% | F551A | 0.30% |

| | | |
|---|---|---|
| (H) Compound Y | (I) Additive | Developer in |

| | | Content | | Content | evaluation of |
|---|---|---|---|---|---|
| | | in solid | | in solid | photolithography |
| Table6-2 | Type | content | Type | content | properties |
| Example 101 | — | — | — | — | TMAHaq. |
| Example 102 | — | — | — | — | TMAHaq. |
| Example 103 | — | — | — | — | TMAHaq. |
| Example 104 | — | — | — | — | TMAHaq. |
| Example 105 | — | — | — | — | TMAHaq. |
| Example 106 | — | — | — | — | TMAHaq. |
| Example 107 | — | — | — | — | TMAHaq. |
| Example 108 | — | — | — | — | TMAHaq. |
| Example 109 | — | — | — | — | TMAHaq. |
| Example 110 | — | — | — | — | TMAHaq. |
| Example 111 | — | — | — | — | TMAHaq. |
| Example 112 | — | — | — | — | TMAHaq. |
| Example 113 | — | — | — | — | TMAHaq. |
| Example 114 | — | — | — | — | Na₂CO₃aq. |
| Example 115 | — | — | — | — | Na₂CO₃aq. |
| Example 116 | — | — | — | — | Na₂CO₃aq. |
| Example 117 | — | — | — | — | Na₂CO₃aq. |
| Example 118 | — | — | — | — | Na₂CO₃aq. |
| Example 119 | — | — | — | — | Na₂CO₃aq. |
| Example 120 | — | — | — | — | Na₂CO₃aq. |
| Example 121 | — | — | HAT | 0.3% | TMAHaq. |
| Example 122 | — | — | HAT | 0.3% | TMAHaq. |
| Example 123 | — | — | HAT | 0.3% | TMAHaq. |
| Example 124 | — | — | HAT | 0.3% | TMAHaq. |
| Example 125 | — | — | HAT | 0.3% | TMAHaq. |
| Example 126 | — | — | ATA | 0.3% | TMAHaq. |
| Example 127 | — | — | — | — | TMAHaq. |
| Example 128 | — | — | HAT | 0.3% | Na₂CO₃aq. |
| Example 129 | — | — | HAT | 0.3% | Na₂CO₃aq. |
| Example 130 | — | — | HAT | 0.3% | Na₂CO₃aq. |
| Example 131 | — | — | HAT | 0.3% | Na₂CO₃aq. |
| Example 132 | — | — | HAT | 0.3% | Na₂CO₃aq. |
| Example 133 | — | — | ATA | 0.3% | Na₂CO₃aq. |
| Example 134 | — | — | — | — | Na₂CO₃aq. |
| Example 135 | Ethyl phthalyl | 22.9% | HAT | 0.3% | TMAHaq. |
| | ethyl glycolate | | | | |
| Example 136 | Ethyl phthalyl | 22.9% | HAT | 0.3% | Na₂CO₃aq. |
| | ethyl glycolate | | | | |

| | Measurement | | | | | | | | |
|---|---|---|---|---|---|---|---|---|---|
| | | | | | | | | Content | Content |
| | Average | | | | | Dielectric | Content of | of Na⁺ | of Cl⁻ |
| | particle | | CTE | CTE | Relative | loss | surface | (ppm by | (ppm by |
| Table6-3 | diameter | | (X) | (Y/X) | permittivity | tangent | modifier | mass) | mass) |
| Example 101 | 50 | nm | A | A | A | A | 2% | 20 | 20 |
| Example 102 | 50 | nm | A | A | A | A | 2% | 20 | 20 |
| Example 103 | 50 | nm | A | A | A | A | 2% | 20 | 20 |
| Example 104 | 300 | nm | B | A | B | B | 1% | 7 | 7 |
| Example 105 | 12 | nm | A | A | A | A | 2% | 20 | 20 |
| Example 106 | 45 | nm | A | A | A | A | 2% | 20 | 20 |
| Example 107 | 80 | nm | A | A | A | A | 2% | 20 | 20 |
| Example 108 | 100 | nm | A | A | A | A | 1% | 6 | 6 |
| Example 109 | 50 | nm | A | A | A | A | 2% | 20 | 20 |
| Example 110 | 50 | nm | A | A | A | A | 2% | 20 | 20 |
| Example 111 | 50 | nm | A | A | A | A | 2% | 20 | 20 |
| Example 112 | 50 | nm | A | A | A | A | 2% | 20 | 20 |
| Example 113 | 50 | nm | A | A | A | A | 2% | 20 | 20 |
| Example 114 | 50 | nm | A | A | A | A | 2% | 20 | 20 |
| Example 115 | 50 | nm | A | A | A | A | 2% | 20 | 20 |
| Example 116 | 50 | nm | A | A | A | A | 2% | 20 | 20 |
| Example 117 | 300 | nm | B | A | B | B | 1% | 7 | 7 |
| Example 118 | 12 | nm | A | A | A | A | 2% | 20 | 20 |
| Example 119 | 45 | nm | A | A | A | A | 2% | 20 | 20 |
| Example 120 | 80 | nm | A | A | A | A | 2% | 20 | 20 |
| Example 121 | 100 | nm | A | A | A | A | 1% | 6 | 6 |
| Example 122 | 100 | nm | A | A | A | A | 1% | 6 | 6 |
| Example 123 | 100 | nm | A | A | A | A | 1% | 6 | 6 |
| Example 124 | 100 | nm | A | A | A | A | 1% | 6 | 6 |
| Example 125 | 150 | nm | A | A | A | A | 1% | 6 | 6 |
| Example 126 | 100 | nm | A | A | A | A | 1% | 6 | 6 |
| Example 127 | 100 | nm | A | A | A | A | 1% | 6 | 6 |
| Example 128 | 100 | nm | A | A | A | A | 1% | 6 | 6 |
| Example 129 | 100 | nm | A | A | A | A | 1% | 6 | 6 |
| Example 130 | 100 | nm | A | A | A | A | 1% | 6 | 6 |
| Example 131 | 100 | nm | A | A | A | A | 1% | 6 | 6 |
| Example 132 | 150 | nm | A | A | A | A | 1% | 6 | 6 |
| Example 133 | 100 | nm | A | A | A | A | 1% | 6 | 6 |
| Example 134 | 100 | nm | A | A | A | A | 1% | 6 | 6 |
| Example 135 | 100 | nm | A | A | A | A | 1% | 6 | 6 |
| Example 136 | 100 | nm | A | A | A | A | 1% | 6 | 6 |

Evaluation

| | Photoli- | Photoli- | Cycle | |
|---|---|---|---|---|
| | thography | thography | thermo | |
| | properties | properties | character- | Migration |
| Table6-4 | φ50 μm | Φ30 μm | istics | resistance |
| Example 101 | A | A | A | B |
| Example 102 | A | A | A | B |
| Example 103 | A | A | A | B |
| Example 104 | B | B | C | A |
| Example 105 | A | A | A | B |
| Example 106 | A | A | A | B |
| Example 107 | A | A | A | B |
| Example 108 | A | A | A | A |
| Example 109 | A | A | A | B |
| Example 110 | A | A | A | B |
| Example 111 | A | A | A | B |
| Example 112 | A | A | A | B |
| Example 113 | A | A | A | B |
| Example 114 | A | A | A | B |
| Example 115 | A | A | A | B |
| Example 116 | A | A | A | B |
| Example 117 | B | B | C | A |
| Example 118 | A | A | A | B |
| Example 119 | A | A | A | B |
| Example 120 | A | A | A | B |
| Example 121 | A | A | A | A |
| Example 122 | A | A | A | A |
| Example 123 | A | A | A | A |
| Example 124 | A | B | A | A |
| Example 125 | A | A | A | A |
| Example 126 | A | A | A | A |
| Example 127 | A | A | A | A |
| Example 128 | A | A | A | A |
| Example 129 | A | A | A | A |
| Example 130 | A | A | A | A |
| Example 131 | A | B | A | A |
| Example 132 | A | A | A | A |
| Example 133 | A | A | A | A |
| Example 134 | A | A | A | A |
| Example 135 | A | A | A | A |
| Example 136 | A | A | A | A |

From the evaluation results shown in the tables, it was found that the composition according to the embodiment of the present invention exhibited desired effects.

It was found that, in a case where the content of the filler was 60% by mass or more (preferably 70% by mass or more) with respect to the total solid content of the composition, the effects of the present invention were more excellent (Examples 1 to 6).

It was found that, in a case where the average particle diameter of the filler was 5 to 100 nm, the effects of the present invention were more excellent (Examples 1, 7, and 9 to 11, and Examples 101 and 104 to 107).

It was found that, in a case where the resin X had a polymerizable group or included a precursor having a group which was decomposed by action of acid to generate a polar group, the photolithography properties (diameter of 30 μm) was more excellent (Examples 1, 24, 36, and 42, and Examples 101 and 114).

It was found that, in a case where the composition further contained a polymerizable compound, the photolithography properties (diameter of 50 μm and diameter of 30 μm) were more excellent (Examples 1, 2, 48, and 49).

It was found that, in a case where the content of the surface modifier was 3% by mass or less with respect to the total mass of the filler, the photolithography properties (diameter of 50 μm and diameter of 30 μm), the cycle thermo characteristics, and the migration resistance were more excellent (Examples 1 and the like, and Example 1-103). In addition, it was found that, in a case where the content of the surface modifier was 1% by mass or less with respect to the total mass of the filler, the migration resistance was more excellent (Examples 12, 9 to 11, and 13 to 15).

In each of Examples, instead of forming the composition layer using the composition, the composition layer was formed on the base material using a transfer film produced by the following procedure, and the same evaluations as those of the composition was performed, and the same evaluation results as those of the composition were obtained.

The obtained composition was applied onto a temporary support (PET film, LUMIRROR 16FB40, thickness: 16 μm, manufactured by Toray Industries, Inc.), and dried to form a composition layer having a thickness of 10.0 μm.

Next, a cover film (polypropylene film, FG-201, thickness: 30 μm, manufactured by Oji F-Tex Co., Ltd.) was provided on the composition layer to obtain a transfer film.

The cover film was peeled off from the transfer film obtained above, and the exposed composition layer was laminated on a base material in various evaluations to form a composition layer. The lamination was performed under the following conditions using a vacuum laminator (manufactured by MCK Co., Ltd.): a substrate temperature of 40° C., a rubber roller temperature of 100° C., a linear pressure of 3 N/cm, and a transportation speed of 2 μm/min. Next, the temporary support was peeled off from the obtained sample. Thereafter, in a case where various evaluations were carried out by the same procedures as those for the composition described above, the same results were obtained.

In each of Examples, instead of forming the composition layer using the composition, the composition layer was formed on the base material using a transfer film including a thermoplastic resin layer, produced by the following procedure, and the same evaluations as those of the composition was performed, and the same evaluation results as those of the composition were obtained.

### [Method of Producing Transfer Film Having Thermoplastic Resin Layer]

A composition “Cu-1” for forming a thermoplastic resin layer, having the following configuration, was applied to a temporary support (PET film, LUMIRROR 16FB40, thickness: 16 μm, manufactured by Toray Industries, Inc.), and dried to form a thermoplastic resin layer having a thickness of 5 μm. Next, the composition described in each of Example was applied onto a cover film (polypropylene, FG-201, thickness: 30 μm, Oji F-Tex Co., Ltd.) and dried to form a composition layer having a thickness of 10 μm. The thermoplastic resin layer on the temporary support and the composition layer on the cover film were bonded to each other using a vacuum laminator (manufactured by MCK Co., Ltd.) under conditions of a substrate temperature of 30° C., a rubber roller temperature of 50° C., a linear pressure of 3 N/cm, and a transportation speed of 2 μm/min, thereby producing a transfer film having a thermoplastic resin layer, composed of temporary support/thermoplastic resin layer/composition layer/cover film.

The same evaluation results were obtained even in a case where the composition “Cu-1” for forming a thermoplastic resin layer was changed to a composition “Cu-2” for forming a thermoplastic resin layer.

TABLE 7

| | | Composition | Composition |
|---|---|---|---|
| | | Cu-1 for forming | Cu-2 for forming |
| | | thermoplastic | thermoplastic |
| | | resin layer | resin layer |
| Component | | (part by mass) | (part by mass) |
| Polymer | A-2 | 15.0 | — |
| | (solid content: | | |
| | 40% by mass) | | |
| | A-11 | — | 6.8 |
| | A-12 | — | 10.2 |
| Coloring agent | B-1 | 0.1 | — |
| Photoacid | C-1 | 0.1 | — |
| generator | | | |
| Plasticizer | D-3 | 2.2 | — |
| | D-4 | 1.1 | — |
| | D-5 | 0.5 | — |
| | D-6 | — | 9.10 |
| Surfactant | E-1 | 0.02 | 0.54 |
| Additive | F-1 | 0.03 | — |
| | F-2 | 0.01 | — |
| Solvent | MEK | 63.0 | 52.4 |
| | PGME | 9.0 | — |
| | PGMEA | 9.0 | 6.4 |
| | MeOH | — | 11.1 |

A-2: polymer-containing solution containing 40% by mass of a polymer (benzyl methacrylate/methacrylic acid/acrylic acid copolymer (compositional ratio of constitutional units derived from respective monomers in polymer: 75% by mass/10% by mass/15% by mass, weight-average molecular weight: 30,000, Tg: 75° C., acid value: 186 mgKOH/g))
A-11: methyl methacrylate/2-ethylhexyl acrylate/benzyl methacrylate/methacrylic acid copolymer (compositional ratio of constitutional units derived from respective monomers in polymer: 55 mol %/11.7 mol %/4.5 mol %/28.8 mol %, weight-average molecular weight: 100,000)
A-12: styrene/acrylic acid copolymer (compositional ratio of constitutional units derived from respective monomers in polymer: 63 mol %/37 mol %, weight-average molecular weight: 10,000)
B-1: compound having the following structure (coloring agent which develops color by acid)

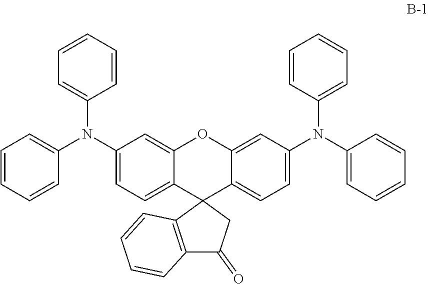 [SMILES: O=C1CC2(c3ccc(N(c4ccccc4)c4ccccc4)cc3Oc3cc(N(c4ccccc4)c4ccccc4)ccc32)c2ccccc21]

C-1: compound having the following structure (photoacid generator; synthesized according to the following method)

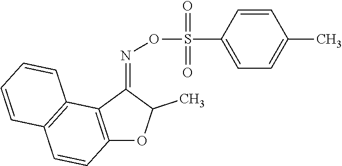 [SMILES: Cc1ccc(S(=O)(=O)O/N=C2/c3c(ccc4ccccc34)OC2C)cc1]

### (Synthesis of Compound C-1)

Aluminum chloride (10.6 g) and 2-chloropropionyl chloride (10.1 g) were added to a suspension of 2-naphthol (10 g) and chlorobenzene (30 mL), and the mixed solution was heated to 40° C. and reacted for 2 hours. Under ice cooling, a 4 N HCl aqueous solution (60 mL) was added dropwise to the reaction solution, and ethyl acetate (50 mL) was added thereto for liquid separation. Potassium carbonate (19.2 g) was added to the organic layer, the mixture was reacted at 40° C. for 1 hour, a 2 N HCl aqueous solution (60 mL) was added thereto for liquid separation, the organic layer was concentrated, and the crystals were subjected to re-slurrying with diisopropyl ether (10 mL), and filtered and dried to obtain a ketone compound (6.5 g).

Acetic acid (7.3 g) and a 50% by mass hydroxylamine aqueous solution (8.0 g) were added to a suspension of the obtained ketone compound (3.0 g) in methanol (18 mL), and the mixture was heated under reflux for 10 hours. After cooling, water (50 mL) was added thereto, and the precipitated crystals were filtered, washed with cold methanol, and dried to obtain an oxime compound (2.4 g).

The obtained oxime compound (1.8 g) was dissolved in acetone (20 mL), triethylamine (1.5 g) and p-toluenesulfonyl chloride (2.4 g) were added thereto under ice cooling, and the mixture was heated to room temperature and reacted for 1 hour. Water (50 mL) was added to the reaction solution, and the precipitated crystals were filtered, subjected to re-slurrying in methanol (20 mL), filtered, and dried to obtain C-1 (2.3 g).
D-3: NK ESTER A-DCP (tricyclodecane dimethanol diacrylate, Shin-Nakamura Chemical Co., Ltd.)
D-4: 8UX-015A (polyfunctional urethane acrylate compound, Taisei Fine Chemical Co., Ltd.)
D-5: ARONIX TO-2349 (polyfunctional acrylate compound having carboxy group, TOAGOSEI CO., LTD.)
D-6: 2,2-bis(4-methacryloxypolyethoxyphenyl)propane (Shin-Nakamura Chemical Co., Ltd.)
E-1: 5-506 (DIC Corporation, Si-based surfactant)
F-1: phenothiazine (FUJIFILM Wako Pure Chemical Corporation)
F-2: CBT-1 (JOHOKU CHEMICAL CO., LTD.)
MEK: methyl ethyl ketone
PGME: propylene glycol monomethyl ether
PGMEA: propylene glycol monomethyl ether acetate
MeOH: methanol

The composition of each of Examples obtained by the above-described method was applied to a glass epoxy base material (CCL-EL190T, thickness: 1.0 mm, manufactured by MITSUBISHI GAS CHEMICAL COMPANY, INC.) on which a circuit pattern had been formed using a bar coater, and dried to form a composition layer on one surface of the glass epoxy base material. The same operation was performed on the back surface of the coated surface to form a composition layer on both surfaces. At this time, a thickness of the composition layer formed on each of the one surfaces of the glass epoxy base material was 25 μm.

A pattern having a via with a diameter of φ60 μm at a predetermined position was formed on the composition layer, a heating treatment was performed, the residue was removed with a sodium permanganate aqueous solution as a roughening liquid, and an electroless plating treatment was performed. Next, a resist pattern was formed at a predetermined position using a known dry film resist, and an electrolytic plating treatment was performed. Next, the resist pattern was peeled off with a stripper. Finally, a seed layer etching treatment was performed, and then a heating treatment (200° C., 3 hours) was performed to form a copper wire on the cured film.

The above-described process from the formation of the composition to the heating treatment described above was performed three times, and finally, a solder resist was formed as an outermost layer, and a semiconductor element was further sealed and mounted to produce a semiconductor package. The obtained semiconductor package was mounted at a predetermined position of a printed wiring board to obtain a semiconductor package substrate. It was found that the obtained semiconductor package substrate normally operated.

The cover film was peeled off from the transfer film of each of Examples obtained by the above-described method (transfer film not having a thermoplastic resin layer), and the exposed composition layer was laminated on each surface of a glass epoxy base material (CCL-EL190T, thickness: 1.0 mm, manufactured by MITSUBISHI GAS CHEMICAL COMPANY, INC.) on which a circuit pattern had been formed, thereby forming a composition layer on both surfaces of the glass epoxy base material. The lamination was performed under the following conditions using a vacuum laminator (manufactured by MCK Co., Ltd.): a substrate temperature of 40° C., a rubber roller temperature of 100° C., a linear pressure of 3 N/cm, and a transportation speed of 2 μm/min. Next, the temporary support was peeled off from the obtained sample.

A pattern having a via with a diameter of φ50 μm at a predetermined position was formed on the composition layer, a heating treatment was performed, the residue was removed with a sodium permanganate aqueous solution as a roughening liquid, and an electroless plating treatment was performed. Next, a resist pattern was formed at a predetermined position using a known dry film resist, and an electrolytic plating treatment was performed. Next, the resist pattern was peeled off with a stripper. Finally, a seed layer etching treatment was performed, and then a heating treatment (200° C., 3 hours) was performed to form a copper wire on the cured film.

The above-described process from the lamination to the heating treatment was performed three times, and finally, a solder resist was formed as an outermost layer, and a semiconductor element was further sealed and mounted to produce a semiconductor package. The obtained semiconductor package was mounted at a predetermined position of a printed wiring board to obtain a semiconductor package substrate. It was found that the obtained semiconductor package substrate normally operated.

### EXPLANATION OF REFERENCES

12: temporary support
14: composition layer
16: cover film
100: transfer film

What is claimed is:

1. A composition comprising:
a resin X including at least one selected from the group consisting of a polyimide precursor, a polyimide, a polybenzoxazole precursor, and a polybenzoxazole; and
a filler,
wherein a content of the filler is 50.0% by mass or more with respect to a total solid content of the composition, and
an average particle diameter of the filler, which is calculated by the following particle diameter measuring method, is 300 nm or less,
the particle diameter measuring method: the composition is applied onto a base material to form a coating film, a rectangular region of 3 μm×10 μm in a cross section of the coating film along a normal direction of a surface of the coating film is observed with a scanning electron microscope, an operation of measuring a major diameter of all the fillers observed in the region is performed at five different locations on the coating film, and an average value of all major diameters of the fillers measured in each operation is obtained as the average particle diameter of the filler.

2. The composition according to claim 1,
wherein the composition does not include an organic filler,
the resin X includes at least one selected from the group consisting of a polyimide precursor, a polybenzoxazole precursor, and a polybenzoxazole, and
the filler is at least one selected from the group consisting of silicon dioxide, silicate, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride.

3. The composition according to claim 1,
wherein the composition does not include an organic filler,
the filler is at least one selected from the group consisting of silicon dioxide, silicate, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride, and
in a case where the resin X has a polymerizable group, the composition further contains a photopolymerization initiator, or
in a case where the resin X has no polymerizable group, the composition further contains a polymerizable compound and a photopolymerization initiator.

4. The composition according to claim 1,
wherein the filler includes at least one selected from the group consisting of silicon dioxide, boron nitride, barium sulfate, and silicate.

5. The composition according to claim 1,
wherein the average particle diameter of the filler is 5 to 100 nm.

6. The composition according to claim 1,
wherein the content of the filler is 60.0% by mass or more with respect to the total solid content of the composition.

7. The composition according to claim 1,
wherein the filler is subjected to a surface treatment with a surface modifier.

8. The composition according to claim 7,
wherein a content of the surface modifier is 3% by mass or less with respect to a total mass of the filler.

9. The composition according to claim 8,
wherein the content of the surface modifier is 1% by mass or less with respect to the total mass of the filler.

10. The composition according to claim 1,
wherein, in a case where the resin X has a polymerizable group, the composition further contains a photopolymerization initiator, or
in a case where the resin X has no polymerizable group, the composition further contains a polymerizable compound and a photopolymerization initiator.

11. The composition according to claim 1, further comprising:
a compound Y having no ethylenically polymerizable group and having a boiling point of 300° C. or higher.

12. The composition according to claim 11,
wherein the composition further contains a polymerizable compound and the compound Y, and
a total content of the polymerizable compound and the compound Y is 30.0% by mass or less with respect to the total solid content of the composition.

13. The composition according to claim 10,
wherein a content of the photopolymerization initiator is 5.0% by mass or less with respect to the total solid content of the composition.

14. The composition according to claim 10,
wherein an average value X of coefficients of thermal expansion of a film obtained by the following method A in a range of 50° C. to 100° C. is 20 ppm/K or less,
the method A: a composition layer is formed on a base material using the composition, the composition layer is exposed at an integrated illuminance of 100 mJ/cm² using a high pressure mercury lamp, and the exposed composition layer is heat-treated at 230° C. for 8 hours, immersed in a 2 M hydrochloric acid for 8 hours, rinsed with water, and peeled off from the base material to obtain the film.

15. The composition according to claim 10,
wherein a ratio of an average value Y of coefficients of thermal expansion of a film obtained by the following method A in a range of 190° C. to 210° C. to an average value X of coefficients of thermal expansion of the film in a range of 50° C. to 100° C. is 2.0 or less,
the method A: a composition layer is formed on a base material using the composition, the composition layer is exposed at an integrated illuminance of 100 mJ/cm² using a high pressure mercury lamp, and the exposed composition layer is heat-treated at 230° C. for 8 hours, immersed in a 2 M hydrochloric acid for 8 hours, rinsed with water, and peeled off from the base material to obtain the film.

16. The composition according to claim 1, further comprising:
a photoacid generator,
wherein the resin X includes the precursor which has a group decomposed by action of acid to generate a polar group.

17. The composition according to claim 16,
wherein a content of the photoacid generator is 5.0% by mass or less with respect to the total solid content of the composition.

18. The composition according to claim 16,
wherein an average value X of coefficients of thermal expansion of a film obtained by the following method B in a range of 50° C. to 100° C. is 20 ppm/K or less,
the method B: a composition layer is formed on a base material using the composition, and the composition layer is heat-treated at 230° C. for 8 hours, immersed in a 2 M hydrochloric acid for 8 hours, rinsed with water, and peeled off from the base material to obtain the film.

19. The composition according to claim 16,
wherein a ratio of an average value Y of coefficients of thermal expansion of a film obtained by the following method B in a range of 190° C. to 210° C. to an average value X of coefficients of thermal expansion of the film in a range of 50° C. to 100° C. is 2.0 or less,
the method B: a composition layer is formed on a base material using the composition, and the composition layer is heat-treated at 230° C. for 8 hours, immersed in a 2 M hydrochloric acid for 8 hours, rinsed with water, and peeled off from the base material to obtain the film.

20. A transfer film comprising:
a temporary support; and
a composition layer formed of the composition according to claim 1.

21. A cured film obtained by curing the composition according to claim 10.

22. A manufacturing method of a laminate, comprising:
a step of forming a composition layer on a base material using the composition according to claim 1;
a step of exposing the composition layer in a patterned manner; and
a step of developing the exposed composition layer with a developer to form a pattern,
wherein the developer includes at least one selected from the group consisting of cyclopentanone, a tetramethylammonium hydroxide aqueous solution, a sodium hydroxide aqueous solution, a sodium carbonate aqueous solution, and a potassium carbonate aqueous solution.

23. A laminate manufactured by the manufacturing method of a laminate according to claim 22.

24. A manufacturing method of a semiconductor package, comprising:
the manufacturing method of a laminate according to claim 22.
